(19) United States
(12) Patent Application Publication
(10) Pub. No.: US 2026/0343859 A1
(43) Pub. Date: Oct. 29, 2026

(54) SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Tsutomu MURAKAWA, Isehara (JP); Satoru SAITO, Yamato (JP); Hitoshi KUNITAKE, Machida (JP); Hiromi SAWAI, Kawasaki (JP)

(21) Appl. No.: 19/484,976

(22) PCT Filed: May 20, 2024
(86) PCT No.: PCT/IB2024/054865

§ 371 Date: Nov. 17, 2025

(30) Foreign Application Priority Data
May 25, 2023 (JP) 2023-086325

(51) Int. Cl. H10B 12/00

(52) U.S. Cl. CPC H10B 12/33; H10B 12/05

(57) ABSTRACT

A semiconductor device having favorable electrical characteristics can be provided. The semiconductor device includes a transistor and a first insulator; the transistor includes a first conductor, a second conductor over the first conductor and the first insulator, an oxide semiconductor, a second insulator, and a third conductor; an opening portion reaching the first conductor is provided in the first insulator and the second conductor; a depressed portion overlapping with the opening portion is provided in the first conductor; part of the oxide semiconductor, part of the second insulator, and part of the third conductor are provided in the depressed portion; the oxide semiconductor is in contact with the first conductor and the second conductor; the second insulator is positioned over the oxide semiconductor and in contact with at least part of a top surface of the first conductor; and the third conductor is positioned over the second insulator.

### TECHNICAL FIELD

One embodiment of the present invention relates to a semiconductor device, a memory device, and an electronic device. Another embodiment of the present invention relates to a method for fabricating the semiconductor device.

Note that one embodiment of the present invention is not limited to the above technical field. Examples of the technical field of one embodiment of the present invention include a semiconductor device, a display device, a light-emitting device, a power storage device, a memory device, an electronic device, a lighting device, an input device (e.g., a touch sensor), an input/output device (e.g., a touch panel), driving methods thereof, and manufacturing methods thereof.

Note that in this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. A display device (e.g., a liquid crystal display device and a light-emitting display device), a projection device, a lighting device, an electro-optical device, a power storage device, a memory device, a semiconductor circuit, an imaging device, an electronic device, and the like each include a semiconductor device in some cases.

### BACKGROUND ART

In recent years, semiconductor devices have been developed, and LSIs (Large Scale Integrations), CPUs (Central Processing Units), memories, and the like are mainly used as the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a semiconductor thin film that can be used in a transistor, and an oxide semiconductor has been attracting attention as another material.

It is known that a transistor using an oxide semiconductor has extremely low leakage current in a non-conduction state. For example, Patent Document 1 discloses a low-power-consumption CPU utilizing a feature of low leakage current of the transistor including an oxide semiconductor. Furthermore, for example, Patent Document 2 discloses a memory device that can retain stored contents for a long period of time by utilizing a feature of low leakage current of the transistor including an oxide semiconductor.

In recent years, demand for an integrated circuit with higher density has risen with reductions in size and weight of electronic devices. Furthermore, the productivity of a semiconductor device including an integrated circuit is desired to be improved. For example, Patent Document 3 and Non-Patent Document 1 each disclose a technique to achieve an integrated circuit with higher density by making a plurality of memory cells overlap with each other by stacking a first transistor using an oxide semiconductor film and a second transistor using an oxide semiconductor film. For another example, Patent Document 4 discloses a technique to achieve an integrated circuit with a higher density by placing a channel of a transistor using an oxide semiconductor film in the vertical direction.

### REFERENCE

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Document

[Non-Patent Document 1]M. Oota et. al., “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a semiconductor device with favorable electrical characteristics. Another object of one embodiment of the present invention is to provide a semiconductor device with a high on-state current. Another object of one embodiment of the present invention is to provide a semiconductor device that operates at high speed. Another object of one embodiment of the present invention is to provide a semiconductor device that can be miniaturized or highly integrated. Another object of one embodiment of the present invention is to provide a highly reliable semiconductor device. Another object of one embodiment of the present invention is to provide a semiconductor device with a small variation in electrical characteristics of transistors. Another object of one embodiment of the present invention is to provide a semiconductor device with low power consumption. Another object of one embodiment of the present invention is to provide a novel semiconductor device. Another object of one embodiment of the present invention is to provide a method for fabricating a semiconductor device with high productivity. Another object of one embodiment of the present invention is to provide a method for fabricating a novel semiconductor device.

Another object of one embodiment of the present invention is to provide a memory device that can be miniaturized or highly integrated. Another object of one embodiment of the present invention is to provide a memory device with a large memory capacity. An object of one embodiment of the present invention is to provide a memory device with high operating speed. Another object of one embodiment of the present invention is to provide a memory device with low power consumption. Another object of one embodiment of the present invention is to provide a novel memory device.

Note that the description of these objects does not preclude the existence of other objects. One embodiment of the present invention does not necessarily achieve all of these objects. Other objects can be derived from the description of the specification, the drawings, and the claims.

### Means for Solving the Problems

One embodiment of the present invention is a semiconductor device including a transistor and a first insulator. The transistor includes a first conductor, a second conductor over the first conductor and the first insulator, an oxide semiconductor, a second insulator, and a third conductor. An opening portion reaching the first conductor is provided in the first insulator and the second conductor. A depressed portion overlapping with the opening portion is provided in the first conductor. Part of the oxide semiconductor, part of the second insulator, and part of the third conductor are provided in the depressed portion. The oxide semiconductor is in contact with the first conductor and the second conductor. The second insulator is placed over the oxide semiconductor and is in contact with at least part of a top surface of the first conductor. The third conductor is placed over the second insulator.

In the above, at least part of a bottom surface of the oxide semiconductor is preferably removed in the depressed portion.

In the above, a bottom surface of the third conductor is preferably at a lower level than a top surface of the first conductor in a region not overlapping with the opening portion.

In the above, the second conductor preferably includes a first layer and a second layer over the first layer, the first layer preferably includes a metal oxide, and the second layer preferably has higher conductivity than the first layer.

In the above, the first layer preferably includes indium. In addition, in the above, the first layer preferably includes tin and silicon.

In the above, the second layer preferably includes tungsten.

In the above, a side surface of the first layer on the opening portion side is preferably positioned closer to the opening portion than a side surface of the second layer on the opening portion side is.

In the above, the oxide semiconductor is preferably in contact with the side surface of the first layer on the opening portion side and part of a top surface of the first layer.

In the above, a third insulator is preferably placed between the second layer and the third conductor.

In the above, the first conductor preferably includes a third layer and a fourth layer over the third layer, the third layer preferably has higher conductivity than the fourth layer, and the fourth layer preferably includes a metal oxide.

In the above, the third layer preferably includes tungsten.

In the above, the fourth layer preferably includes indium. In addition, in the above, the fourth layer preferably includes tin and silicon.

In the above, the opening portion can reach the third layer.

Another embodiment of the present invention is a semiconductor device including a transistor and a first insulator; the transistor includes a first conductor provided over a base insulator, a second conductor over the first conductor and the first insulator; an oxide semiconductor, a second insulator, and a third conductor; an opening portion reaching the base insulator is provided in the first conductor, the first insulator, and the second conductor; part of the oxide semiconductor, part of the second insulator, and part of the third conductor are provided in the opening portion; the oxide semiconductor is in contact with the first conductor and the second conductor; the second insulator is placed over the oxide semiconductor and is in contact with at least part of a top surface of the base insulator; and the third conductor is placed over the second insulator.

### Effect of the Invention

One embodiment of the present invention can provide a semiconductor device with favorable electrical characteristics. Another embodiment of the present invention can provide a semiconductor device with a high on-state current. Another embodiment of the present invention can provide a semiconductor device that operates at high speed. Another embodiment of the present invention can provide a semiconductor device that can be miniaturized or highly integrated. One embodiment of the present invention can provide a highly reliable semiconductor device. Another embodiment of the present invention can provide a semiconductor device with a small variation in electrical characteristics of transistors. Another embodiment of the present invention can provide a semiconductor device with low power consumption. Another embodiment of the present invention can provide a novel semiconductor device. Another embodiment of the present invention can provide a method for fabricating a semiconductor device with high productivity. Another embodiment of the present invention can provide a method for fabricating a novel semiconductor device.

Another embodiment of the present invention can provide a memory device that can be miniaturized or highly integrated. Another embodiment of the present invention can provide a memory device with a large memory capacity. Another embodiment of the present invention can provide a memory device that can operate at high speed. Another embodiment of the present invention can provide a memory device with low power consumption. Another embodiment of the present invention can provide a novel memory device.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a plan view illustrating an example of a semiconductor device. FIG. 1B to FIG. 1D are cross-sectional views illustrating an example of a semiconductor device.

FIG. 2A and FIG. 2B are cross-sectional views illustrating examples of a semiconductor device.

FIG. 3A to FIG. 3C are cross-sectional views illustrating examples of a semiconductor device.

FIG. 4A to FIG. 4F are cross-sectional views illustrating an example of a method for fabricating a semiconductor device.

FIG. 5A to FIG. 5F are cross-sectional views illustrating an example of a method for fabricating a semiconductor device.

FIG. 6A is a plan view illustrating an example of a semiconductor device. FIG. 6B to FIG. 6D are cross-sectional views illustrating the example of the semiconductor device.

FIG. 7A is a plan view illustrating an example of a semiconductor device. FIG. 7B to FIG. 7D are cross-sectional views illustrating the example of the semiconductor device.

FIG. 8A is a plan view illustrating an example of a semiconductor device. FIG. 8B to FIG. 8D are cross-sectional views illustrating the example of the semiconductor device.

FIG. 9A is a plan view illustrating an example of a semiconductor device. FIG. 9B to FIG. 9D are cross-sectional views illustrating the example of the semiconductor device.

FIG. 10A is a plan view illustrating an example of a semiconductor device. FIG. 10B to FIG. 10D are cross-sectional views illustrating the example of the semiconductor device.

FIG. 11A is a plan view illustrating an example of a semiconductor device. FIG. 11B is a cross-sectional view illustrating the example of the semiconductor device.

FIG. 12A and FIG. 12B are plan views illustrating an example of a semiconductor device. FIG. 12C is a cross-sectional view illustrating the example of the semiconductor device.

FIG. 13A is a plan view illustrating an example of a semiconductor device. FIG. 13B and FIG. 13C are cross-sectional views illustrating the example of the semiconductor device.

FIG. 14A and FIG. 14B are plan views illustrating an example of a semiconductor device. FIG. 14C is a cross-sectional view illustrating the example of the semiconductor device.

FIG. 15A to FIG. 15D are conceptual diagrams illustrating cross sections of oxide semiconductor layers.

FIG. 16 is a block diagram showing a structure example of a semiconductor device.

FIG. 17A to FIG. 17H are each a diagram showing a circuit configuration example of a memory cell.

FIG. 18A is a plan view illustrating an example of a semiconductor device. FIG. 18B and FIG. 18C are cross-sectional views illustrating the example of the semiconductor device.

FIG. 19A is a plan view illustrating an example of a semiconductor device. FIG. 19B is a cross-sectional view illustrating the example of the semiconductor device.

FIG. 20A and FIG. 20B are perspective views illustrating structure examples of a semiconductor device.

FIG. 21 is a cross-sectional view illustrating an example of a semiconductor device.

FIG. 22 is a block diagram showing a CPU.

FIG. 23A and FIG. 23B are perspective views of a semiconductor device.

FIG. 24A and FIG. 24B are perspective views of semiconductor devices.

FIG. 25A and FIG. 25B are diagrams showing hierarchies of memory devices.

FIG. 26A and FIG. 26B are diagrams illustrating examples of electronic devices, and FIG. 26C to FIG. 26E are diagrams illustrating an example of a large computer.

FIG. 27 is a diagram illustrating an example of space equipment.

FIG. 28 is a diagram showing an example of a storage system that can be used for a data center.

FIG. 29A and FIG. 29B are structure examples of a display device.

FIG. 30 is a structure example of a display device.

FIG. 31 is a structure example of a display device.

FIG. 32A to FIG. 32C are a structure examples of a display device.

FIG. 33A and FIG. 33B are structure examples of a display device.

FIG. 34A to FIG. 34D are structure examples of electronic devices.

FIG. 35A to FIG. 35F are structure examples of electronic devices.

FIG. 36A to FIG. 36G are structure examples of electronic devices.

FIG. 37 is a cross-sectional view of a transistor in Example.

FIG. 38 is a graph showing electrical characteristics of a transistor in Example.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Thus, the disclosed invention is not necessarily limited to the position, size, range, and the like disclosed in the drawings.

In a plan view, a perspective view, or the like, especially, some components are not illustrated for easy understanding of the invention in some cases. In addition, some hidden lines are not shown in some cases.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

Note that the term “film” and the term “layer” can be used interchangeably depending on the case or the circumstances. For example, the term “conductive layer” can be replaced with the term “conductive film”. For another example, the term “insulating film” can be replaced with the term “insulating layer”. The term “conductor” can be replaced with the term “conductive layer” or “conductive film” depending on the case or the circumstances. The term “insulator” can be replaced with the term “insulating layer” or “insulating film” depending on the case or the circumstances. The term “oxide semiconductor” can be replaced with the term “oxide semiconductor layer” or “oxide semiconductor film” depending on the case or the circumstances.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 800 and less than or equal to 100°. Accordingly, the case where the angle is greater than or equal to 850 and less than or equal to 950 is also included. Furthermore, “substantially perpendicular” indicates a state where two straight lines are placed at an angle greater than or equal to 600 and less than or equal to 120°.

The term “opening” includes a groove, a slit, a depressed portion, and the like. A region where an opening is formed is referred to as an opening portion in some cases.

In the drawings used in this specification, a sidewall of an insulator in an opening portion is illustrated as being perpendicular or substantially perpendicular to a substrate surface or a formation surface, but the sidewall may have a tapered shape.

In this specification and the like, a tapered shape refers to a shape such that at least part of a side surface of a component is inclined with respect to a substrate surface or a formation surface. For example, the tapered shape preferably includes a region where the angle between the inclined side surface and the substrate surface or the formation surface (the angle is hereinafter referred to as a taper angle in some cases) is less than 90°. Note that the side surface of the component and the substrate surface are not necessarily completely flat and may be substantially flat with a slight curvature or with slight unevenness. In this specification and the like, an inverse tapered shape refers to a shape having a side portion or an upper portion protruding beyond its bottom portion in the direction parallel to a substrate.

Note that in this specification and the like, the expression “substantially level with” indicates a structure having the same level from a reference surface (e.g., a flat surface such as a substrate surface) in a cross-sectional view. For example, in a manufacturing process of a memory device, planarization treatment (typically, chemical mechanical polishing (CMP) treatment) is performed, whereby the surface(s) of a single layer or a plurality of layers are exposed in some cases. In this case, the surfaces on which the CMP treatment is performed are at the same level from a reference surface. Note that a plurality of layers are not level with each other in some cases, depending on a treatment apparatus, a treatment method, or a material of the treated surfaces on which the CMP treatment is performed. This case is also regarded as being “level with” in this specification and the like. For example, the expression “level with” also includes the case where two layers (here, given as a first layer and a second layer) have different levels with respect to the reference surface and the difference in the top-surface level between the first and second layers is less than or equal to 20 nm.

In this specification and the like, the expression “a side end portion is aligned with another side end portion” means that at least outlines of stacked layers partly overlap with each other in a plan view. For example, the case of processing an upper layer and a lower layer with the use of the same mask pattern or mask patterns that are partly the same is included. The expression “a side end portion is aligned with another side end portion” also includes the case where the outlines do not exactly overlap with each other; for instance, the outline of the upper layer may be positioned inward or outward from the outline of the lower layer.

In general, it is difficult to clearly differentiate “completely the same” from “substantially the same”. Thus, in this specification and the like, the expression “the same” includes both “completely the same” and “substantially the same”.

Note that in this specification and the like, the expression “the first thickness and the second thickness are the same” means that a value obtained by dividing the absolute value of the difference between the first thickness and the second thickness by the first thickness is less than or equal to 0.1. Alternatively, the expression means that a value obtained by dividing the absolute value of the difference between the first thickness and the second thickness by the second thickness is less than or equal to 0.1.

Note that in this specification and the like, the expression “the distance A and the distance B are the same” means that a value obtained by dividing the absolute value of the difference between the distance A and the distance B by the distance A is less than or equal to 0.1. Alternatively, the expression means that a value obtained by dividing the absolute value of the difference between the distance A and the distance B by the distance B is less than or equal to 0.1.

### Embodiment 1

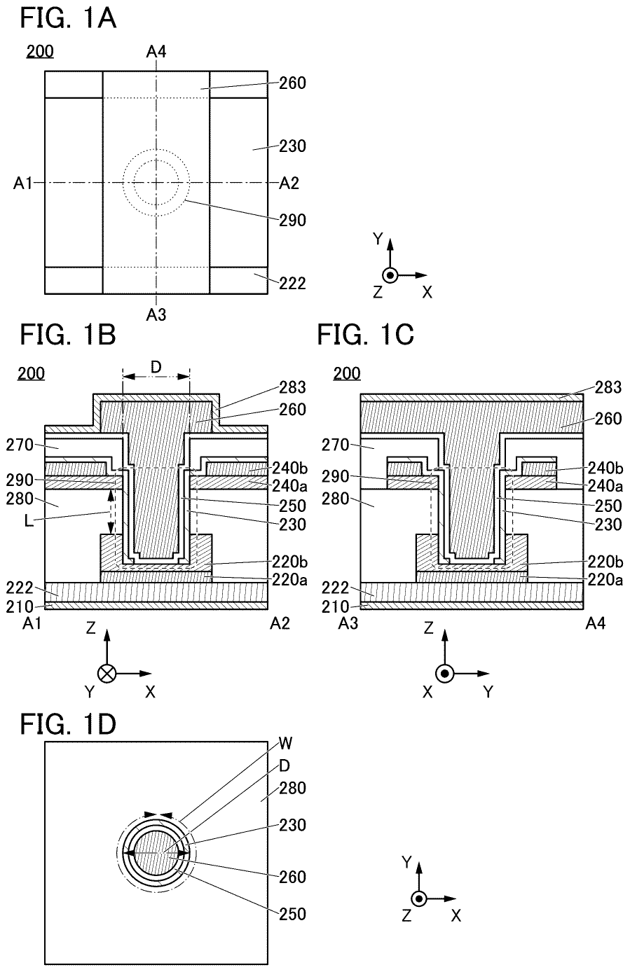

In this embodiment, examples of a semiconductor device of one embodiment of the present invention are described with reference to FIG. 1A to FIG. 14C.

### Structure Example of Semiconductor Device

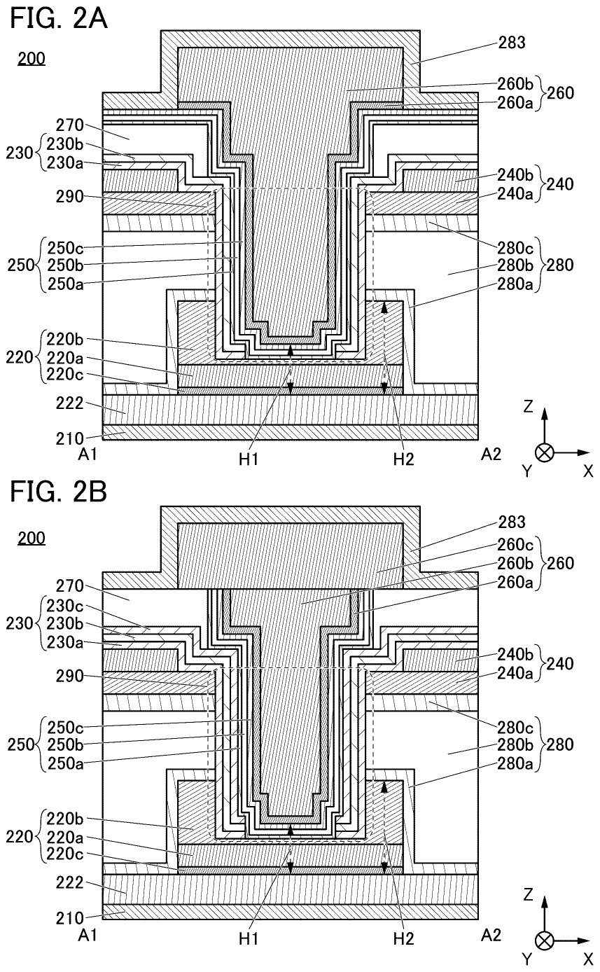

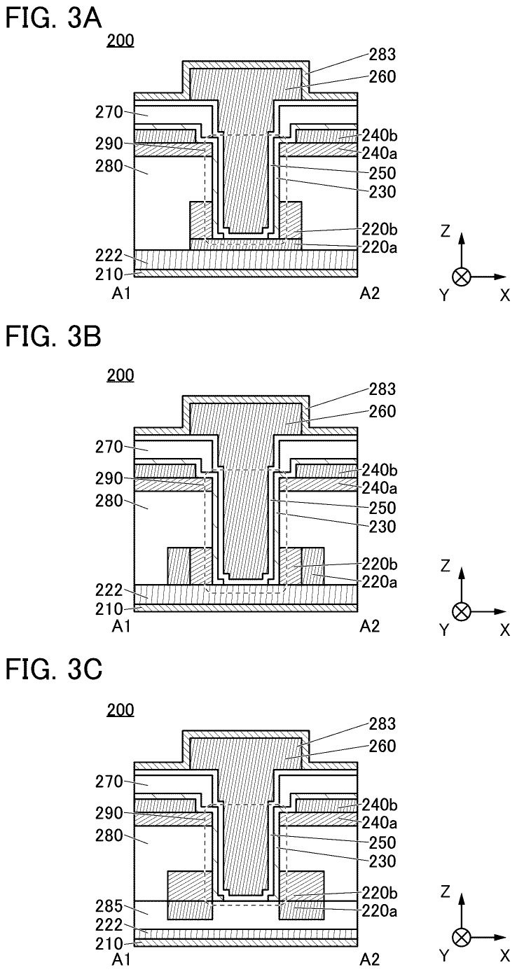

A structure example of the semiconductor device of one embodiment of the present invention is described with reference to FIG. 1A to FIG. 3C. FIG. 1A to FIG. 1D are a top view and cross-sectional views of a semiconductor device including a transistor 200. FIG. 1A is a top view of the semiconductor device. FIG. 1B to FIG. 1D are the cross-sectional views of the semiconductor device. Here, FIG. 1B is a cross-sectional view of a portion indicated by the dashed-dotted line A1-A2 in FIG. 1A. FIG. 1C is a cross-sectional view of a portion indicated by the dashed-dotted line A3-A4 in FIG. 1A. Note that some components are omitted in the plan view of FIG. 1A for clarity of the drawing. FIG. 2A and FIG. 2B are enlarged views corresponding to FIG. 1B. FIG. 3A to FIG. 3C illustrate other structure examples of the semiconductor device corresponding to that in FIG. 1B.

Note that in the drawings and the like in this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

The semiconductor device illustrated in FIG. 1A to FIG. 1D includes an insulator 210 over a substrate (not illustrated), an insulator 222 over the insulator 210, the transistor 200 over the insulator 222, an insulator 280 over the insulator 222, an insulator 270 over the insulator 280, and an insulator 283 over the transistor 200. The insulator 210, the insulator 280, and the insulator 270 each function as an interlayer insulating film. The insulator 210 and the insulator 222 each function as a base insulator.

The transistor 200 includes a conductor 220 over the insulator 222, a conductor 240 over the insulator 280, an oxide semiconductor 230 in contact with the conductor 220 and the conductor 240, an insulator 250 over the oxide semiconductor 230 and the insulator 270, and a conductor 260 over the insulator 250. The conductor 240 includes a conductor 240a and a conductor 240b over the conductor 240a. The conductor 220 includes a conductor 220a and a conductor 220b over the conductor 220a.

In the transistor 200, the oxide semiconductor 230 functions as a semiconductor layer, the conductor 260 functions as a gate electrode, the insulator 250 functions as a gate insulator, the conductor 220 functions as one of a source electrode and a drain electrode, and the conductor 240 functions as the other of the source electrode and the drain electrode.

In the transistor 200, a metal oxide functioning as a semiconductor (also referred to as an oxide semiconductor) is preferably used as the oxide semiconductor 230 including the channel formation region. Hereinafter, a transistor including an oxide semiconductor in its channel formation region, such as the transistor 200, is referred to as an OS transistor in some cases.

As illustrated in FIG. 1B and FIG. 1C, an opening portion 290 reaching the conductor 220 is provided in the insulator 280 and the conductor 240a. Here, a depressed portion is formed on the top surface of the conductor 220 and the depressed portion overlaps with the opening portion 290. Here, the bottom portion of the opening portion 290 is the bottom surface of the depressed portion of the conductor 220. The sidewall of the opening portion 290 is the side surface of the insulator 280, the side surface of the conductor 240a, and the side surface of the depressed portion of the conductor 220. The opening portion 290 includes an opening portion of the insulator 280 and an opening portion of the conductor 240a. In other words, the opening portion of the insulator 280 in a region overlapping with the conductor 220 is part of the opening portion 290, and the opening portion of the conductor 240a in a region overlapping with the conductor 220 is another part of the opening portion 290.

At least part of the components of the transistor 200 is placed in the opening portion 290. Specifically, at least part of each of the oxide semiconductor 230, the insulator 250, and the conductor 260 is placed in the opening portion 290.

Portions of the oxide semiconductor 230 and the insulator 250 that are placed in the opening portion 290 reflect at least part of the shape of the opening portion 290. That is, the oxide semiconductor 230 is provided so as to cover the sidewall of the opening portion 290, the insulator 250 is provided so as to cover the oxide semiconductor 230, and the conductor 260 is provided so as to be embedded in the depressed portion of the insulator 250 that reflects the shape of the opening portion 290.

Note that at least part of the bottom surface of the oxide semiconductor 230 is removed in the opening portion 290. In other words, an opening is formed in part of the bottom surface of the oxide semiconductor 230. Thus, the insulator 250 is in contact with the conductor 220 in a region of the bottom portion of the opening 290 where the oxide semiconductor 230 is removed. That is, the insulator 250 is in contact with at least part of the top surface of the conductor 220. Here, in the case where part of the bottom surface of the oxide semiconductor 230 is removed by a lithography method, a lower portion of the oxide semiconductor 230 has a shape that protrudes in the direction toward the center of the opening portion 290, as illustrated in FIG. 1A to FIG. 1C. The shape of the insulator 250 reflects the protruding shape of the lower portion of the oxide semiconductor 230.

Here, the oxide semiconductor 230 is provided inside the opening portion of the insulator 280. The transistor 200 has a structure in which current flows in the vertical direction since one of the source electrode and the drain electrode (here, the conductor 220) is positioned on the lower side and the other of the source electrode and the drain electrode (here, the conductor 240) is positioned on the upper side. That is, in the transistor 200, a channel is formed along the side surface of the opening portion 290 of the insulator 280. Accordingly, the transistor of one embodiment of the present invention can be referred to as a vertical-channel transistor or a VFET (Vertical Field-Effect Transistor). Although FIG. 1B and FIG. 1C illustrate the insulator 280 having a single-layer structure as an example, without limitation to this, a stacked-layered structure can be employed. For example, the insulator 280 can have a two-layer structure in which the top surface of an insulator in the first layer is level with the top surface of the conductor 220 and an insulator in the second layer is provided over the insulator in the first layer.

In the oxide semiconductor 230, a source region and a drain region are formed such that the channel formation region is sandwiched therebetween. Here, one of the source region and the drain region includes at least part of a region of the oxide semiconductor 230 that is in contact with the conductor 240. The other of the source region and the drain region includes at least part of a region of the oxide semiconductor 230 that is in contact with the conductor 220. That is, the channel formation region of the transistor 200 is positioned in a region of the oxide semiconductor 230 that is between the conductor 220 and the conductor 240. It can also be said that the channel formation region of the transistor 200 is positioned in a region of the oxide semiconductor 230 that is in contact with the insulator 280, or the vicinity of the region.

The channel length of the transistor 200 is the distance between the source region and the drain region. That is, it can be said that the channel length of the transistor 200 is determined by the thickness of the insulator 280 over the conductor 220. In FIG. 1B, a channel length L of the transistor 200 is indicated by a dashed double-headed arrow. In a cross-sectional view, the channel length L is a distance between an end portion of a region where the oxide semiconductor 230 is in contact with the conductor 220 and an end portion of a region where the oxide semiconductor 230 is in contact with the conductor 240. It can also be said that the channel length L corresponds to the distance between the top surface of the conductor 220b and the bottom surface of the conductor 240a in the cross-sectional view.

FIG. 1D is a cross-sectional view of the XY plane in a region between the conductor 220 and the conductor 240. As illustrated in FIG. 1D, the oxide semiconductor 230, the insulator 250, and the conductor 260 are provided concentrically in the opening portion 290 of the insulator 280. Thus, the side surface of the conductor 260 provided at the center faces the side surface of the oxide semiconductor 230 with the insulator 250 therebetween. That is, in the region between the conductor 220 and the conductor 240, the entire circumference of the oxide semiconductor 230 serves as the channel formation region.

At this time, when a depressed portion is not formed on the top surface of the conductor 220 and the top surface of the conductor 220 has a flat shape, the insulator 250 is formed over the conductor 220, and the bottom surface of the conductor 260 is at a higher level than the top surface of the conductor 220. In that case, the contact between the oxide semiconductor 230 and the conductor 220 is a bottom contact that is mainly made at the bottom surface of the oxide semiconductor 230. In the vicinity of the conductor 220, the structure in which the oxide semiconductor 230, the insulator 250, and the conductor 260 are provided concentrically as illustrated in FIG. 1D is not employed. Accordingly, an offset region is formed in the oxide semiconductor 230 in the vicinity of the conductor 220; thus, electrical characteristics such as on-state current, a subthreshold swing value (hereinafter, sometimes referred to as S value), field-effect mobility, and frequency characteristics of the transistor might be degraded.

In view of this, as described above, a depressed portion overlapping with the opening portion 290 is preferably formed in the conductor 220, and the conductor 260 is preferably provided to be embedded in the depressed portion. With such a structure, as illustrated in FIG. 2A, a level H1 of the bottom surface of the conductor 260 is lower than a level H2 of the top surface of the conductor 220 in a region not overlapping with the opening portion 290. Here, for the level H1 and the level H2, the bottom surface of the conductor 220 is used as a reference. In this case, the contact between the oxide semiconductor 230 and the conductor 220 is a side contact mainly made at the side surface of the oxide semiconductor 230. Furthermore, as described above, when a region where at least part of the bottom surface of the oxide semiconductor 230 is removed is formed and the insulator 250 is in contact with the conductor 220 in the region, the level H1 of the bottom surface of the conductor 260 in the region can be lower.

With the above structure, the oxide semiconductor 230, the insulator 250, and the conductor 260 can be provided concentrically even in a region in the vicinity of the conductor 220. Thus, in the region in the vicinity of the conductor 220, the conductor 260 and the side surface of the oxide semiconductor 230 can be provided to face each other with the insulator 250 therebetween. Thus, the electric field of the conductor 260 functioning as the gate electrode can be sufficiently applied to the oxide semiconductor 230 even in the vicinity of the conductor 220. In this manner, formation of the offset region in the oxide semiconductor 230 in the vicinity of the conductor 220 can be inhibited. Accordingly, the electrical characteristics such as on-state current, an S value, field-effect mobility, and frequency characteristics of the transistor 200 can be improved.

A planar transistor, whose channel length is limited by the light exposure limit of photolithography, has been difficult to further miniaturize. In the present invention, the channel length can be determined by the thickness of the insulator 280 over the conductor 220. Thus, the channel length L of the transistor 200 can be, for example, less than or equal to 1 μm, less than or equal to 500 nm, less than or equal to 100 nm, less than or equal to 60 nm, less than or equal to 50 nm, less than or equal to 40 nm, less than or equal to 30 nm, less than or equal to 20 nm, or less than or equal to 10 nm, and greater than or equal to 0.1 nm, greater than or equal to 1 nm, or greater than or equal to 5 nm. For example, when the transistor 200 has an extremely minute structure with the channel length below the light exposure limit of lithography, the on-state current, frequency characteristics, and the like can be improved. For example, when the channel length L is increased, DIBL (Drain Induced Barrier Lowering) can be inhibited and the electrical characteristics can be improved in the transistor 200.

In addition, as described above, the channel formation region, the source region, and the drain region can be formed in the opening portion 290. Thus, the area occupied by the transistor 200 can be reduced as compared with a planar transistor in which a channel formation region, a source region, and a drain region are provided separately on the XY plane. For example, in the transistor 200, the channel length L can be larger than the width in the X direction and the width in the Y direction while the area occupied by the transistor 200 is reduced. Accordingly, high integration of the semiconductor device can be achieved. In the case where the semiconductor device of one embodiment of the present invention is used for a memory device, the memory capacity per unit area can be increased.

As illustrated in FIG. 1D, the entire circumference of the oxide semiconductor 230 serves as the channel formation region in the region between the conductor 220 and the conductor 240. In this case, for example, the channel width of the transistor 200 is determined by the length of the outer circumference of the oxide semiconductor 230. In other words, the channel width of the transistor 200 is determined by the maximum width of the opening portion 290 (the maximum diameter in the case where the opening portion 290 is circular in the plan view). In FIG. 1B and FIG. 1D, a maximum width D of the opening portion 290 is indicated by a dashed double-dotted double-headed arrow. In FIG. 1D, a channel width W of the transistor 200 is indicated by a dashed-dotted double-headed arrow. By increasing the maximum width D of the opening portion 290, the channel width per unit area can be increased and the on-state current can be increased.

In the case where the opening portion 290 is formed by a lithography method, the maximum width D of the opening portion 290 is limited by the light exposure limit of lithography. In addition, the maximum width D of the opening portion 290 is determined by the thicknesses of the oxide semiconductor 230, the insulator 250, and the conductor 260 provided in the opening portion 290. The maximum width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 290 is circular in a plan view, the maximum width D of the opening portion 290 corresponds to the diameter of the opening portion 290, and the channel width W can be calculated by “D×π”.

In the case where the opening portion 290 is formed to be circular in a plan view, the oxide semiconductor 230, the insulator 250, and the conductor 260 are provided concentrically. This makes the distance between the conductor 260 and the oxide semiconductor 230 substantially uniform, so that a gate electric field can be substantially uniformly applied to the oxide semiconductor 230.

Although this embodiment describes the example where the opening portion 290 has a circular shape in the plan view, the present invention is not limited thereto. For example, the opening portion 290 in a plan view may have an almost circular shape such as an elliptical shape, a polygonal shape such as a quadrangular shape, or a polygonal shape such as a quadrangular shape with rounded corners. In that case, the maximum width of the opening portion 290 can be calculated as appropriate in accordance with the shape of the uppermost portion of the opening portion 290. For example, in the case where the opening portion is quadrangular in a plan view, the maximum width of the opening portion 290 can be regarded as the length of a diagonal line of the uppermost portion of the opening portion 290.

The sidewall of the opening portion 290 is preferably perpendicular to the top surface of the insulator 210. This structure enables miniaturization or high integration of the semiconductor device.

Although the opening portion 290 is provided such that the sidewall of the opening portion 290 is perpendicular to the top surface of the conductor 220 in FIG. 1B and FIG. 1C, the present invention is not limited thereto. For example, the sidewall of the opening portion 290 is not strictly perpendicular and has a tapered shape in some cases. The taper angle formed by the side surface of the insulator 280, which is part of the sidewall of the opening portion 290, and the top surface of the conductor 220 (which may be the top surface of the insulator 222 or the top surface of the insulator 210) is preferably 90° or an angle approximately 90°. For example, the taper angle is preferably greater than or equal to 75° and less than or equal to 90°.

The taper angle is sometimes less than 75°, less than 70°, less than 65°, or less than 60°. When the sidewall of the opening portion 290 has a tapered shape, the oxide semiconductor 230 and the insulator 250 can be formed with good coverage.

The oxide semiconductor 230 is in contact with the side surface of the conductor 240a on the opening portion 290 side, part of the top surface of the conductor 240a, the side surface of the conductor 240b on the opening portion 290 side, and the top surface of the conductor 240b. As illustrated in FIG. 1C, the side surface of the oxide semiconductor 230 is preferably aligned with the side surface of the conductor 240a that is on the side opposite to the opening portion 290 and the side surface of the conductor 240b that is on the side opposite to the opening portion 290. With such a structure, the oxide semiconductor 230, the conductor 240a, and the conductor 240b can be processed in the same step; thus, the manufacturing process of the semiconductor device can be simplified.

Although FIG. 1B illustrates the structure in which the oxide semiconductor 230 is placed to extend in the X direction, the present invention is not limited thereto. For example, the oxide semiconductor 230 may be an island shape.

Although FIG. 1C illustrates the structure in which the side surface of the oxide semiconductor 230 is aligned with the side surface of the conductor 240a and the side surface of the conductor 240b, the present invention is not limited thereto. For example, in the Y direction, the side surface of the oxide semiconductor 230 may be positioned inward from the side surface of the conductor 240a and the side surface of the conductor 240b. Alternatively, the side surface of the oxide semiconductor 230 may be positioned outward from the side surface of the conductor 240a and the side surface of the conductor 240b. In that case, the conductor 240a and the conductor 240b may be covered with the oxide semiconductor 230.

As the oxide semiconductor 230, a single layer or stacked layers of any of metal oxides described later in the section [Metal oxide] can be used.

As the oxide semiconductor 230, specifically, a metal oxide with a composition of In:M:Zn=1:3:2 [atomic ratio] or in the neighborhood thereof, a metal oxide with a composition of In:M:Zn=1:3:4 [atomic ratio] or in the neighborhood thereof, a metal oxide with a composition of In:M:Zn=1:1:0.5 [atomic ratio] or in the neighborhood thereof, a metal oxide with a composition of In:M:Zn=1:1:1 [atomic ratio] or in the neighborhood thereof, a metal oxide with a composition of In:M:Zn=1:1:1.2 [atomic ratio] or in the neighborhood thereof, a metal oxide with a composition of In:M:Zn=1:1:2 [atomic ratio] or in the neighborhood thereof, or a metal oxide with a composition of In:M:Zn=4:2:3 [atomic ratio] or in the neighborhood thereof may be used. Note that a composition in the neighborhood includes the range of ±30% of an intended atomic ratio. One or more of gallium, aluminum, and tin is preferably used as an element M.

The oxide semiconductor 230 may have a structure not containing the element M. For example, a metal oxide used as the oxide semiconductor 230 may be an In—Zn oxide. Specifically, the oxide semiconductor 230 can have a composition of In:Zn=1:1 [atomic ratio] or in the neighborhood thereof or a composition of In:Zn=4:1 [atomic ratio] or in the neighborhood thereof. Alternatively, an indium oxide may be used as the oxide semiconductor 230. The oxide semiconductor 230 may contain a slight amount of the element M. Specifically, the oxide semiconductor 230 can have a composition of In:Sn:Zn=4:0.1:1 [atomic ratio] or in the neighborhood thereof, for example.

For analysis of the composition of a metal oxide used as the oxide semiconductor 230, for example, energy dispersive X-ray spectroscopy (EDX), X-ray photoelectron spectroscopy (XPS), inductively coupled plasma-mass spectrometry (ICP-MS), or inductively coupled plasma-atomic emission spectrometry (ICP-AES) can be used. Alternatively, these methods may be combined for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A sputtering method or an atomic layer deposition (ALD) method can be suitably used to form the metal oxide. Note that in the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

Examples of an ALD method include a thermal ALD method, in which a precursor and a reactant react with each other only by a thermal energy, and a plasma ALD (PEALD: Plasma Enhanced ALD) method, in which a reactant excited by plasma is used.

An ALD method enables atomic layers to be deposited one by one, and has advantages such as formation of an extremely thin film, formation of a film on a component with a high aspect ratio or on a surface with a large step, formation of a film with few defects such as pinholes, formation of a film with excellent coverage, and low-temperature film formation. The use of plasma in a PEALD method is sometimes preferable because it enables deposition at a lower temperature. Note that a precursor used in the ALD method sometimes contains an element such as carbon or chlorine. Thus, in some cases, a film provided by an ALD method contains a larger amount of an element such as carbon or chlorine than a film provided by another film formation method. Note that these elements can be quantified by XPS or SIMS. The film formation method of a metal oxide of one embodiment of the present invention, which employs an ALD method and one or both of a film formation condition with a high substrate temperature and impurity removal treatment, can sometimes form a film with smaller amounts of carbon and chlorine than a method employing an ALD method without the film formation condition with a high substrate temperature or the impurity removal treatment.

Unlike a film formation method in which particles ejected from a target or the like are deposited, an ALD method is a film formation method in which a film is formed by reaction at a surface of an object to be processed. Thus, an ALD method is a film formation method that enables good step coverage almost regardless of the shape of an object. In particular, the ALD method enables excellent step coverage and excellent thickness uniformity and thus is suitable for covering a surface of an opening portion with a high aspect ratio, for example. On the other hand, the ALD method has a relatively low film formation rate, and thus is preferably used in combination with another film formation method with a high film formation rate, such as a sputtering method or a CVD method, in some cases. In the case where a metal oxide has a stacked-layer structure of a first metal oxide and a second metal oxide, a method in which the first metal oxide is formed by a sputtering method and the second metal oxide is formed by an ALD method over the first metal oxide can be given as an example. For example, in the case where the first metal oxide has a crystal part, crystal growth occurs in the second metal oxide with the use of the crystal part as a nucleus.

In the ALD method, the composition of a film to be formed can be controlled with the amount of introduced source gases. For example, a film with a certain composition can be formed by adjusting the amount of introduced source gases, the number of times of introduction (also referred to as the number of pulses), and the time required for one pulse (also referred to as the pulse time) in an ALD method. Moreover, for example, when the source gas is changed during the film formation in an ALD method, a film whose composition is continuously changed can be formed. In the case where the film is formed while the source gas is changed, as compared to the case where a film is formed using a plurality of film formation chambers, the time taken for the film formation can be shortened because the time taken for transfer and pressure adjustment is omitted. Thus, the productivity of the semiconductor device can be increased in some cases.

Note that there is no particular limitation on a method for forming an oxide semiconductor film to be the oxide semiconductor 230. For example, the oxide semiconductor film may be formed by a CVD method, an MBE method, a PLD method, or the like.

There is no particular limitation on the crystallinity of a semiconductor material used for the oxide semiconductor 230, and any of an amorphous semiconductor (a semiconductor having an amorphous structure), a single crystal semiconductor (a semiconductor having a single crystal structure), and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used because degradation of the transistor characteristics can be inhibited.

It is preferable that the oxide semiconductor 230 include a metal oxide layer having crystallinity. Examples of the structure of a metal oxide having crystallinity include a CAAC (c-axis aligned crystal) structure, a polycrystalline (Poly-crystal) structure, and a nano-crystal (nc) structure. With the use of the metal oxide layer having crystallinity for the oxide semiconductor 230, the density of defect states in the oxide semiconductor 230 can be reduced, which enables the semiconductor device to have high reliability. Note that the CAAC structure is a crystal structure in which a plurality of microcrystals (typically, a plurality of IGZO microcrystals) have c-axis alignment and the plurality of microcrystals are connected in an a-b plane without alignment. When the cross section of an OS film having the CAAC structure is observed with use of a high-resolution TEM image, it can be confirmed that metal atoms are arranged in a layered manner in the crystal parts. Thus, the CAAC structure of the OS film can also be referred to as a structure including the layered crystal parts.

The polycrystalline structure includes a crystal grain boundary. When an oxide semiconductor layer having a polycrystalline structure is formed and then subjected to heat treatment, a minute gap (also referred to as a nano crack or a micro crack) or a minute space (also referred to as a nano space or a micro space) can be formed between crystal parts. When a minute gap or a minute space is formed in the oxide semiconductor layer, the electric resistance of the oxide semiconductor layer is increased. This is because the electric resistance of the minute gap or the minute space is extremely high, for example, infinite. In the case where an oxide semiconductor layer including a minute gap or a minute space is used for a channel formation region of a transistor, the contact resistance between the oxide semiconductor layer and one or both of a source electrode and a drain electrode becomes high. This adversely affects initial characteristics or reliability of the transistor. A CAAC structure has a fewer crystal grain boundaries in the a-b plane than the polycrystalline structure; thus, a highly reliable semiconductor device can be achieved.

The higher the crystallinity of the metal oxide layer used for the oxide semiconductor 230 is, the lower the density of defect states in the oxide semiconductor 230 can be. By contrast, the use of a metal oxide layer having low crystallinity achieves a transistor through which a large amount of current can flow.

The higher the substrate temperature (the stage temperature) in the formation of the metal oxide layer is, the higher the crystallinity of the metal oxide layer can be. The metal oxide layer with higher crystallinity can be formed as the proportion of a flow rate of an oxygen gas to the whole film formation gas (also referred to as oxygen flow rate ratio) used in film formation is increased.

The crystallinity of the oxide semiconductor 230 can be analyzed with X-ray diffraction (XRD), a transmission electron microscope (TEM), or electron diffraction (ED), for example. Alternatively, these methods may be combined for the analysis.

Although a single layer of the oxide semiconductor 230 is illustrated in FIG. 1B and FIG. 1C, the present invention is not limited thereto. The oxide semiconductor 230 may have a stacked-layer structure of a plurality of oxide layers with different chemical compositions. For example, a structure may be employed in which a plurality of kinds of metal oxides selected from the metal oxides described later in the section [Metal oxide] are stacked as appropriate.

The oxide semiconductor 230 can have a stacked-layer structure of two or more metal oxide layers having different crystallinities. In that case, two or more metal oxide layers may have different compositions, or may have the same or substantially the same compositions. For example, as illustrated in FIG. 2A, the oxide semiconductor 230 may have a stacked-layer structure of an oxide semiconductor 230a and an oxide semiconductor 230b over the oxide semiconductor 230a. Here, the oxide semiconductor 230b can include a region having higher crystallinity than the oxide semiconductor 230a. Alternatively, the oxide semiconductor 230b can include a region having lower crystallinity than the oxide semiconductor 230a. Note that in the case where the oxide semiconductor 230b includes a region having lower crystallinity than the oxide semiconductor 230a, the crystallinity of the oxide semiconductor 230b can be increased by performing heat treatment (also referred to as crystallization treatment) after the formation of the oxide semiconductor 230b).

For example, it is preferable that the oxide semiconductor 230a be formed using a metal oxide with a composition of In:M:Zn=1:3:2 [atomic ratio] or in the neighborhood thereof or a metal oxide with a composition of In:M:Zn=1:3:4 [atomic ratio] or in the neighborhood thereof, and that the oxide semiconductor 230b be formed using a metal oxide with a composition of In:M:Zn=1:1:1 [atomic ratio] or in the neighborhood thereof. The use of a metal oxide in which the ratio of Zn to In is high for the oxide semiconductor 230a can increase the crystallinity of the oxide semiconductor 230a. Furthermore, forming the oxide semiconductor 230b over the oxide semiconductor 230a with high crystallinity facilitates increasing the crystallinity of the oxide semiconductor 230b. This is preferable because the crystallinity of the whole oxide semiconductor 230 can be increased. At this time, gallium, aluminum, or tin is particularly preferably used as the element M. For example, two IGZO layers having different compositions may be stacked. For another example, a stacked-layer structure of one selected from indium oxide, indium gallium oxide, and IGZO, and one selected from IAZO, IAGZO, and ITZO (registered trademark) may be employed.

The conductivity of a material used for the oxide semiconductor 230a is preferably different from the conductivity of a material used for the oxide semiconductor 230b.

For example, a material having higher conductivity than a material for the oxide semiconductor 230b can be used for the oxide semiconductor 230a. The use of the material having high conductivity for the oxide semiconductor 230a, which is in contact with the conductor 220 and the conductor 240 functioning as the source electrode and the drain electrode, can reduce the contact resistance between the oxide semiconductor 230 and the conductor 220 and the contact resistance between the oxide semiconductor 230 and the conductor 240, and thus the transistor can have high on-state current.

Here, in the case where a material having high conductivity is used for the oxide semiconductor 230b provided on the side of the conductor 260 functioning as the gate electrode, the threshold voltage of the transistor shifts and drain current flowing when the gate voltage is 0 V (hereinafter, also referred to as cutoff current) increases in some cases. Specifically, the threshold voltage may be low when the transistor 200 is an n-channel transistor. Thus, a material having lower conductivity than a material for the oxide semiconductor 230a is preferably used for the oxide semiconductor 230b. Accordingly, the transistor 200 can have high threshold voltage in the case where the transistor 200 is an n-channel transistor, in which case the transistor 200 can have low cut-off current. Note that low cutoff current is sometimes referred to as normally-off.

When the oxide semiconductor 230 has the stacked-layer structure and the material having higher conductivity than the material for the oxide semiconductor 230b is used for the oxide semiconductor 230a as described above, the transistor can have normally-off characteristics and high on-state current. Consequently, the semiconductor device can have both low power consumption and high performance.

The carrier concentration of the oxide semiconductor 230a is preferably higher than the carrier concentration of the oxide semiconductor 230b. Increasing the carrier concentration of the oxide semiconductor 230a results in higher conductivity thereof, which can reduce the contact resistance between the oxide semiconductor 230 and the conductor 220 and the contact resistance between the oxide semiconductor 230 and the conductor 240, and thus the transistor can have high on-state current. When the carrier concentration of the oxide semiconductor 230b is reduced, the conductivity is reduced, and thus the transistor can have normally-off characteristics.

Although the example in which a material having higher conductivity than a material for the oxide semiconductor 230b is used for the oxide semiconductor 230a is described here, the present invention is not limited thereto. A material having lower conductivity than a material for the oxide semiconductor 230b may be used for the oxide semiconductor 230a. The carrier concentration of the oxide semiconductor 230a can be lower than the carrier concentration of the oxide semiconductor 230b.

The band gap of the first metal oxide used for the oxide semiconductor 230a and the band gap of the second metal oxide used for the oxide semiconductor 230b are preferably different from each other. For example, the difference between the band gap of the first metal oxide and the band gap of the second metal oxide is preferably larger than or equal to 0.1 eV, further preferably larger than or equal to 0.2 eV, still further preferably larger than or equal to 0.3 eV.

The band gap of the first metal oxide used for the oxide semiconductor 230a can be smaller than the band gap of the second metal oxide used for the oxide semiconductor 230b. Thus, the contact resistance between the oxide semiconductor 230 and the conductor 220 and the contact resistance between the oxide semiconductor 230 and the conductor 240 can be reduced, and thus the transistor can have high on-state current. Furthermore, the transistor 200 can have high threshold voltage in the case where the transistor is an n-channel transistor; accordingly, the transistor 200 can be a normally-off transistor.

Although the example in which the band gap of the first metal oxide is smaller than the band gap of the second metal oxide is described here, the present invention is not limited thereto. The band gap of the first metal oxide can be larger than the band gap of the second metal oxide.

As described above, the band gap of the first metal oxide used for the oxide semiconductor 230a can be smaller than the band gap of the second metal oxide used for the oxide semiconductor 230b. The composition of the first metal oxide is preferably different from that of the second metal oxide. When the compositions of the first metal oxide and the second metal oxide are different from each other, the band gap can be controlled. For example, the content percentage of the element M in the first metal oxide is preferably lower than that of the element M in the second metal oxide. Specifically, in the case where the first metal oxide and the second 15 metal oxide are each an In-M-Zn oxide, the first metal oxide can have a composition of In:M:Zn=1:1:1 [atomic ratio] or in the neighborhood thereof, and the second metal oxide can have a composition of In:M:Zn=1:3:2 [atomic ratio] or in the neighborhood thereof. It is particularly preferable to use one or more of gallium, aluminum, and tin as the element M.

The first metal oxide may have a composition not including the element M. For example, the first metal oxide used for the oxide semiconductor 230a can be an In—Zn oxide, and the second metal oxide used for the oxide semiconductor 230b can be an In-M-Zn oxide. Specifically, the first metal oxide can be an In—Zn oxide, and the second metal oxide can be an In—Ga—Zn oxide. More specifically, the first metal oxide can have a composition of In:Zn=1:1 [atomic ratio] or in the neighborhood thereof or a composition of In:Zn=4:1 [atomic ratio] or in the neighborhood thereof, and the second metal oxide can have a composition of In:Ga:Zn=1:1:1 [atomic ratio] or in the neighborhood thereof. The first metal oxide may contain a slight amount of the element M. Specifically, the first metal oxide can have a composition of In:Sn:Zn=4:0.1:1 [atomic ratio] or in the neighborhood thereof, for example.

Although the example in which the content percentage of the element M in the first metal oxide is lower than the content percentage of the element M in the second metal oxide is described here, one embodiment of the present invention is not limited thereto. The content percentage of the element M in the first metal oxide may be higher than the content percentage of the element M in the second metal oxide. As long as the compositions of the first metal oxide and the second metal oxide are different from each other, the content percentages of elements other than the element M may be different from each other. Alternatively, the compositions of the first metal oxide and the second metal oxide can be the same as or substantially similar to each other. In that case, the formation methods for the first metal oxide and the second metal oxide are preferably different from each other.

In the case where the oxide semiconductor 230a and the oxide semiconductor 230b are formed by different methods, an ALD method and a sputtering method are preferably used. For example, a film of the first metal oxide used for the oxide semiconductor 230a can be formed by a sputtering method, and a film of the second metal oxide used for the oxide semiconductor 230b can be formed by an ALD method. For another example, a film of the first metal oxide used for the oxide semiconductor 230a can be formed by an ALD method, and a film of the second metal oxide used for the oxide semiconductor 230b can be formed by a sputtering method.

The thickness of the oxide semiconductor 230 is preferably greater than or equal to 3 nm and less than or equal to 200 nm, further preferably greater than or equal to 3 nm and less than or equal to 100 nm, still further preferably greater than or equal to 5 nm and less than or equal to 100 nm, yet still further preferably greater than or equal to 10 nm and less than or equal to 100 nm, yet still further preferably greater than or equal to 10 nm and less than or equal to 70 nm, yet still further preferably greater than or equal to 15 nm and less than or equal to 70 nm, yet still further preferably greater than or equal to 15 nm and less than or equal to 50 nm, yet still further preferably greater than or equal to 20 nm and less than or equal to 50 nm. In a transistor used for a more miniaturized semiconductor device, the thickness of the oxide semiconductor 230 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm.

The thicknesses of the layers included in the oxide semiconductor 230 (here, the oxide semiconductor 230a and the oxide semiconductor 230b) are determined such that the thickness of the oxide semiconductor 230 is within the above-described range. The thickness of the oxide semiconductor 230a can be determined such that the contact resistance between the oxide semiconductor 230a and the conductor 220 and the contact resistance between the oxide semiconductor 230a and the conductor 240 are within required ranges. The thickness of the oxide semiconductor 230b can be determined such that the threshold voltage of the transistor is within a required range. Note that the thickness of the oxide semiconductor 230a may be the same as or different from the thickness of the oxide semiconductor 230b.

The oxide semiconductor 230a and the oxide semiconductor 230b differ in the ratio between the thickness of a portion formed over the top surface of the conductor 240 and the thickness of a portion formed along the side surface of the conductor 240 and the side surface of the insulator 280 in some cases.

Although FIG. 2A illustrates the structure in which the oxide semiconductor 230 has the stacked-layer structure of the two layers of the oxide semiconductor 230a and the oxide semiconductor 230b, the present invention is not limited thereto. The oxide semiconductor 230 may have a stacked-layer structure of three or more layers.

For example, as illustrated in FIG. 2B, the oxide semiconductor 230 may have a stacked-layer structure of the oxide semiconductor 230a, the oxide semiconductor 230b over the oxide semiconductor 230a, and an oxide semiconductor 230c over the oxide semiconductor 230b. In other words, in the structure illustrated in FIG. 2A, the oxide semiconductor 230c may be provided between the insulator 250 and the oxide semiconductor 230b.

The atomic ratio of the element M to In in the metal oxide used for the oxide semiconductor 230a is preferably greater than the atomic ratio of the element M to In in the metal oxide used for the oxide semiconductor 230b. With such a structure, impurities and oxygen can be inhibited from diffusing into the oxide semiconductor 230b from the components formed outside the oxide semiconductor 230a. In addition, diffusion of the element contained in the insulator 280, the conductor 220, or the conductor 240 into the oxide semiconductor 230b can be inhibited.

In the case where a material having high conductivity is used for the oxide semiconductor 230c provided on the conductor 260 side functioning as the gate electrode, the threshold voltage of the transistor 200 shifts and cutoff current increases in some cases. Specifically, the threshold voltage may be low when the transistor 200 is an n-channel transistor. Thus, a material having lower conductivity than a material for the oxide semiconductor 230b is preferably used for the oxide semiconductor 230c. Accordingly, the transistor 200 can have high threshold voltage in the case where the transistor 200 is an n-channel transistor, in which case the transistor 200 can have low cut-off current.

As described above, when the material having higher conductivity than the material for the oxide semiconductor 230c is used for the oxide semiconductor 230b, the transistor can have normally-off characteristics and high on-state current. Consequently, the semiconductor device can have both low power consumption and high performance.

The carrier concentration of the oxide semiconductor 230b is preferably higher than the carrier concentration of the oxide semiconductor 230c. Increasing the carrier concentration of the oxide semiconductor 230b results in higher conductivity thereof, which enables the transistor to have high on-state current. When the carrier concentration of the oxide semiconductor 230c is reduced, the conductivity is reduced, and thus the transistor can have normally-off characteristics.

Although the example in which a material having higher conductivity than a material for the oxide semiconductor 230c is used for the oxide semiconductor 230b is described here, one embodiment of the present invention is not limited thereto. A material having lower conductivity than a material for the oxide semiconductor 230c may be used for the oxide semiconductor 230b. The carrier concentration of the oxide semiconductor 230b may be lower than the carrier concentration of the oxide semiconductor 230c.

The oxide semiconductor 230a and the oxide semiconductor 230c each preferably have a larger band gap than the oxide semiconductor 230b. Accordingly, the oxide semiconductor 230b is interposed between the pair of oxide semiconductors with a large band gap, and the oxide semiconductor 230b functions as a main current path (channel). When the oxide semiconductor 230b is interposed between the pair of oxide semiconductors, the trap states at and near the interfaces with the oxide semiconductor 230b can be reduced. Accordingly, a buried-channel transistor where a channel is distanced from the interface with an insulating layer can be achieved, whereby the field-effect mobility can be increased. Furthermore, the influence of interface states that can be formed on the back channel side is reduced, so that light deterioration (e.g., light negative bias deterioration) of the transistor can be inhibited and the reliability of the transistor can be increased.

The first metal oxide used for the oxide semiconductor 230a and the third metal oxide used for the oxide semiconductor 230c may have the same composition or different compositions.

For example, for the oxide semiconductor 230a and the oxide semiconductor 230c, a metal oxide with a composition of In:Ga:Zn=1:1:1 [atomic ratio] or in the neighborhood thereof, a metal oxide with a composition of In:Ga:Zn=1:3:2 [atomic ratio] or in the neighborhood thereof or a metal oxide with a composition of In:Ga:Zn=1:3:4 [atomic ratio] or in the neighborhood thereof may be used. For the oxide semiconductor 230b, it is preferable to use a metal oxide with a composition of In:Zn=1:1 [atomic ratio] or in the neighborhood thereof, a metal oxide with a composition of In:Zn=2:1 [atomic ratio] or in the neighborhood thereof, a metal oxide with a composition of In:Sn:Zn=2:0.1:1 [atomic ratio] or in the neighborhood thereof, a metal oxide with a composition of In:Zn=4:1 [atomic ratio] or in the neighborhood thereof, a metal oxide with a composition of In:Sn:Zn=4:0.1:1 [atomic ratio] or in the neighborhood thereof, or an indium oxide. With this structure, the transistor 200 can have high on-state current and high reliability with small variations.

Note that the oxide semiconductor 230a, the oxide semiconductor 230b, and the oxide semiconductor 230c may be formed by different methods. In that case, an ALD method and a sputtering method are preferably used. For example, a film of the first metal oxide used for the oxide semiconductor 230a can be formed by a sputtering method, a film of the second metal oxide used for the oxide semiconductor 230b can be formed by an ALD method, and a film of the third metal oxide used for the oxide semiconductor 230c can be formed by a sputtering method. For another example, a film of the first metal oxide used for the oxide semiconductor 230a can be formed by an ALD method, a film of the second metal oxide used for the oxide semiconductor 230b can be formed by a sputtering method, and a film of the third metal oxide used for the oxide semiconductor 230c can be formed by an ALD method.

At the time of forming the oxide semiconductor layer with the two-layer structure, two kinds of film formation methods, which are a sputtering method and an ALD method, are preferably used. For example, after a first oxide semiconductor layer having a CAAC structure is formed by a sputtering method, a second oxide semiconductor layer having lower crystallinity than the CAAC structure is formed by an ALD method, in which case, an atomic layer of the second oxide semiconductor layer is expected to fill or repair an atomic-level gap between crystal parts included in the CAAC structure of the first oxide semiconductor layer. After the second oxide semiconductor layer is formed by an ALD method, heat treatment (e.g., at higher than or equal to 100 °C and lower than or equal to 500 °C, preferably higher than or equal to 200 °C and lower than or equal to 450 °C, further preferably higher than or equal to 300 °C and lower than or equal to 400 °C) is preferably performed. By the heat treatment, the atomic-level gap between crystal parts included in the CAAC structure of the first oxide semiconductor layer is expected to be repaired by the second oxide semiconductor layer (in other words, crystal molecules formed by an ALD method). The oxide semiconductor layer formed by the two kinds of film formation methods may be referred to as a Hybrid OS.

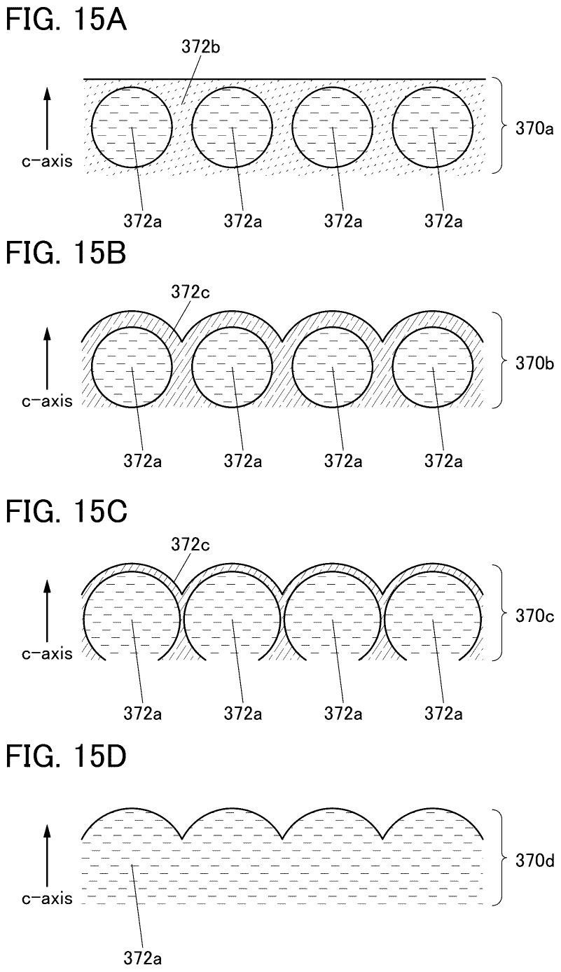

Here, a concept of the heat treatment that increases the crystallinity of an oxide semiconductor layer is described with reference to FIG. 15A, FIG. 15B, FIG. 15C, and FIG. 15D. Note that FIG. 15A, FIG. 15B, FIG. 15C, and FIG. 15D are conceptual diagrams each illustrating a cross section of an oxide semiconductor layer having a CAAC structure. In each of the diagrams, the c-axis is indicated by an arrow.

An oxide semiconductor layer 370a illustrated in FIG. 15A includes regions 372a and a region 372b positioned between the regions 372a. The regions 372a each correspond to a region having a CAAC structure (i.e., a structure including a layered crystal part), and the region 372b corresponds to a region between the CAAC structures. The CAAC structure has fewer crystal grain boundaries in the a-b plane than a polycrystalline structure. As described above, even in the oxide semiconductor layer 370a having the CAAC structure, a minute gap or a minute space (the region 372b in FIG. 15A) can exist between crystal parts, in some cases.

In view of the above, in order to increase the crystallinity of an oxide semiconductor layer, in other words, in order to reduce the region 372b illustrated in FIG. 15A, after an oxide semiconductor layer having a CAAC structure is formed by a sputtering method as the first oxide semiconductor layer, an oxide semiconductor layer having a microcrystalline structure or an amorphous structure with lower crystallinity than the CAAC structure is formed by an ALD method as the second oxide semiconductor layer.

Specifically, as illustrated in FIG. 15B, after an oxide semiconductor layer including the regions 372a is formed by a sputtering method as the first oxide semiconductor layer, an oxide semiconductor layer including a region 372c having lower crystallinity than the CAAC structure is formed by an ALD method as the second oxide semiconductor layer. In FIG. 15B, an oxide semiconductor layer 370b includes the regions 372a and the region 372c. Since atomic layers can be deposited one by one by an ALD method, the second oxide semiconductor layer can be formed so as to fill the region 372b.

Then, heat treatment is performed, whereby the regions 372a included in the first oxide semiconductor layer serve as seeds and the crystallinity of the region 372c included in the second oxide semiconductor layer is increased. In other words, the regions 372a included in the first oxide semiconductor layer serve as seeds, whereby crystal growth of the region 372c included in the second oxide semiconductor layer can be achieved. Alternatively, the regions 372a of the first oxide semiconductor layer having the CAAC structure serve as nuclei, whereby crystal growth of the region 372c included in the second oxide semiconductor layer having the amorphous structure can be achieved. The model of this crystal growth can be regarded as a concept equivalent to hetero epitaxy. In FIG. 15C, an oxide semiconductor layer 370c includes the regions 372a and the region 372c. The regions 372a illustrated in FIG. 15C are each a region with higher crystallinity or higher density of crystal parts than the regions 372a illustrated in FIG. 15B. By the heat treatment, the crystallinity of one or both of the regions 372a and the region 372c can be increased. The region 372c includes a crystal part having the same crystal structure as the crystal part included in the regions 372a, for example. Alternatively, the region 372c includes a crystal part that is connected with the crystal part included in the regions 372a, for example.

In FIG. 15D, an oxide semiconductor layer 370d includes the region 372a. The region 372a is a region having higher crystallinity than the regions 372a illustrated in FIG. 15B and FIG. 15C, where there is no boundary between the region 372a and the region 372c or a boundary is not observed between the region 372a and the region 372c. Thus, the entire oxide semiconductor layer 370d has a CAAC structure. When the entire oxide semiconductor layer 370d has a CAAC structure as illustrated in FIG. 15D, a highly reliable semiconductor device can be achieved. Whether there is a boundary between the region 372a and the region 372c can be checked with a cross-sectional TEM, a cross-sectional STEM, or the like, for example.

Even in the case where a minute gap or a minute space is included in the first oxide semiconductor layer, forming the second oxide semiconductor layer over the first oxide semiconductor layer or forming the second oxide semiconductor layer and performing heat treatment can fill the minute gap or the minute space in the first oxide semiconductor layer. When an oxide semiconductor layer having a CAAC structure is used as the first oxide semiconductor layer and an oxide semiconductor layer having a microcrystalline structure or an amorphous structure is used as the second oxide semiconductor layer in this manner, a dense oxide semiconductor layer with increased crystallinity density can be provided. When the dense oxide semiconductor layer with increased crystallinity density is used in a channel formation region of a transistor, an increase in electric resistance of the oxide semiconductor layer can be inhibited or initial characteristics (particularly on-state current) of the transistor can be improved; thus, the transistor suitable for high-speed operation can be expected.

In the case where an oxide semiconductor layer is formed by both a sputtering method and an ALD method and an oxide semiconductor layer formed by an ALD method is thin, the oxide semiconductor layer can be regarded as not having a stacked-layer structure of an oxide semiconductor layer formed by a sputtering method and the oxide semiconductor layer formed by an ALD method, but having a single-layer structure. For example, when the thickness of the oxide semiconductor layer formed by an ALD method is greater than 0 nm and less than or equal to 3 nm, preferably greater than 0 nm and less than or equal to 2 nm, further preferably greater than 0 nm and less than or equal to 1 nm, the oxide semiconductor layer formed by two kinds of film formation methods, which are a sputtering method and an ALD method, can be regarded as having a single-layer structure. On the other hand, when the thickness of the oxide semiconductor layer formed by an ALD method exceeds 3 nm, the oxide semiconductor layer can be sometimes regarded as having a stacked-layer structure, a multilayer structure, or a multi-structure of the oxide semiconductor layer formed by a sputtering method and the oxide semiconductor layer formed by an ALD method.

In the case where the oxide semiconductor layer is formed by both a sputtering method and an ALD method, different compositions are preferably employed. Typically, a metal oxide with a composition of In:Ga:Zn=1:1:1 [atomic ratio] or in the neighborhood thereof can be formed by a sputtering method, and then a metal oxide with a composition of In:Ga:Zn=4:0.1:1 [atomic ratio] or in the neighborhood thereof can be formed by an ALD method. The oxide semiconductor layer having the above composition can have high reliability owing to the metal oxide layer with In:Ga:Zn=1:1:1 [atomic ratio] and have high on-state current or high field-effect mobility owing to the metal oxide with a composition of In:Ga:Zn=4:0.1:1 [atomic ratio]or in the neighborhood thereof. Instead of the metal oxide with a composition of In:Ga:Zn=4:0.1:1 [atomic ratio] or in the neighborhood thereof, a metal oxide with In:Ga:Zn=1:0:0 [atomic ratio], that is, indium oxide or a metal oxide with a high In proportion can be used.

The oxide semiconductor layer formed by the two kinds of film formation methods can be regarded as having a structure where a gap between crystal parts included in the CAAC structure is filled with an atomic layer formed by an ALD method. Note that this structure can be analyzed by analysis methods such as a cross-sectional SEM, a cross-sectional STEM, a cross-sectional TEM, SIMS, and EDX.

The oxide semiconductor layer having a CAAC structure formed by the two kinds of film formation methods sometimes has one or more of a higher relative permittivity, higher film density, and higher film hardness than the oxide semiconductor layer having a CAAC structure formed by one kind of film formation method. With the use of the oxide semiconductor layer having the CAAC structure formed by two kinds of film formation methods in a channel formation region of a transistor as described above, a transistor with excellent characteristics (e.g., a transistor with high on-state current, a transistor with high field-effect mobility, a transistor with a small S value, a transistor with high frequency characteristics (also referred to as f characteristics), or a transistor with high reliability) can be achieved.

In order to improve the electrical characteristics and reliability of an OS transistor, it is important to sufficiently reduce the hydrogen concentration in the channel formation region of the oxide semiconductor. For example, the hydrogen concentration in the channel formation region of the oxide semiconductor, which is obtained by secondary ion mass spectrometry (SIMS), is preferably lower than 1×10²⁰ atoms/cm³, further preferably lower than 5×10¹⁹ atoms/cm³, still further preferably lower than 1×10¹⁹ atoms/cm³, yet further preferably lower than 5×10¹⁸ atoms/cm³, yet still further preferably lower than 1×10¹⁸ atoms/cm³, yet still further preferably lower than 1×10¹⁷ atoms/cm³.

Thus, a barrier insulator against hydrogen is preferably used as each of the insulator 210 and the insulator 283. The insulator 210 and the insulator 283 are provided such that the transistor 200 including the oxide semiconductor 230 is interposed therebetween. When the insulator 210 and the insulator 283 provided outside the oxide semiconductor 230 has a barrier property against hydrogen, diffusion of hydrogen into the oxide semiconductor 230 can be inhibited.

In this specification and the like, a barrier insulator refers to an insulator having a barrier property. In addition, the barrier property refers to a property that does not easily allow diffusion of a target substance (also referred to as a property that does not easily allow passage of a target substance, a property with low permeability to a target substance, or a function of inhibiting diffusion of a target substance). In addition, hydrogen described as a target substance refers to at least one of a hydrogen atom, a hydrogen molecule, and a substance bonded to hydrogen, such as a water molecule or OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule.

Examples of the barrier insulator against hydrogen include aluminum oxide, magnesium oxide, hafnium oxide, gallium oxide, indium gallium zinc oxide, silicon nitride, and silicon nitride oxide.

Silicon nitride is preferably used for the insulator 210 and the insulator 283, for example. In that case, the insulator 210 and the insulator 283 each contain silicon and nitrogen.

Silicon nitride that can be used for the insulator 210 and the insulator 283 has a barrier property against hydrogen when having a thickness of 2 nm or more, for example. In order to have a higher barrier property against hydrogen, silicon nitride preferably has a film thickness of 3 nm or more, further preferably 5 nm or more. Note that silicon nitride has a barrier property against oxygen when having a film thickness of 1 nm or more, for example. In order to have a higher barrier property against oxygen, silicon nitride preferably has a film thickness of 2 nm or more. That is, silicon nitride formed with a film thickness enabling a barrier property against hydrogen also has a barrier property against oxygen.

As the insulator 222, an insulator having a function of capturing or fixing hydrogen is preferably used. When the insulator 222 has a function of capturing or fixing hydrogen, the hydrogen concentration in the oxide semiconductor 230 positioned inside the insulator 210 and the insulator 283 can be reduced. In this case, hydrogen in the oxide semiconductor 230 is captured or fixed by the insulator 222, so that the hydrogen concentration in the insulator 222 increases. For example, the hydrogen concentration in at least part of the insulator 222 obtained by SIMS may be higher than or equal to 1×10¹⁹ atoms/cm³ or higher than or equal to 1×10²⁰ atoms/cm³. In that case, the hydrogen concentration of at least part of the insulator 222 is higher than that of the oxide semiconductor 230. In other words, the oxide semiconductor 230 includes a region having a lower hydrogen concentration than the insulator 222.

Note that a function of capturing or fixing a target substance can also be referred to as a property that does not easily allow diffusion of a target substance. Thus, the function of capturing or fixing a target substance can be rephrased as a barrier property.

As the insulator having a function of capturing or fixing hydrogen, a metal oxide containing hafnium or the like (e.g., hafnium oxide) is preferable. The metal oxide preferably contains an oxygen atom having a dangling bond. Such a metal oxide has a property of capturing or fixing hydrogen with the dangling bond in some cases. For example, the above-described metal oxide preferably has an amorphous structure. This is because some oxygen atoms in a metal oxide having an amorphous structure have dangling bonds. Although the metal oxide preferably has an amorphous structure, a crystal region is partly formed in some cases. The metal oxide partly has a crystal grain boundary in some cases.

Here, addition of silicon to hafnium oxide can inhibit polycrystallization of hafnium oxide. That is, an oxide containing hafnium and silicon (hereinafter, sometimes referred to as hafnium silicate) is likely to have an amorphous structure. Thus, hafnium silicate has a property of capturing or fixing hydrogen and is suitable as the insulator 222. In this case, the insulator 222 contains hafnium, silicon, and oxygen.

Although an oxide containing hafnium is given above as an example of the insulator having a function of capturing or fixing hydrogen, the present invention is not limited thereto. Examples of the insulator include an oxide containing magnesium, an oxide containing aluminum, and an oxide containing aluminum and hafnium (hafnium aluminate). Alternatively, the above-described metal oxide further containing zirconium may be used. For example, an oxide containing hafnium and zirconium can be given. These metal oxides preferably have an amorphous structure by addition of silicon oxide.

The insulator 280 is provided to cover the conductor 220 and is in contact with the side surface of the oxide semiconductor 230 and the bottom surface of the conductor 240. The insulator 280 is preferably formed using a material with a low relative permittivity. Accordingly, the insulator 280 functions as an interlayer insulating film, so that the parasitic capacitance between the conductor 240 and the conductor 220 can be reduced. Accordingly, the transistor 200 can have improved frequency characteristics.

As the insulator 280, a single layer or stacked layers of any of insulators each containing a material with a low relative permittivity described in the later-described section [Insulator] can be used. Specifically, silicon oxide or silicon oxynitride can be used for the insulator 280. The concentration of impurities such as water and hydrogen in the insulator 280 is preferably reduced. This can inhibit entry of impurities such as water and hydrogen into the channel formation region of the oxide semiconductor 230.

As the insulator 280, an insulator containing oxygen is preferably used. When the insulator 280 has a high oxygen content, oxygen is easily supplied to the oxide semiconductor 230 in contact with the insulator 280 to reduce oxygen vacancies.

It is further preferable that a film from which oxygen is released by heating be used as the insulator 280. When the insulator 280 releases oxygen by being heated during the fabrication process of the transistor 200, the oxygen can be supplied to the oxide semiconductor 230. Supply of oxygen from the insulator 280 to the oxide semiconductor 230, particularly to the channel formation region of the oxide semiconductor 230, can reduce oxygen vacancies and VoH in the channel formation region of the oxide semiconductor 230, so that the transistor can have favorable electrical characteristics and high reliability.

For example, the amount of oxygen molecules released from the insulator 280b is preferably greater than or equal to 1.0×10¹⁴ molecules/cm² and less than 1.0×10¹⁵ molecules/cm². Note that the amount of released oxygen molecules can be measured by thermal desorption spectrometry.

Particularly in the case where the channel length of the transistor 200 is short, oxygen vacancies and VoH in the channel formation region significantly affect the electrical characteristics and reliability. Accordingly, when the hydrogen concentration in the oxide semiconductor 230 is sufficiently reduced and the amount of oxygen supplied to the oxide semiconductor 230 is optimized, a transistor with a short channel length, favorable electrical characteristics, and high reliability can be provided.

The insulator 280 is preferably formed by a film formation method such as a sputtering method or a plasma-enhanced chemical vapor deposition (PECVD) method. It is particularly preferable to employ a sputtering method, in which a hydrogen gas does not need to be used as a film formation gas, to form a film having an extremely low hydrogen content. Thus, supply of hydrogen to the oxide semiconductor 230 is inhibited and the electrical characteristics of the transistor 200 can be stabilized.

In the case where the amount of oxygen supplied to the oxide semiconductor 230 is increased, heat treatment in an oxygen-containing atmosphere or plasma treatment in an oxygen-containing atmosphere is preferably performed after formation of the insulator 280, for example. Alternatively, an oxide film may be formed over the top surface of the insulator 280 by a sputtering method in an oxygen atmosphere to supply oxygen. After that, the oxide film may be removed. Such treatment can supply oxygen to the insulator 280 and increase the amount of oxygen supplied to the oxide semiconductor 230.

The above barrier insulator against hydrogen can also be used as the insulator 280. For example, silicon nitride is used for the insulator 280. Such a structure can inhibit diffusion of hydrogen into the oxide semiconductor 230. The concentration of impurities such as water and hydrogen in the insulator 280 is preferably reduced. This can inhibit entry of impurities such as water and hydrogen into the channel formation region of the oxide semiconductor 230.

As illustrated in FIG. 2A, the insulator 280 may have a stacked-layer structure of an insulator 280a, an insulator 280b over the insulator 280a, and an insulator 280c over the insulator 280b.

The insulator 280a includes a region in contact with the top surface of the insulator 222, a region in contact with the side surface of the conductor 220, and a region in contact with the top surface of the conductor 220. The insulator 280c includes a region in contact with the bottom surface of the conductor 240.

The insulator 280b is formed using any of the insulating materials that can be used for the insulator 280. Specifically, silicon oxide or silicon oxynitride can be used for the insulator 280b. The concentration of impurities such as water and hydrogen in the insulator 280b is preferably reduced.

In the case where an insulator containing oxygen is used as the insulator 280b, any of barrier insulators against oxygen described later in the section [Insulator] is preferably used as each of the insulator 280a and the insulator 280c. The insulator 280a provided between the insulator 280b and the conductor 220 can inhibit oxidation of the conductor 220 and an increase in the resistance of the conductor 220. The insulator 280c provided between the insulator 280b and the conductor 240 can inhibit oxidation of the conductor 240 and an increase in the resistance of the conductor 240.

As each of the insulator 280a and the insulator 280c, a barrier insulator against hydrogen can be used. Thus, the insulator 280b can be sandwiched between barrier insulators against hydrogen. Thus, diffusion of hydrogen into the insulator 280b from below the insulator 280a or above the insulator 280c can be inhibited. A silicon nitride film and a silicon nitride oxide film can be suitably used for the insulator 280a and the insulator 280c because they release fewer impurities (e.g., water and hydrogen) and are less likely to transmit oxygen and hydrogen. For the insulator 280a and the insulator 280c, the same material or different materials may be used.

An insulator having a function of capturing or fixing hydrogen may be used as one or both of the insulator 280a and the insulator 280c. With such a structure, diffusion of hydrogen from below the insulator 280a or above the insulator 280c into the insulator 280b can be inhibited, and hydrogen contained in the insulator 280b can be captured or fixed. Thus, the hydrogen concentration in the oxide semiconductor 230 and its vicinity can be reduced. For the insulator 280a, magnesium oxide, aluminum oxide, hafnium oxide, an oxide containing hafnium and silicon, or the like can be used. Alternatively, for example, a stacked-layer film of aluminum oxide and silicon nitride over the aluminum oxide may be used as the insulator 280a. Alternatively, for example, a stacked-layer film of silicon nitride and aluminum oxide over the silicon nitride may be used for the insulator 280c.

For example, silicon nitride can be used for the insulator 280a and the insulator 280c, and silicon oxide can be used for the insulator 280b. In that case, each of the insulator 280a and the insulator 280c contains at least silicon and nitrogen. The insulator 280b contains at least silicon and oxygen.

Although FIG. 2A illustrates the structure in which the insulator 280c is provided over the planarized insulator 280b, the present invention is not limited thereto. For example, the insulator 280c may be formed without performing planarization treatment on the insulator 280b. When planarization treatment is not performed, the manufacturing cost can be reduced and the production yield can be increased. In addition, the insulator 280a, the insulator 280b, and the insulator 280c can be successively formed without exposure to the air. By the formation without exposure to the air, impurities or moisture from the atmospheric environment can be prevented from being attached onto the insulator 280a to the insulator 280c, so that the vicinity of the interface between the insulator 280a and the insulator 280b and the vicinity of the interface between the insulator 280b and the insulator 280c can be kept clean.

A region of the oxide semiconductor 230 that is in contact with the insulator 280a and a region of the oxide semiconductor 230 that is in contact with the insulator 280c are supplied with a smaller amount of oxygen than a region of the oxide semiconductor 230 that is in contact with the insulator 280b. Thus, the region of the oxide semiconductor 230 that is in contact with the insulator 280a and the region of the oxide semiconductor 230 that is in contact with the insulator 280c each have a low resistance in some cases. That is, by adjusting the thickness of the insulator 280a, the range of the region functioning as one of the source region and the drain region can be controlled. Similarly, by adjusting the thickness of the insulator 280c, the range of the region functioning as the other of the source region and the drain region can be controlled. Accordingly, the film thicknesses of the insulator 280a and the insulator 280c can be set as appropriate in accordance with the characteristics required for the transistor 200.

Although FIG. 2A illustrates the structure in which the insulator 280 has a stacked-layer structure of three layers, the present invention is not limited thereto. The insulator 280 may have a stacked-layer structure of two layers or four or more layers.

The insulator 270 is provided to cover the conductor 240 and the oxide semiconductor 230. The insulator 270 is preferably formed using a material with a low relative permittivity. Accordingly, the insulator 270 functions as an interlayer insulating film, so that the parasitic capacitance between the conductor 260 and the conductor 240 can be reduced. Accordingly, the transistor 200 can have improved frequency characteristics. The insulator 270 can be formed using any of the insulating materials that can be used for the insulator 280. Specifically, silicon oxide or silicon oxynitride can be used for the insulator 270. The concentration of impurities such as water and hydrogen in the insulator 270 is preferably reduced.

As illustrated in FIG. 1C, the insulator 270 preferably covers the end portion of the side surface of the oxide semiconductor 230, the end portion of the side surface of the conductor 240a, and the end portion of the side surface of the conductor 240b. This can prevent a short circuit between the conductor 260 and the oxide semiconductor 230, the conductor 240a, and the conductor 240b.

The conductor 240 preferably includes the conductor 240a and the conductor 240b over the conductor 240a. The conductor 240a has the opening portion 290 in a region overlapping with the conductor 220. As illustrated in FIG. 1B and FIG. 1C, the side surface of the conductor 240b on the opening portion 290 side is receded from the side surface of the conductor 240a on the opening portion 290 side. In other words, the side surface of the conductor 240a on the opening portion 290 side is positioned closer to the opening portion 290 than the side surface of the conductor 240b on the opening portion 290 side.

It is preferable that the conductor 240a not be provided in the opening portion of the insulator 280. That is, it is preferable that the conductor 240a not include a region in contact with the side surface of the insulator 280 in the opening portion 290. With such a structure, the opening portion of the conductor 240a and the opening portion of the insulator 280 can be collectively formed. When the side surface of the conductor 240a in the opening portion 290 is aligned with the side surface of the insulator 280 in the opening portion 290, the thickness distribution of the oxide semiconductor 230 provided in the opening portion 290 can be uniform. In addition, the oxide semiconductor 230 can be inhibited from being divided by a step between the conductor 240a and the insulator 280.

Although FIG. 1B and FIG. 1C illustrate the structure in which the side surface of the conductor 240a in the opening portion 290 is aligned with the side surface of the insulator 280 in the opening portion 290, the present invention is not limited thereto. For example, the side surface of the conductor 240a in the opening portion 290 and the side surface of the insulator 280 in the opening portion 290 may be discontinuous. The inclination of the side surface of the conductor 240a in the opening portion 290 and the inclination of the side surface of the insulator 280 in the opening portion 290 may be different from each other. In that case, for example, the angle between the side surface of the conductor 240a in the opening portion 290 and the top surface of the insulator 210 is preferably smaller than the angle between the side surface of the insulator 280 in the opening portion 290 and the top surface of the insulator 210. With such a structure, the coverage of the side surface of the conductor 240a with the oxide semiconductor 230 in the opening portion 290 is improved, so that the number of defects such as voids can be reduced.

The conductor 240 preferably has a stacked-layer structure. For example, the conductor 240 preferably has a stacked-layer structure of the conductor 240a and the conductor 240b in contact with the top surface of the conductor 240a.

The bottom surface of the conductor 240a is in contact with the insulator 280, one of the side surfaces and part of the top surface of the conductor 240a are in contact with the oxide semiconductor 230, and the other side surface of the conductor 240a is in contact with the insulator 270.

The conductor 240a is preferably in ohmic contact with the oxide semiconductor 230 and preferably has low contact resistance with the oxide semiconductor 230. For example, the contact resistance between the conductor 240a and the oxide semiconductor 230 is preferably lower than the contact resistance between the metal layer used for the conductor 240b and the oxide semiconductor 230. Thus, for the conductor 240a, a metal oxide having conductivity (sometimes referred to as a conductive oxide) is preferably used. As described above, when the side surface of the conductor 240b is receded and one of the side surfaces and part of the top surface of the conductor 240a are in contact with the oxide semiconductor 230, the contact area between the conductor 240a and the oxide semiconductor 230 can be increased. Thus, the contact resistance between the conductor 240a and the oxide semiconductor 230 can be further reduced. When the conductor 240a has the above structure, the on-state current, the field-effect mobility, the S value, and the frequency characteristics of the transistor 200 can be improved.

As a conductive oxide (OC: Oxide Conductor, also referred to as a conductive material containing oxygen) used for the conductor 240a, a conductive oxide containing indium is preferable. As the conductive oxide containing indium, indium oxide, indium tin oxide (also referred to as ITO in some cases), indium zinc oxide, indium tin oxide to which silicon is added (also referred to as ITSO), or the like is preferably used. Furthermore, tungsten, titanium, or the like may be contained in indium oxide; for example, In—W oxide, In—W—Zn oxide, In—Ti oxide, In—Ti—Sn oxide, or the like may be used. Alternatively, a conductive oxide containing zinc may be used; for example, zinc oxide, zinc oxide to which gallium is added, In—Ga—Zn oxide, or the like can be used. As the conductive oxide, ruthenium oxide, an oxide including strontium and ruthenium, an oxide including lanthanum and nickel, or the like can also be used. A conductive oxide containing indium is particularly preferable because of its high conductivity.

For example, indium tin oxide to which silicon is added can be used for the conductor 240a. In this case, the conductor 240a contains indium, tin, silicon, and oxygen. Here, the addition of silicon to the indium tin oxide can inhibit polycrystallization of the indium tin oxide. That is, indium tin oxide to which silicon is added is likely to have an nc structure (a nano-crystal structure) or an amorphous structure. Note that the present invention is not limited to the above.

Polycrystalline indium tin oxide can also be used for the conductor 240a. In this case, the conductor 240a contains indium, tin, and oxygen.

One of the side surfaces and the top surface of the conductor 240b are in contact with the oxide semiconductor 230. The bottom surface of the conductor 240b is in contact with the conductor 240a. The other of the side surfaces of the conductor 240b is in contact with the insulator 270.

For the conductor 240b, a metal having higher conductivity than that for the conductor 240a is preferably used. For the conductor 240b, a metal having lower sheet resistance than the conductor 240a is preferably used. With such a structure, the conductor 240 including the conductor 240b can function as a wiring electrically connected to one of the source electrode and the drain electrode.

For the conductor 240b, one or more of ruthenium, tantalum, nickel, titanium, molybdenum, tungsten, hafnium, vanadium, niobium, aluminum, chromium, copper, silver, gold, platinum, zinc, manganese, iron, cobalt, magnesium, zirconium, beryllium, indium, iridium, strontium, and lanthanum, an alloy including one or more of these metals as its components, or the like can be used. For example, tungsten is preferably used for the conductor 240b.

Part of the conductor 240b contains a metal oxide of the above metal in some cases. In that case, a layer of the metal oxide is sometimes formed in the conductor 240b in the vicinity of an interface with the conductor 240a and in the vicinity of an interface with the oxide semiconductor 230. Here, ruthenium and an alloy of ruthenium are preferable because they are materials that maintain relatively low electric resistance even after oxidized.

Although the example in which the conductor 240 has a stacked-layer structure of two layers of the conductor 240a and the conductor 240b is described above, the present invention is not limited thereto. The conductor 240 may have a stacked-layer structure of three or more layers. Although the structure in which the conductor 240b is stacked over the conductor 240a is described above, the present invention is not limited thereto. A structure in which the conductor 240a is stacked over the conductor 240b can be employed.

The conductor 220 is provided over the insulator 222 and can have an island shape as illustrated in FIG. 1B and FIG. 1C. In the case where the conductor 220 has an island shape, a conductor functioning as a via can be formed under the conductor 220, and the conductor 220 can be connected to a wiring layer provided below the insulator 210. Alternatively, the conductor 220 can be extended in either the X direction or the Y direction to make the conductor 220 function as a wiring.

As the conductor 220, a single layer or stacked layers of any of the conductors described later in the section [Conductor] can be used. A conductive material that is less likely to be oxidized, a conductive material having a function of inhibiting diffusion of oxygen, or the like is preferably used for the conductor 220. For example, titanium nitride, tantalum nitride, or the like can be used.

Furthermore, as illustrated in FIG. 1B and FIG. 1C, the conductor 220 preferably has a stacked-layer structure of the conductor 220a and the conductor 220b over the conductor 220a. Here, a metal having high conductivity is preferably used for the conductor 220a. Thus, a metal that can be used for the conductor 240b can be used for the conductor 220a, for example. Tungsten may be used for the conductor 220a, for example. With such a structure, the conductor 220 including the conductor 220a can function as a wiring electrically connected to the other of the source electrode and the drain electrode.

As illustrated in FIG. 2A, a structure in which a conductor 220c is additionally provided under the conductor 220a may be employed. The conductive material that is less likely to be oxidized, the conductive material having a function of inhibiting diffusion of oxygen, or the like is preferably used for the conductor 220c. For example, titanium nitride, tantalum nitride, or the like can be used. When such a conductor 220c is provided, oxidation of the conductor 220b can be inhibited and a reduction in conductivity of the conductor 220b can be inhibited.

As the conductor 220b in contact with the oxide semiconductor 230, a conductive oxide is preferably used. Thus, for example, a conductive oxide that can be used for the conductor 240a may be used for the conductor 220b. For example, indium tin oxide to which silicon is added can be used for the conductor 220b. In this case, the conductor 220b contains indium, tin, silicon, and oxygen. Accordingly, the conductor 220b can be in ohmic contact with the oxide semiconductor 230, so that the contact resistance between the conductor 220b and the oxide semiconductor 230 can be reduced. Thus, the on-state current, field-effect mobility, and frequency characteristics of the transistor 200 can be improved.

As illustrated in FIG. 1B, FIG. 1C, FIG. 2A, and FIG. 2B, a depressed portion connected to the opening portion 290 is preferably formed on the top surface of the conductor 220b. With the structure in which the oxide semiconductor 230 is in contact with the side surface of the depressed portion, the area where the conductor 220b and the oxide semiconductor 230 are in ohmic contact with each other can be increased, so that the contact resistance between the conductor 220b and the oxide semiconductor 230 can be further reduced. The formation of the depressed portion in the conductor 220b can prevent the conductor 220a from being in contact with the oxide semiconductor 230 and can prevent excessive oxidation of the conductor 220a.

Although FIG. 1B and the like illustrate a structure in which the depressed portion connected to the opening portion 290 reaches the conductor 220b, the present invention is not limited thereto. For example, as illustrated in FIG. 3A, a structure in which the opening portion 290 reaches the conductor 220a can be employed. With such a structure, the level of the bottom surface of the conductor 260 can be further lowered, and the electric field of the conductor 260 can be easily applied to the oxide semiconductor 230 in the vicinity of the conductor 220. Here, at least part of the bottom surface of the oxide semiconductor 230 is removed, so that the area where the oxide semiconductor 230 and the top surface of the conductor 220a are in contact with each other can be reduced. Thus, excessive oxidation of the conductor 220a can be prevented.

As illustrated in FIG. 3B, a structure in which the conductor 220b is located inward from the conductor 220a may be employed. For example, an opening portion can be formed in the conductor 220a, the conductor 220b can be formed in the opening portion, and the opening portion 290 can be formed to overlap with the conductor 220b. Here, as illustrated in FIG. 3B, the opening portion 290 reaches the insulator 222, and the oxide semiconductor 230 and the insulator 250 are in contact with the insulator 222. With such a structure, the inner side surface of the conductor 220b and the side surface of the oxide semiconductor 230 are in contact with each other, so that the conductor 220 and the oxide semiconductor 230 can be in ohmic contact with each other. Furthermore, the oxide semiconductor 230 and the conductor 220a can be prevented from being in contact with each other, so that oxidation of the conductor 220a can be inhibited.

Alternatively, as illustrated in FIG. 3C, a structure in which the conductor 220a is embedded in the insulator 285 and the conductor 220b is provided in contact with the top surface of the conductor 220a can be employed. Here, for the insulator 285, an insulating material that can be used for the insulator 270 can be used. The opening portion 290 is formed to overlap with the conductor 220b. The opening portion 290 is preferably placed so as not to overlap with the conductor 220a. In this case, as illustrated in FIG. 3C, the opening portion 290 reaches the insulator 285, and the oxide semiconductor 230 and the insulator 250 are in contact with the insulator 285. With such a structure, the inner side surface of the conductor 220b and the side surface of the oxide semiconductor 230 are in contact with each other, so that the conductor 220 and the oxide semiconductor 230 can be in ohmic contact with each other. Furthermore, the oxide semiconductor 230 and the conductor 220a can be prevented from being in contact with each other, so that oxidation of the conductor 220a can be inhibited.

As illustrated in FIG. 2A and the like, the insulator 250 is provided in contact with the top surfaces of the insulator 270, the oxide semiconductor 230, and the conductor 220. As illustrated in FIG. 2B, a structure in which the upper end portion of the insulator 250 and the top surface of the insulator 270 are level with or substantially level with each other and the insulator 250 is not provided over the insulator 270 can be employed.

As illustrated in FIG. 2A, the insulator 250 may have a stacked-layer structure of the insulator 250a, the insulator 250b over the insulator 250a, and the insulator 250c over the insulator 250b. The insulator 250a is in contact with the conductor 220, the oxide semiconductor 230, and the insulator 270. The insulator 250c is in contact with the conductor 260 and the insulator 283. The insulator 250b is provided between the insulator 250a and the insulator 250c.

As the insulator 250a and the insulator 250c, an insulator having a barrier property against oxygen is preferably used. Furthermore, as the insulator 250a and the insulator 250c, an insulator having a function of capturing or fixing hydrogen is preferably used. For the insulator 250a and the insulator 250c, an insulating material that can be used for the insulator 222 may be used. Providing such an insulator 250a and such an insulator 250c can inhibit oxidation of the conductor 220 in contact with the insulator 250a and the conductor 260 in contact with the insulator 250c. Moreover, hydrogen contained in the oxide semiconductor 230 and its vicinity can be captured or fixed more effectively by the insulator 250a and the insulator 250c. Thus, the hydrogen concentration in the oxide semiconductor 230 can be reduced. For example, aluminum oxide can be used for the insulator 250a and hafnium oxide can be used for the insulator 250c. As the insulator 250a and the insulator 250c, a single layer or stacked layers of any of the insulators described later in the section [Insulator] may be used.

Aluminum oxide and hafnium oxide are each a high permittivity (high-k) material. Accordingly, in the case of using the insulator 250a and the insulator 250c as a gate insulator, a gate potential applied during operation of the transistor can be reduced while the physical thickness of the gate insulator is maintained. In addition, the equivalent oxide thickness (EOT) of an insulator functioning as a gate insulator can be reduced.

The film thickness of each of the insulator 250a and the insulator 250c is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. At least part of each of the insulator 250a and the insulator 250c has a region with the above-described thickness.

For the insulator 250b, silicon oxide, silicon oxynitride, or the like having high withstand voltage is preferably used. In order to increase the withstand voltage, the insulator 250b may have a thickness larger than those of the insulator 250a and the insulator 250c. Providing such an insulator 250b can improve the withstand voltage of the insulator 250 and reduce leakage current.

An insulator having a barrier property against hydrogen may further be provided between the insulator 250c and the conductor 260. Accordingly, diffusion of impurities such as hydrogen contained in the conductor 260 into the oxide semiconductor 230 can be inhibited. As the insulator having a barrier property against hydrogen, an insulator that can be used as the insulator 210 and the insulator 283 can be used. For example, silicon nitride is suitable because of having a high barrier property against hydrogen. In the case where the insulator has a barrier property against hydrogen, the insulator also has a barrier property against oxygen.

The conductor 260 is provided in contact with the top surface of the insulator 250. As illustrated in FIG. 1A to FIG. 1C, a portion of the conductor 260 that is above the insulator 270 can be extended in the Y direction to make the portion function as a wiring.

As the conductor 260, a single layer or stacked layers of any of conductors described later in the section [Conductor] can be used. For example, a conductive material with high conductivity such as tungsten can be used for the conductor 260.

In addition, a conductive material that is less likely to be oxidized, a conductive material having a function of inhibiting diffusion of oxygen, or the like is preferably used as the conductor 260. Examples of the conductive material include a conductive material containing nitrogen (e.g., titanium nitride or tantalum nitride) and a conductive material containing oxygen (e.g., ruthenium oxide). Thus, a decrease in the conductivity of the conductor 260 can be inhibited.

Although the conductor 260 being a single layer is illustrated in FIG. 1B and FIG. 1C, the present invention is not limited to this structure. The conductor 260 may have a stacked-layer structure. For example, as illustrated in FIG. 2A, the conductor 260 may have a stacked-layer structure of a conductor 260a and a conductor 260b over the conductor 260a. In that case, titanium nitride may be used for the conductor 260a, and tungsten may be used for the conductor 260b, for example. When a layer containing tungsten is provided in this manner, the conductor 260 can have improved conductivity and can serve well as a wiring.

Although FIG. 2A illustrates the structure in which the conductor 260 has the stacked-layer structure of the two layers of the conductor 260a and the conductor 260b, the present invention is not limited thereto. The conductor 260 may have a stacked-layer structure of three or more layers.

For example, as illustrated in FIG. 2B, the conductor 260a and the conductor 260b may be provided only in a portion below the top surface of the insulator 270, and a conductor 260c functioning as a wiring may be provided over the conductor 260a and the conductor 260b. Here, the upper end portion of the conductor 260a and the top surface of the conductor 260b are level with or substantially level with the top surface of the insulator 270. The conductor 260c functions as a wiring and thus can be formed to extend in the Y direction, for example. For the conductor 260c, a conductive material that can be used for the conductor 260a or the conductor 260b may be used. For example, the conductor 260c can have a stacked-layer structure of titanium nitride and tungsten.

As the insulator 283, a barrier insulator against hydrogen is preferably used. This can inhibit diffusion of hydrogen from above the insulator 283 into the oxide semiconductor 230. A silicon nitride film and a silicon nitride oxide film can be suitably used for the insulator 283 because they release fewer impurities (e.g., water and hydrogen) and are less likely to transmit oxygen and hydrogen.

Silicon nitride formed by a sputtering method is particularly preferably used for the insulator 283. In that case, the insulator 283 contains silicon and nitrogen. Since a sputtering method does not need to use a molecule containing hydrogen in a film formation gas, the hydrogen concentration in the insulator 283 can be reduced. When the insulator 283 is formed by a sputtering method, high-density silicon nitride can be formed.

Alternatively, silicon nitride formed by a PEALD method may be used for the insulator 283. When the insulator 283 is formed by a PEALD method, the conductor 260 can be covered with good coverage.

With this structure, diffusion of hydrogen from above the insulator 283 into the oxide semiconductor 230 can be inhibited. Thus, the hydrogen concentration in the oxide semiconductor 230 can be reduced.

### Example of Method for Fabricating Semiconductor Device

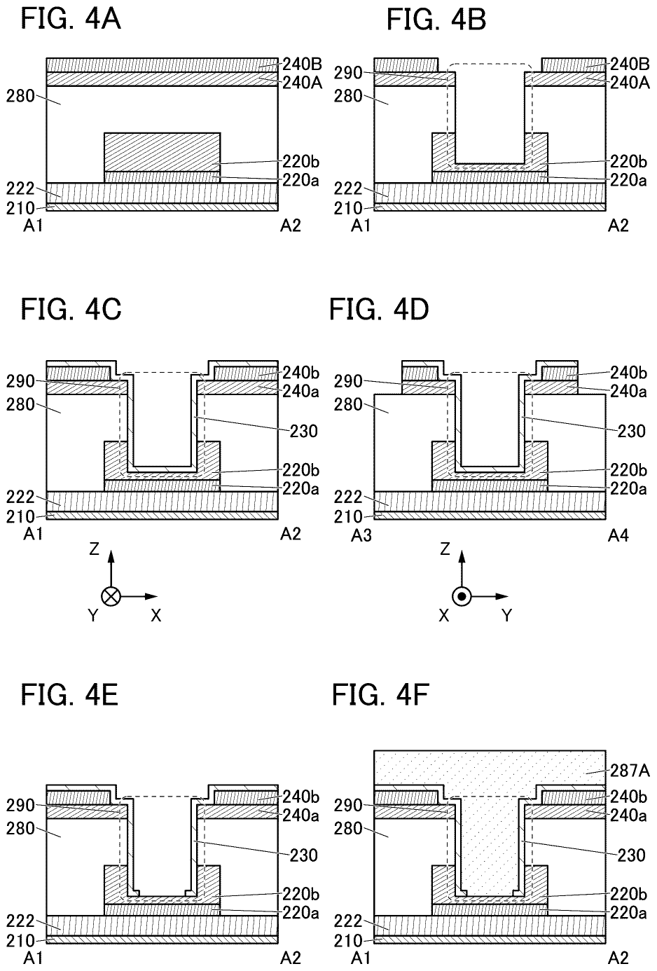

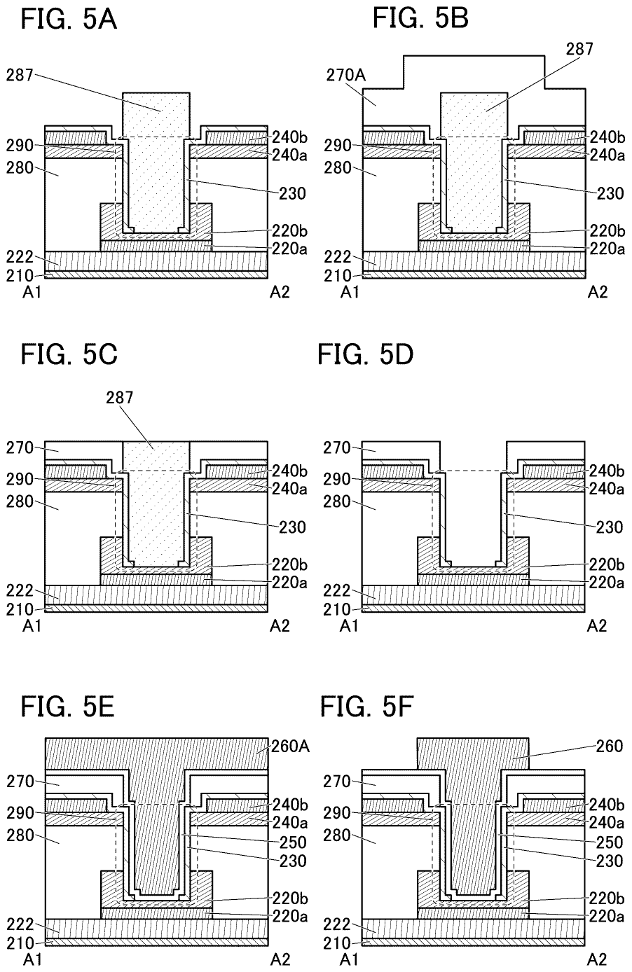

Next, a method for fabricating the transistor 200 illustrated in FIG. 1A to FIG. 1D and the like is described with reference to FIG. 4A to FIG. 5F. Note that FIG. 4A to FIG. 4C and FIG. 4E to FIG. 5F correspond to FIG. 1B. FIG. 4D corresponds to FIG. 1C.

Hereinafter, a film of an insulating material for forming an insulator, a film of a conductive material for forming a conductor, or a film of a semiconductor material for forming a semiconductor can be formed by a sputtering method, a chemical vapor deposition (CVD) method, a molecular beam epitaxy (MBE) method, a pulsed laser deposition (PLD) method, an ALD method, or the like as appropriate.

Examples of a sputtering method include an RF sputtering method in which a high-frequency power source is used as a sputtering power source, a DC sputtering method in which a DC power source is used, and a pulsed DC sputtering method in which voltage applied to an electrode is changed in a pulsed manner. An RF sputtering method is mainly used in the case where an insulating film is formed, and a DC sputtering method is mainly used in the case where a metal conductive film is formed. The pulsed DC sputtering method is mainly used in the case where a compound such as an oxide, a nitride, or a carbide is formed by a reactive sputtering method.

Note that a CVD method can be classified into a plasma CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by a plasma CVD method. Furthermore, a thermal CVD method is a film formation method that does not use plasma and thus enables less plasma damage to an object. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. By contrast, a thermal CVD method, which does not use plasma, does not cause such plasma damage, and thus can increase the yield of the semiconductor device. In addition, a thermal CVD method does not cause plasma damage during film formation, so that a film with few defects can be obtained.

As an ALD method, a thermal ALD method, in which a precursor and a reactant react with each other only by a thermal energy, a PEALD method, in which a reactant excited by plasma is used, and the like can be used.

A CVD method and an ALD method are different from a sputtering method in which particles ejected from a target or the like are deposited. Thus, a CVD method and an ALD method are film formation methods that enable good step coverage almost regardless of the shape of an object. In particular, the ALD method enables excellent step coverage and excellent thickness uniformity and thus is suitable for covering a surface of an opening portion with a high aspect ratio, for example. On the other hand, the ALD method has a relatively low film formation rate, and thus is preferably used in combination with another film formation method with a high film formation rate, such as the CVD method, in some cases.

By a CVD method, a film with a certain composition can be formed depending on the flow rate ratio of the source gases. For example, by the CVD method, a film whose composition is continuously changed can be formed by changing the flow rate ratio of the source gases during formation. In the case where a film is formed while the flow rate ratio of the source gas is changed, the time taken for transfer or pressure adjustment is saved, and thus, the time taken for the film formation can be shortened as compared to the case where a film is formed using a plurality of film formation chambers. Thus, the productivity of the semiconductor device can be increased in some cases.

By an ALD method, a film with a certain composition can be formed by introducing different kinds of precursors. For example, in the case where different kinds of precursors are introduced, a film with a certain composition can be formed by controlling the number of cycles for each of the precursors.

In the case where a plurality of different kinds of precursors are introduced in an ALD method, the kind of oxidizer may be changed depending on the precursors. For example, in the case where at least a first precursor and a second precursor are introduced, ozone (O₃) may be used as an oxidizer for the first precursor and oxygen (O₂) may be used as an oxidizer for the second precursor.

In addition, heat treatment may be performed before formation of a film. This heat treatment may be performed under reduced pressure, and the film may be successively formed without exposure to the air. Such treatment can remove moisture and hydrogen adsorbed onto the surface over which the film is to be formed, and further can reduce the moisture concentration and the hydrogen concentration in a structural element that serves as the surface over which the film is to be formed. The temperature of the heat treatment is preferably higher than or equal to 100 °C and lower than or equal to 600 °C.

First, a substrate (not illustrated) is prepared, and the insulator 210 is formed over the substrate (see FIG. 4A). The insulator 210 can be formed by a sputtering method, a CVD method, an MBE method, a PLD method, an ALD method, or the like as appropriate. For example, a silicon nitride film can be formed by a sputtering method as the insulator 210.

Next, the insulator 222 is formed over the insulator 210 (see FIG. 4A). The insulator 222 can be formed by a sputtering method, a CVD method, an MBE method, a PLD method, an ALD method, or the like as appropriate. For example, hafnium silicate can be formed as the insulator 222 by a sputtering method. In that case, a film formation target containing hafnium and silicon, or the like may be used. For example, a co-sputtering method using a silicon oxide target and a hafnium oxide target may be employed.

Next, the conductor 220a and the conductor 220b are formed over the insulator 222 (see FIG. 4A). The conductor 220a and the conductor 220b can be formed in the following manner: conductive films are formed over the insulator 222 and the conductive films are patterned by a lithography method. The conductive films may be formed by a sputtering method, a CVD method, an MBE method, a PLD method, an ALD method, or the like as appropriate. For example, a tungsten film can be formed as the conductive film to be the conductor 220a by a sputtering method, and an ITSO film can be formed as the conductive film to be the conductor 220b by a sputtering method.

Next, the insulator 280 is formed over the insulator 222 and the conductor 220 (see FIG. 4A). Any of the above-described insulating materials can be used as the insulator 280 as appropriate. The insulator 280 can be formed by a sputtering method, a CVD method, an MBE method, a PLD method, an ALD method, or the like as appropriate. For example, the insulator 280 can have a structure including the insulator 280a, the insulator 280b, and the insulator 280c illustrated in FIG. 2A. In that case, silicon nitride can be formed by a PEALD method as the insulator 280a, silicon oxide can be formed by a sputtering method as the insulator 280b, and silicon nitride can be formed by a sputtering method as the insulator 280c. The top surface of the formed insulator 280 is preferably planarized by CMP treatment. The planarization treatment for the insulator 280 enables favorable formation of the conductor 240 functioning as a wiring.

Note that the CMP treatment may be skipped in some cases. In that case, the top surface of the insulator 280 has an upward-convex curved top surface shape. When planarization treatment is not performed, the manufacturing cost can be reduced and the production yield can be increased.

Note that planarization treatment is not always performed after the insulator 280a to the insulator 280c are formed. For example, planarization treatment may be performed after the insulator 280a and the insulator 280b are formed, and then the insulator 280c may be formed.

By using a sputtering method that does not need to use a molecule containing hydrogen as a film formation gas for the formation of the insulator 280, the hydrogen concentration in the insulator 280 can be reduced. When the insulator 280 is formed in this manner, diffusion of hydrogen from the insulator 280 to into the oxide semiconductor 230 can be reduced, and oxygen vacancies and VoH in the channel formation region can be reduced.

Next, a conductive film 240A is formed over the insulator 280, and a conductive film 240B is formed over the conductive film 240A (see FIG. 4A). The conductive film 240A is to be the conductor 240a in a later step, and the conductive film 240B is to be the conductor 240b in a later step. Any of the above-described conductive materials can be used for the conductive film 240A and the conductive film 240B as appropriate. The conductive film 240A and the conductive film 240B can be formed by a sputtering method, a CVD method, an MBE method, a PLD method, an ALD method, or the like as appropriate. For example, as the conductive film 240A, ITSO can be formed by a sputtering method. As the conductive film 240B, tungsten can be formed by a sputtering method.

Then, part of the conductive film 240A, part of the conductive film 240B, and part of the insulator 280 are processed to form the opening portion 290 reaching the conductor 220 (see FIG. 4B). The opening portion 290 may be formed by a lithography method.

Note that in a lithography method, first, a resist is exposed to light through a mask. Next, a region exposed to light is removed or left using a developing solution, so that a resist mask is formed. Then, etching treatment through the resist mask is performed, whereby a conductor, a semiconductor, an insulator, or the like can be processed into a desired shape. The resist mask can be formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that the use of a mask may be unnecessary in the case of using an electron beam or an ion beam.

Note that the resist mask that is no longer needed after the processing can be removed by dry etching treatment such as ashing using oxygen plasma (hereinafter, sometimes referred to as oxygen plasma treatment), wet etching treatment, wet etching treatment after dry etching treatment, or dry etching treatment after wet etching treatment.

An SOC (Spin On Carbon) film and an SOG (Spin On Glass) film may be formed between an object to be processed and the resist mask. Using the SOC film and the SOG film as masks can enhance the durability of a mask pattern. For example, the SOC film, the SOG film, and the resist mask are formed in this order over the object to be processed and a lithography method can be performed. A hard mask formed of an insulator or a conductor can be provided between the object to be processed and the SOC film.

For example, the SOC film, the SOG film, and the resist mask are formed in this order over the conductive film 240B and the resist mask can be patterned into the shape of the opening portion 290.

A dry etching method or a wet etching method can be used for forming the opening portion 290. A dry etching method enables anisotropic etching and thus is suitable for forming the opening portion 290 with a high aspect ratio. Note that the opening portion 290 can also be formed by a dry etching method and a wet etching method as appropriate.

Here, as an etching gas for the dry etching treatment, an etching gas containing a halogen can be used, and specifically, an etching gas containing one or more of fluorine, chlorine, and bromine can be used. As the etching gas, for example, a C₄F₆ gas, a C₅F₆ gas, a C₄F₈ gas, a CF₄ gas, a SF₆ gas, a CHF₃ gas, a CH₂F₂ gas, a CH₃F gas, a Cl₂ gas, a BCl₃ gas, a SiCl₄ gas, a CCl₄ gas, an HBr gas, a BBr₃ gas, or the like can be used alone or two or more of the gases can be mixed and used. Furthermore, an oxygen gas, a carbonic acid gas, a nitrogen gas, a helium gas, an argon gas, a hydrogen gas, a hydrocarbon gas, or the like can be added to the above etching gas as appropriate. Depending on an object to be subjected to the dry etching treatment, a gas that contains a hydrocarbon gas or a hydrogen gas and does not contain a halogen gas can be used as the etching gas. As the hydrocarbon used for the etching gas, one or more of methane (CH₄), ethane (C₂H₆), propane (C₃H₈), butane (C₄H₁₀), ethylene (C₂H₄), propylene (C₃H₆), acetylene (C₂H₂), and propyne (C₃H₄) can be used. The etching conditions can be set as appropriate depending on an object to be etched.

As a dry etching apparatus, a capacitively coupled plasma (CCP) etching apparatus including parallel plate electrodes can be used. The capacitively coupled plasma etching apparatus including parallel plate electrodes can have a structure in which high-frequency voltage is applied to one of the parallel plate electrodes. Alternatively, a structure can be employed in which high-frequency voltage with the same frequency is applied to the parallel plate electrodes. Alternatively, different high-frequency voltage can be applied to the parallel plate electrodes. Such a CCP etching apparatus is referred to as a dual frequency capacitively coupled plasma (DF-CCP) etching apparatus. In the DF-CCP etching apparatus, high-frequency voltage with different frequencies can be applied to the parallel plate electrodes. Alternatively, a structure can be employed in which different high-frequency voltage is applied to one of the parallel plate electrodes. Alternatively, a dry etching apparatus including a high-density plasma source can be used. As the dry etching apparatus including a high-density plasma source, an inductively coupled plasma (ICP) etching apparatus or the like can be used, for example. The etching apparatus can be set as appropriate depending on an object to be etched. Note that in the above dry etching apparatus, high-frequency voltage is applied to the electrode on the substrate side to generate a self-bias potential, whereby reactive ion etching can be performed. In reactive ion etching, ion species in plasma are accelerated to collide with an object to be processed, whereby highly anisotropic etching can be performed.

Note that the following steps of forming the opening portion 290 are preferably performed successively without exposure to the air. For example, the processing is performed without exposure to the air by using a multi-chamber etching apparatus.

The above-described etching gas and etching apparatus can be selected as appropriate according to the structures of the SOG film, the SOC film, the conductive film 240B, the conductive film 240A, and the insulator 280. For example, in the case where a tungsten film is used as the conductive film 240B, treatment can be performed with a DF-CCP etching apparatus using Cl₂, CF₄, and an oxygen gas as etching gases. For example, in the case where an ITSO film is used as the conductive film 240A, treatment can be performed with a DF-CCP etching apparatus using CH4 and an argon gas as etching gases. For example, in the case where a stacked-layer film of silicon oxide and silicon nitride is used as the insulator 280, treatment can be performed with a DF-CCP etching apparatus using C₄F₈, C₄F₆, an oxygen gas, and an argon gas as etching gases.

The SOC film preferably remains over the conductive film 240B after the opening portion 290 is formed. Wet etching in this state enables side-etching of the conductive film 240B. As an etchant of the wet etching, an ammonia hydrogen peroxide mixture (a mixed solution of ammonia, water, and a hydrogen peroxide solution) is preferably used, for example. Accordingly, the side surface of the conductive film 240B can be receded from the side surface of the conductive film 240A.

In order to remove impurities and the like attached to the opening portion 290 in the etching step, cleaning treatment is preferably performed. As a cleaning method, wet cleaning using a cleaning solution or the like (which can also be referred to as wet etching treatment) can be performed. Furthermore, the top surface of the conductor 220 is etched by the wet cleaning, so that a depressed portion connected to the opening portion 290 is formed on the top surface of the conductor 220.

The wet cleaning may be performed using an aqueous solution in which one or more of oxalic acid, phosphoric acid, and hydrofluoric acid are diluted with carbonated water or pure water. The wet cleaning may be performed using an aqueous solution in which ammonia water is diluted with carbonated water or pure water. The wet cleaning may be performed using pure water, carbonated water, or the like. Alternatively, ultrasonic cleaning using such an aqueous solution, pure water, or carbonated water may be performed. Alternatively, these cleanings may be performed in combination as appropriate. The cleaning treatment may be performed a plurality of times, and the cleaning solution may be changed in every cleaning treatment. For example, wet cleaning is performed using diluted hydrofluoric acid obtained by diluting hydrofluoric acid with pure water.

The depressed portion of the top surface of the conductor 220 is not necessarily formed by the wet cleaning. For example, the depressed portion of the top surface of the conductor 220 may be formed by a dry etching method successively after the dry etching treatment on the insulator 280.

After the formation of the opening portion 290, microwave treatment may be performed in an oxygen-containing atmosphere to reduce the impurity concentration in the insulator 280. Here, the microwave treatment refers to, for example, treatment using an apparatus including a power source that generates high-density plasma with the use of a microwave. In this specification and the like, a microwave refers to an electromagnetic wave having a frequency higher than or equal to 300 MHz and lower than or equal to 300 GHz. Specific examples of the impurity include hydrogen and carbon. When the insulator 280 is subjected to microwave treatment in an oxygen-containing atmosphere, hydrogen contained in the insulator 280 can be released as H₂O to the outside. Release of hydrogen from the insulator 280 positioned in the vicinity of the oxide semiconductor 230 can offer a highly reliable semiconductor device.

Next, heat treatment may be performed. After the microwave treatment is performed, the heat treatment may be successively performed without exposure to the air. The heat treatment is performed at higher than or equal to 250 °C and lower than or equal to 650 °C, preferably higher than or equal to 300 °C and lower than or equal to 500 °C, further preferably higher than or equal to 320 °C and lower than or equal to 450 °C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas can be approximately 20%. The heat treatment may be performed under reduced pressure. Alternatively, the heat treatment may be performed in an atmosphere containing an oxidizing gas at higher than or equal to 10 ppm, higher than or equal to 1%, or higher than or equal to 10% after the heat treatment in a nitrogen gas or inert gas atmosphere. By the above-described heat treatment, impurities such as water contained in the insulator 280 or the like can be reduced before formation of the later-described oxide semiconductor film to be the oxide semiconductor 230. Note that the heat treatment is preferably performed under the condition where the conductor 220 and the conductor 240 are not excessively oxidized.

The gas used in the above heat treatment is preferably highly purified. For example, the amount of moisture contained in the gas used in the above heat treatment can be less than or equal to 1 ppb, preferably less than or equal to 0.1 ppb, further preferably less than or equal to 0.05 ppb. The heat treatment using a highly purified gas can prevent entry of moisture or the like into the insulator 280 and the like as much as possible.

Note that although the structure in which the heat treatment is performed after the microwave treatment is described above, the present invention is not limited thereto. The microwave treatment can be performed after the heat treatment.

Next, an oxide semiconductor film to be the oxide semiconductor 230 is formed in contact with the top surface of the conductor 220, the side surface of the insulator 280, the side surface of the conductive film 240A, part of the top surface of the conductive film 240A, and the top surface and the side surface of the conductive film 240B. For the oxide semiconductor film, a metal oxide that can be used for the oxide semiconductor 230 can be used as appropriate. The oxide semiconductor film can be formed by a sputtering method, a CVD method, an MBE method, a PLD method, an ALD method, or the like.

For example, as in FIG. 2A, a stacked-layer film of oxide semiconductors can be formed such that a stacked-layer structure of the oxide semiconductor 230a and the oxide semiconductor 230b can be obtained. In that case, an oxide semiconductor film to be the oxide semiconductor 230a can be formed by a sputtering method, and an oxide semiconductor film to be the oxide semiconductor 230b can be formed thereover by an ALD method. The oxide semiconductor film to be the oxide semiconductor 230a can be formed using a target with a composition of In:Ga:Zn=1:1:1.2 [atomic ratio] or in the neighborhood thereof. The oxide semiconductor film to be the oxide semiconductor 230b can be formed to have a composition of In:Ga:Zn=1:1:1 [atomic ratio] or in the neighborhood thereof.

Note that the microwave treatment and the heat treatment may be performed after the formation of the oxide semiconductor film.

Next, the oxide semiconductor film to be the oxide semiconductor 230, the conductive film 240A, and the conductive film 240B are processed by a lithography method to form the oxide semiconductor 230, the conductor 240a, and the conductor 240b (see FIG. 4C and FIG. 4D). Note that the oxide semiconductor film to be the oxide semiconductor 230, the conductive film 240A, and the conductive film 240B can be processed by a dry etching method or a wet etching method. Processing by a dry etching method is suitable for microfabrication.

Thus, the conductor 240a and the conductor 240b are formed to extend in the X direction and can function as wirings. Like the conductor 240a and the conductor 240b, the oxide semiconductor 230 is formed to extend in the X direction. Note that part of the oxide semiconductor 230 is formed in the opening portion 290. Here, as illustrated in FIG. 4D, the side surface of the oxide semiconductor 230, the side surface of the conductor 240a, and the side surface of the conductor 240b are preferably formed to be aligned with each other.

Although the oxide semiconductor 230, the conductor 240a, and the conductor 240b are formed collectively in the above description, the present invention is not limited thereto. For example, the conductive film 240A and the conductive film 240B can be processed after the formation of the oxide semiconductor 230. In this case, the side surface of the oxide semiconductor 230 is positioned inward from the side surface of the conductor 240a and the side surface of the conductor 240b.

Next, the oxide semiconductor 230 is processed by a lithography method, and part of the oxide semiconductor 230 is removed at the bottom portion of the opening portion 290 (see FIG. 4E). Thus, part of the top surface of the conductor 220b is exposed from the oxide semiconductor 230. In a cross-sectional view, the lower portion of the oxide semiconductor 230 has a shape protruding in the opening portion 290. For the processing of the oxide semiconductor 230, a dry etching method or a wet etching method can be employed. Processing by a dry etching method is suitable for microfabrication.

Here, the oxide semiconductor 230 is preferably formed in contact with the depressed portion of the conductor 220 in the opening portion 290, the side surface of the insulator 280 in the opening portion 290, the side surface of the conductor 240a, part of the top surface of the conductor 240a, and the top surface and the side surface of the conductor 240b. When the oxide semiconductor 230 is formed in contact with the side surface of the depressed portion of the conductor 220, the conductor 220 functions as one of the source electrode and the drain electrode of the transistor 200. When the oxide semiconductor 230 is formed in contact with the conductor 240a, the conductor 240a and the conductor 240b function as the other of the source electrode and the drain electrode of the transistor 200.

Next, a coating film 287A is formed to fill the opening portion 290 (see FIG. 4F). For the coating film 287A, an SOC film can be applied first, and an SOG film can be applied thereover. The coating film 287A functions as a sacrificial layer at the time of forming the insulator 270.

Next, the coating film 287A is processed by a lithography method, so that a sacrificial layer 287 that protrudes above the opening portion 290 is formed (see FIG. 5A). The sacrificial layer 287 can be patterned in accordance with the shape of an opening of the insulator 270 to be formed later. A dry etching method or a wet etching method can be used for the processing of the coating film 287A. Processing by a dry etching method is suitable for microfabrication. Here, when the sacrificial layer 287 has a structure in which the SOG film is stacked over the SOC film, the sacrificial layer 287 can be prevented from losing its shape in the above processing.

Next, an insulating film 270A to be the insulator 270 is formed to cover the sacrificial layer 287 and the oxide semiconductor 230 (see FIG. 5B). Any of the above-described insulating materials is used for the insulating film 270A as appropriate. The insulating film 270A may be formed by a sputtering method, a CVD method, an MBE method, a PLD method, an ALD method, or the like as appropriate. For the insulating film 270A, silicon oxide can be formed by a sputtering method, for example. A sputtering method that does not necessarily use a molecule containing hydrogen as a film formation gas is used for the formation of the insulating film 270A, the hydrogen concentration in the insulating film 270A can be reduced. When the insulating film 270A is formed in this manner, diffusion of hydrogen from the insulating film 270A into the oxide semiconductor 230 can be reduced, and oxygen vacancies and VoH in the channel formation region can be reduced.

The insulating film 270A may be a stacked-layer film of an aluminum oxide film formed by an ALD method and a silicon oxide film over the aluminum oxide film. In that case, an upper portion of the sacrificial layer 287 is covered with the aluminum oxide film. When the silicon oxide film is formed by a sputtering method while the sacrificial layer 287 is covered with the aluminum oxide film in this manner, the sacrificial layer 287 can be prevented from losing its shape during the formation of the silicon oxide film.

Next, the insulating film 270A is subjected to CMP treatment until the sacrificial layer 287 is exposed, whereby the insulator 270 is formed (see FIG. 5C). At this time, the SOG film, which is the upper portion of the sacrificial layer 287, is also removed so that the SOC film of the sacrificial layer 287 is exposed.

Next, the sacrificial layer 287 is removed to form the opening in the insulator 270 that overlaps with the opening portion 290 (see FIG. 5D). The sacrificial layer 287 can be removed by dry etching treatment such as ashing, wet etching treatment, wet etching treatment after dry etching treatment, or dry etching treatment after wet etching treatment.

Next, the insulator 250 is formed over the insulator 270, the oxide semiconductor 230, and the conductor 220 (see FIG. 5E). Any of the above-described insulating materials can be used for the insulator 250 as appropriate. The insulator 250 can be formed by a sputtering method, a CVD method, an MBE method, a PLD method, an ALD method, or the like as appropriate. The insulator 250 is preferably formed in contact with the oxide semiconductor 230 that is provided in the opening portion 290. Thus, the insulator 250 is preferably formed by a film formation method enabling favorable coverage, and is further preferably formed by a CVD method, an ALD method, or the like. For example, as illustrated in FIG. 2A, the insulator 250 can have a stacked-layer structure of the insulator 250a, the insulator 250b, and the insulator 250c. For example, aluminum oxide can be formed by a thermal ALD method as the insulator 250a, silicon oxide can be formed by a PEALD method as the insulator 250b, and hafnium oxide can be formed by a thermal ALD method as the insulator 250c.

The microwave treatment and the heat treatment may be performed after the formation of the insulator 250. In the case where the insulator 250 has a stacked-layer structure, the microwave treatment is not necessarily performed after all the insulators included in the insulator 250 are formed. For example, in the case of the structure illustrated in FIG. 2A, microwave treatment may be performed after the insulator 250b is formed, and then the insulator 250c may be formed. Alternatively, for example, the steps may be performed in the following order: formation of the insulator 250b, microwave treatment, formation of the insulator 250c, and microwave treatment. In this manner, the microwave treatment in an oxygen-containing atmosphere may be performed multiple times.

Next, a conductive film 260A to be the conductor 260 is formed to fill the depressed portion of the insulator 250. Any of the above-described conductive materials may be used for the conductive film 260A as appropriate. The conductive film 260A can be formed by a sputtering method, a CVD method, an MBE method, a PLD method, an ALD method, or the like as appropriate. Here, the conductive film 260A is preferably formed in contact with the insulator 250 provided in the opening portion 290. Thus, the conductive film is preferably formed by a film formation method enabling favorable coverage or a good filling property, and is further preferably formed by a CVD method, an ALD method, or the like. For example, as the conductive film 260A, titanium nitride can be formed by a CVD method or an ALD method and tungsten can be formed over the titanium nitride by a CVD method.

Although the conductive film 260A is provided to fill the opening portion 290 in the above description, the present invention is not limited thereto. For example, a depressed portion reflecting the shape of the opening portion 290 is formed in a center portion of the conductive film in some cases. The depressed portion may be filled with an inorganic insulating material or the like.

Next, the conductive film to be the conductive film 260A is processed to form the conductor 260 (see FIG. 5F). The conductor 260 may be formed by a lithography method. A dry etching method or a wet etching method can be used for the processing. Processing by a dry etching method is suitable for microfabrication.

Alternatively, the conductive film 260A and the insulator 250 can be subjected to CMP treatment to remove portions of the conductive film 260A and the insulator 250 that are above the insulator 270. In that case, the remaining portion of the conductive film 260A corresponds to the conductor 260a and the conductor 260b illustrated in FIG. 2B, and the remaining portion of the insulator 250 corresponds to the insulator 250 illustrated in FIG. 2B. After that, the conductor 260c functioning as a wiring can be formed over the conductor 260a and the conductor 260b.

Next, the insulator 283 is formed to cover the conductor 260 and the insulator 250. Any of the above-described insulating materials can be used as the insulator 283 as appropriate. The insulator 283 can be formed by a sputtering method, a CVD method, an MBE method, a PLD method, an ALD method, or the like as appropriate. For example, as the insulator 283, a silicon nitride film is preferably formed by a PEALD method.

The microwave treatment and the heat treatment may be performed after the formation of the insulator 283. In the case where an insulator having a function of inhibiting diffusion of hydrogen is used as the insulator 210 and the insulator 283 and an insulator having a function of capturing or fixing hydrogen is used as the insulator 222 and the insulator 250, the heat treatment can be performed in a state where the insulator 222 and the insulator 250 are provided in a region sandwiched between the insulator 210 and the insulator 283. Accordingly, hydrogen in the region sandwiched between the insulator 210 and the insulator 283 can be captured or fixed by the insulator 222 and the insulator 250. Thus, the hydrogen concentration in the channel formation region of the oxide semiconductor 230 can be reduced. Therefore, the electrical characteristics and reliability of the transistor can be improved. Moreover, a semiconductor device with a small variation in electrical characteristics of transistors can be provided.

Through the above process, the transistor 200 illustrated in FIG. 1A to FIG. 1D and the like can be fabricated.

### Modification Example of Semiconductor Device

Although the semiconductor device in FIG. 1A to FIG. 1D has a structure in which the insulator 250 is formed after the insulator 270 is formed, the present invention is not limited thereto. For example, the insulator 270 can be formed after the insulator 250 is formed.

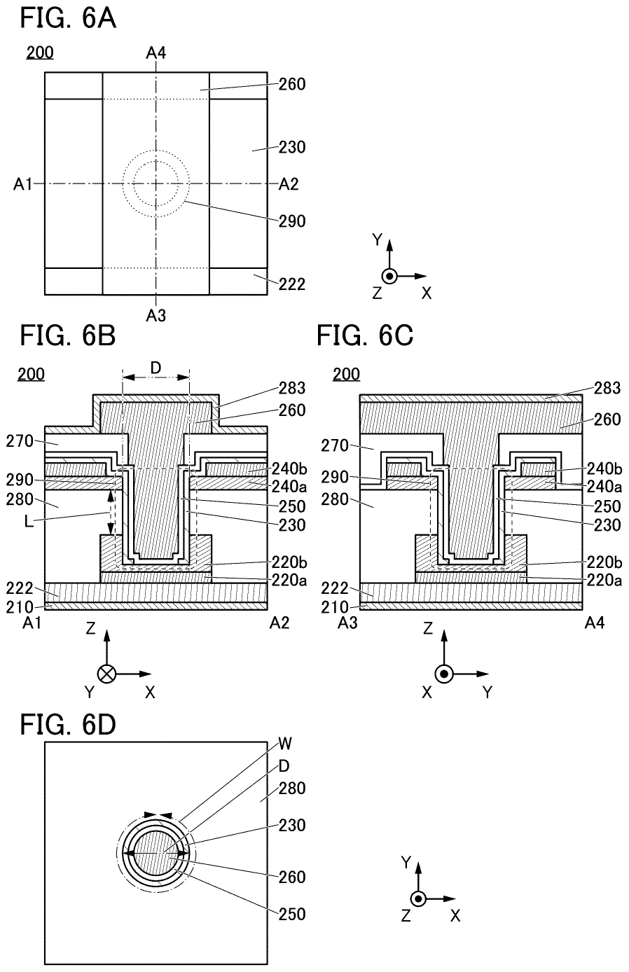

FIG. 6A to FIG. 6D illustrate another example of the semiconductor device of one embodiment of the present invention. FIG. 6A is a plan view of the semiconductor device. FIG. 6B to FIG. 6D are cross-sectional views of the semiconductor device. Here, FIG. 6B is a cross-sectional view taken along the dashed-dotted line A1-A2 in FIG. 6A. FIG. 6C is a cross-sectional view taken along the dashed-dotted line A3-A4 in FIG. 6A. FIG. 6D is a cross-sectional view along the XY plane including the insulator 280. Note that some components are omitted in the plan view of FIG. 6A for clarity of the drawing.

The semiconductor device illustrated in FIG. 6A to FIG. 6D is different from the semiconductor device illustrated in FIG. 1 in that the insulator 270 is provided over the insulator 250. Differences from the description with reference to FIG. 1A to FIG. 1D are mainly described below; the description is referred to for the same portions, and the description of the same portions is omitted in some cases.

As illustrated in FIG. 6B, in a region not overlapping with the opening portion 290, the insulator 250 is provided in contact with the top surface of the oxide semiconductor 230, and the insulator 270 is provided in contact with the top surface of the insulator 250. The top surface of the insulator 270 is in contact with the conductor 260 and the insulator 283. As illustrated in FIG. 6C, the insulator 250 is provided to cover the side surface of the oxide semiconductor 230, the side surface of the conductor 240b, and the side surface of the conductor 240a. The insulator 250 is in contact with the top surface of the insulator 280 outside the conductor 240.

In the case where the transistor 200 has the shape illustrated in FIG. 6A to FIG. 6D, the insulator 250 can be formed after part of the bottom surface of the oxide semiconductor 230 is removed in the step illustrated in FIG. 4E. After that, the semiconductor device can be fabricated according to the steps in FIG. 4F to FIG. 5F.

Although the semiconductor device in FIG. 1A to FIG. 1D has a structure in which the insulator 270 is formed, the present invention is not limited thereto. For example, a structure in which the insulator 270 is not formed can be employed.

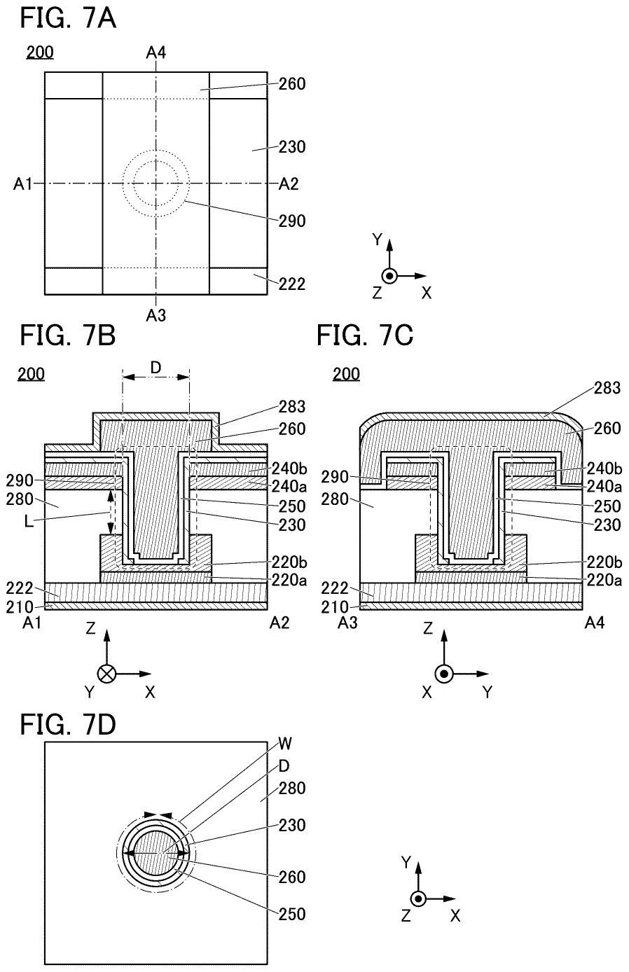

FIG. 7A to FIG. 7D illustrate another example of the semiconductor device of one embodiment of the present invention. FIG. 7A is a plan view of the semiconductor device. FIG. 7B to FIG. 7D are cross-sectional views of the semiconductor device. Here, FIG. 7B is the cross-sectional view taken along the dashed-dotted line A1-A2 in FIG. 7A. FIG. 7C is the cross-sectional view taken along the dashed-dotted line A3-A4 in FIG. 7A. FIG. 7D is a cross-sectional view along the XY plane including the insulator 280. Note that for clarity of the drawing, some components are not illustrated in the plan view of FIG. 7A.

The semiconductor device illustrated in FIG. 7A to FIG. 7D is different from the semiconductor device illustrated in FIG. 1 mainly in that the insulator 270 is not provided. Differences from the description with reference to FIG. 1A to FIG. 1D are mainly described below; the description is referred to for the same portions, and the description of the same portions is omitted in some cases.

As illustrated in FIG. 7B, the insulator 250 is provided in contact with the top surface of the oxide semiconductor 230. As illustrated in FIG. 7C, the insulator 250 is provided to cover the side surface of the oxide semiconductor 230, the side surface of the conductor 240b, and the side surface of the conductor 240a. The insulator 250 is in contact with the top surface of the insulator 280 outside the conductor 240.

In the case where the transistor 200 has the shape illustrated in FIG. 7A to FIG. 7D, the steps illustrated in FIG. 4F to FIG. 5D can be omitted. That is, in the step illustrated in FIG. 4E, part of the bottom surface of the oxide semiconductor 230 can be removed, and then the semiconductor device can be fabricated following the steps in FIG. 5E and FIG. 5F. When the fabrication process is simplified in this manner, the productivity of the semiconductor device can be improved.

As illustrated in FIG. 7B and FIG. 7C, a structure can be employed in which the side surface of the conductor 240a on the opening portion 290 side is aligned with the side surface of the conductor 240b on the opening portion 290 side. In that case, side etching treatment for making the side surface of the conductive film 240B recede in the step of FIG. 4B can be omitted. When the fabrication process is simplified in this manner, the productivity of the semiconductor device can be improved.

Although the semiconductor device in FIG. 1A to FIG. 1D has a structure in which part of the bottom surface of the oxide semiconductor 230 is removed by a lithography method, the present invention is not limited thereto. For example, the removal of part of the bottom surface of the oxide semiconductor 230 can be performed by anisotropic etching.

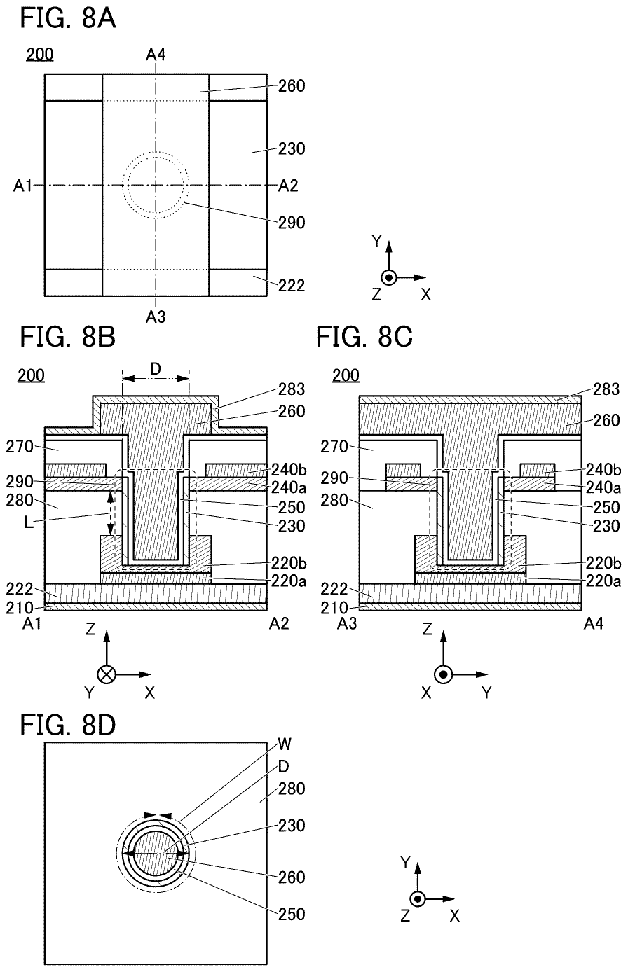

FIG. 8A to FIG. 8D illustrate another example of the semiconductor device of one embodiment of the present invention. FIG. 8A is a plan view of the semiconductor device. FIG. 8B to FIG. 8D are cross-sectional views of the semiconductor device. Here, FIG. 8B is the cross-sectional view taken along the dashed-dotted line A1-A2 in FIG. 8A. FIG. 8C is the cross-sectional view taken along the dashed-dotted line A3-A4 in FIG. 8A. FIG. 8D is the cross-sectional view along the XY plane including the insulator 280. Note that some components are omitted in the plan view of FIG. 8A for clarity of the drawing.

The semiconductor device illustrated in FIG. 8A to FIG. 8D is different from the semiconductor device illustrated in FIG. 1 in that the oxide semiconductor 230 does not cover the conductor 240a or the conductor 240b. Differences from the description with reference to FIG. 1A to FIG. 1D are mainly described below; the description is referred to for the same portions, and the description of the same portions is omitted in some cases.

As illustrated in FIG. 8B and FIG. 8C, the oxide semiconductor 230 is formed along the sidewall of the opening portion 290 and is in contact with the side surface of the conductor 240a, the side surface of the insulator 280, and the side surface of the depressed portion of the conductor 220. In other words, the oxide semiconductor 230 is formed in a sidewall shape along the opening portion 290. It is preferable that the oxide semiconductor 230 be formed not to cover the conductor 240a or the conductor 240b and not be in contact with the top surface of the conductor 240a or the top surface of the conductor 240b. Here, the upper end portion of the oxide semiconductor 230 is aligned or substantially aligned with the top surface of the conductor 240a in some cases. In addition, the lower portion of the oxide semiconductor 230 does not have a protruding shape in some cases.

In the case where the transistor 200 has the shape illustrated in FIG. 8A to FIG. 8D, in the step illustrated in FIG. 4E, the oxide semiconductor 230 can be processed by anisotropic etching without using a lithography method. A dry etching method is preferably employed for the anisotropic etching. For example, reactive ion etching is preferably performed. By performing anisotropic etching, the oxide semiconductor 230 can be processed into a sidewall shape even in the opening portion 290 having a high aspect ratio. Note that part of the oxide semiconductor 230 remains on the side surface of the conductor 240b on the opening portion 290 side and the side surfaces of the conductor 240a and the conductor 240b on the side opposite to the opening portion 290 in some cases. With such a method, part of the bottom surface of the oxide semiconductor can be removed without using a mask.

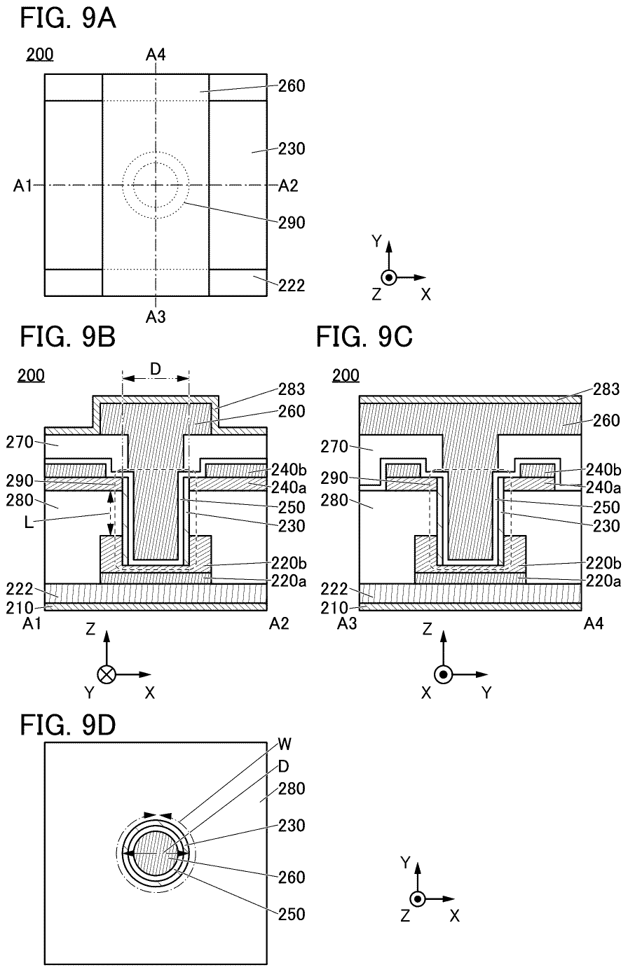

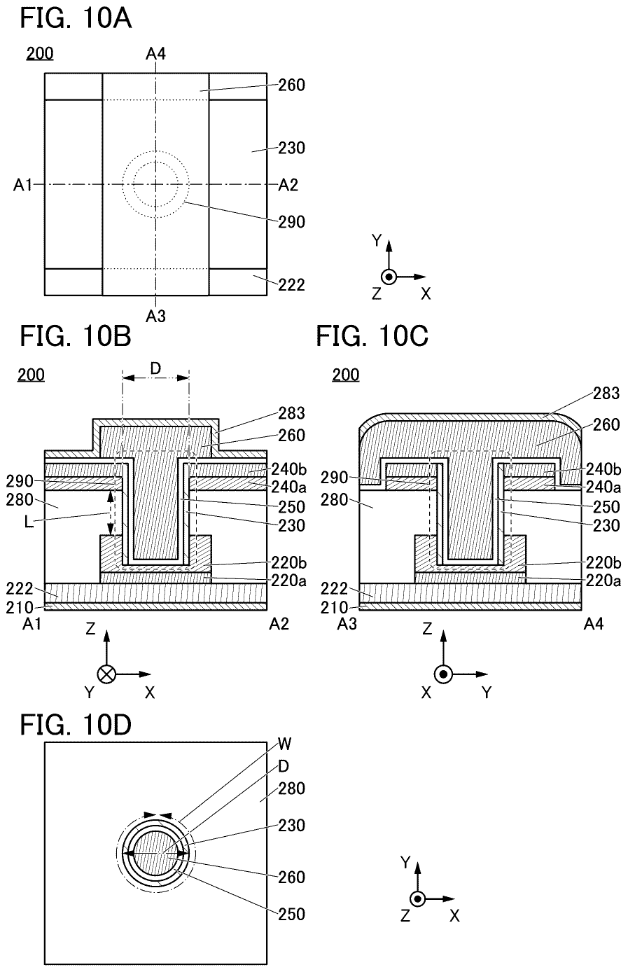

Furthermore, as illustrated in FIG. 9A to FIG. 9D, the insulator 270 can be formed after the formation of the insulator 250 in the case where the oxide semiconductor 230 is processed by anisotropic etching. Moreover, as illustrated in FIG. 10A to FIG. 10D, a structure in which the insulator 270 is not provided can be employed in the case where the oxide semiconductor 230 is processed by anisotropic etching. Furthermore, a structure in which the side surface of the conductor 240a on the opening portion 290 side is aligned with the side surface of the conductor 240b on the opening portion 290 side can be employed.

Although the semiconductor device in FIG. 1A to FIG. 1D has a structure in which one transistor 200 is provided in the opening portion 290, the present invention is not limited thereto. For example, a plurality of transistors 200 can be provided in the opening portion 290.

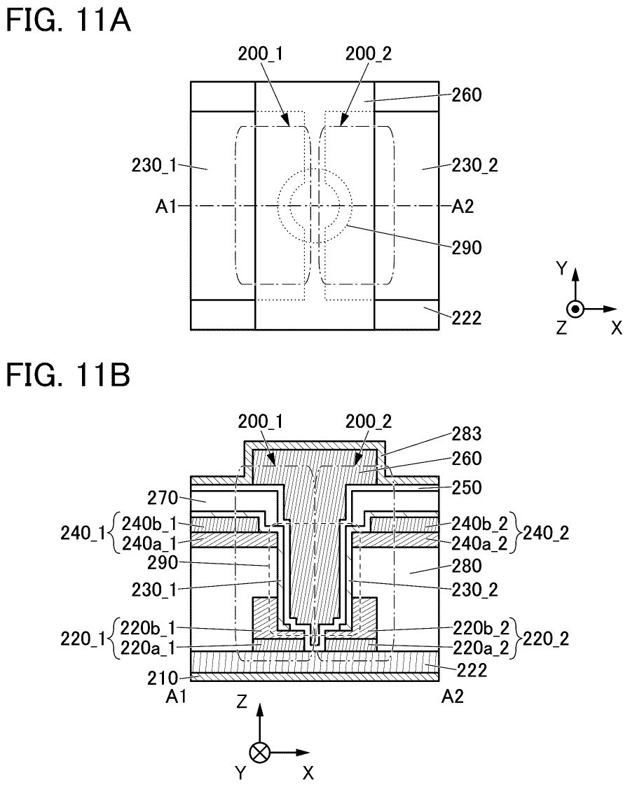

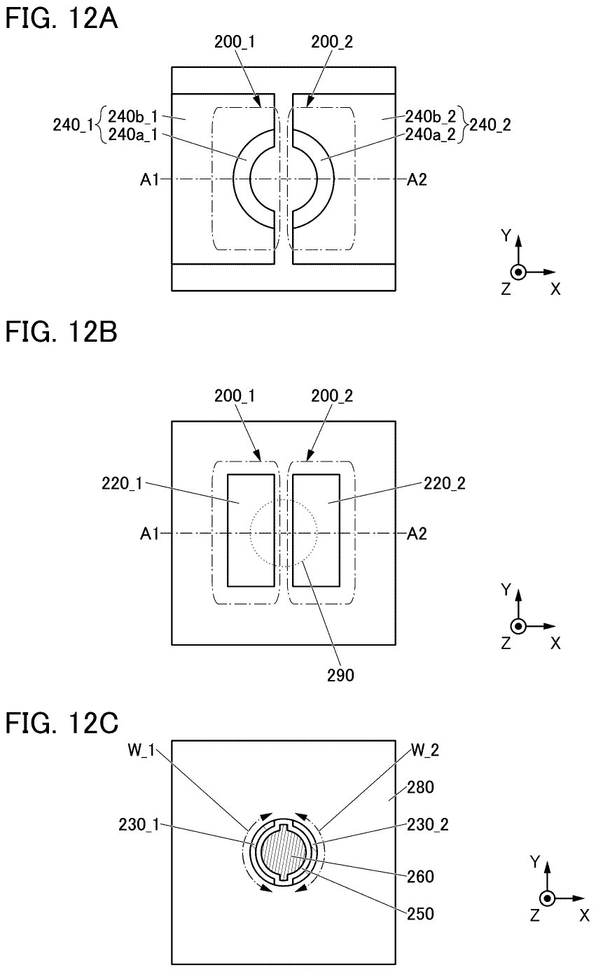

FIG. 11A, FIG. 11B, and FIG. 12A to FIG. 12C illustrate another example of the semiconductor device of one embodiment of the present invention. FIG. 11A, FIG. 12A, and FIG. 12B are plan views of the semiconductor device. FIG. 11B is a cross-sectional view of a portion indicated by the dashed-dotted line A1-A2 in FIG. 11A. FIG. 12C is a cross-sectional view along the XY plane including the insulator 280. Note that some components are omitted in the plan views of FIG. 11A, FIG. 12A, and FIG. 12B for clarity of the drawings.

The semiconductor device illustrated in FIG. 11A to FIG. 12C is different from the semiconductor device illustrated in FIG. 1A to FIG. 1D in that a transistor 200_1 and a transistor 200_2 are provided in the opening portion 290. Differences from the description with reference to FIG. 1A to FIG. 1D are mainly described below; the description is referred to for the same portions, and the description of the same portions is omitted in some cases.

The transistor 200_1 and the transistor 200_2 are provided to be arranged side by side in the X direction. The transistor 200_1 includes an oxide semiconductor 230_1, a conductor 240_1, and a conductor 2201, and the transistor 200_2 includes an oxide semiconductor 230_2, a conductor 240_2, and a conductor 220_2. Here, the conductor 240_1 has a stacked-layer structure of a conductor 240a_1 and a conductor 240b_1, and the conductor 240_2 has a stacked-layer structure of a conductor 240a_2 and a conductor 240b_2. The conductor 220_1 has a stacked-layer structure of a conductor 220a_1 and a conductor 220b_1, and the conductor 220_2 has a stacked-layer structure of a conductor 220a_2 and a conductor 220b_2.

As illustrated in FIG. 11A, FIG. 11B, and FIG. 12C, the oxide semiconductor 230_1 and the oxide semiconductor 230_2 are provided to be arranged side by side in the X direction. In other words, the oxide semiconductor 230_1 and the oxide semiconductor 230_2 are obtained by dividing the oxide semiconductor 230 illustrated in FIG. 1 and are arranged side by side in the X direction.

As illustrated in FIG. 12A, the conductor 240_1 and the conductor 240_2 are provided to be arranged side by side in the X direction. In other words, the conductor 240_1 and the conductor 240_2 are obtained by dividing the conductor 240 illustrated in FIG. 1 and are arranged side by side in the X direction.

As illustrated in FIG. 12B, the conductor 220_1 and the conductor 220_2 are provided to be arranged side by side in the X direction. In other words, the conductor 220_1 and the conductor 220_2 are obtained by dividing the conductor 220 illustrated in FIG. 1 and are arranged side by side in the X direction.

Here, as illustrated in FIG. 12C, the oxide semiconductor 230_1 and the oxide semiconductor 230_2 each have a shape obtained by substantially dividing the oxide 25 semiconductor 230 illustrated in FIG. 1 in half. Thus, a channel width W_1 of the transistor 200_1 and a channel width W_2 of the transistor 200_2 are each approximately half of the channel width W of the transistor 200 or smaller.

When the two transistors are formed in the opening portion 290 as described above, a more highly integrated semiconductor device can be provided.

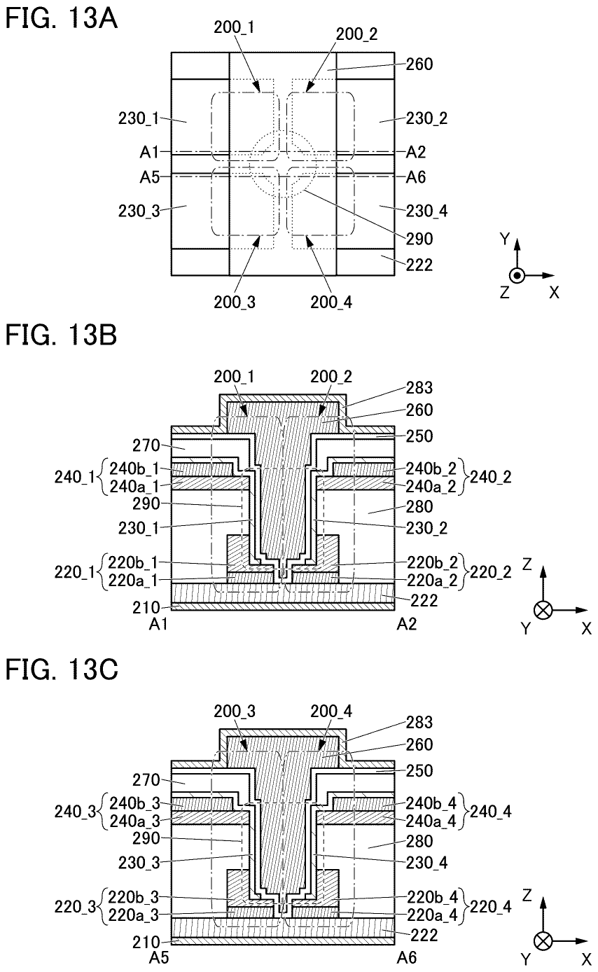

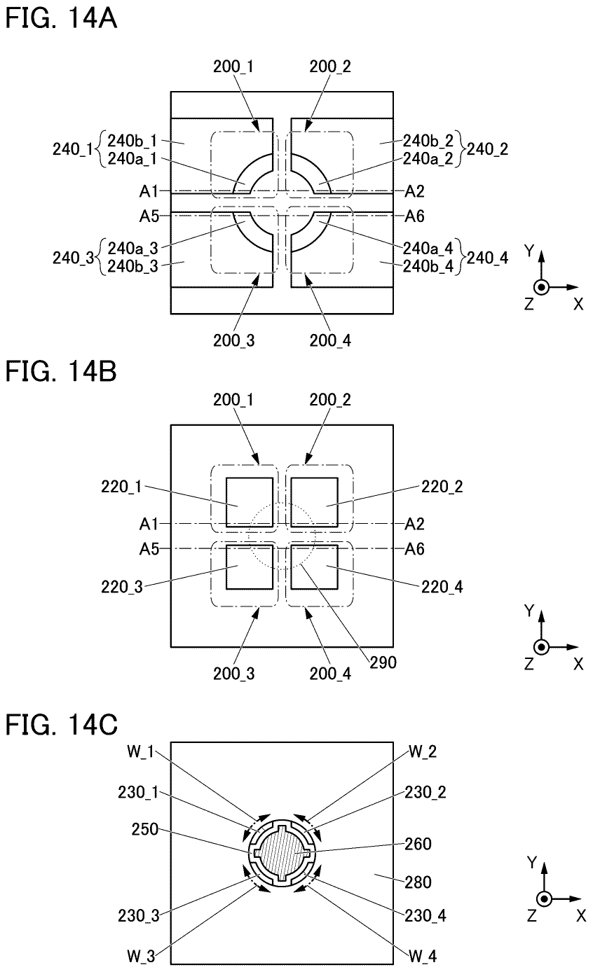

As illustrated in FIG. 13A to FIG. 14C, the transistors may be further divided and four transistors may be provided in the opening portion 290. That is, the transistor 200_1 and the transistor 200_2 illustrated in FIG. 11A to FIG. 12C can be divided in the Y direction to form the transistor 2001, the transistor 2002, a transistor 2003, and a transistor 200_4.

In that case, the oxide semiconductor 230_1 and the oxide semiconductor 230_2 illustrated in FIG. 11A to FIG. 12C can be divided in the Y direction to form the oxide semiconductor 2301, the oxide semiconductor 230_2, an oxide semiconductor 2303, and an oxide semiconductor 230_4. Note that the oxide semiconductor 230_1 to the oxide semiconductor 230_4 each have a shape obtained by substantially dividing the oxide semiconductor 230_1 or the oxide semiconductor 230_2 illustrated in FIG. 11A to FIG. 12C in half. Thus, the channel width W_1 of the transistor 2001, the channel width W_2 of the transistor 200_2, a channel width W_3 of the transistor 2003, and a channel width W_4 of the transistor 200_4 illustrated in FIG. 13 and FIG. 14 are each approximately half of the channel width W_1 of the transistor 200_1 or smaller.

Furthermore, the conductor 240_1 and the conductor 240_2 illustrated in FIG. 11A to FIG. 12C can be divided in the Y direction to form the conductor 2401, the conductor 2402, a conductor 240_3, and a conductor 240_4. Here, the conductor 240_1 to the conductor 240_4 each have a stacked-layer structure of a corresponding one of the conductor 240a_1 to a conductor 240a_4 and a corresponding one of the conductor 240b_1 to a conductor 240b_4.

Furthermore, the conductor 220_1 and the conductor 220_2 illustrated in FIG. 11A to FIG. 12C can be divided in the Y direction to form the conductor 2201, the conductor 2202, a conductor 220_3, and a conductor 220_4. Here, the conductor 220_1 to the conductor 220_4 each have a stacked-layer structure of a corresponding one of the conductor 220a_1 to a conductor 220a_4 and a corresponding one of the conductor 220b_1 to a conductor 220b_4.

When the four transistors are formed in the opening portion 290 as described above, a more highly integrated semiconductor device can be provided.

### <Materials for Semiconductor Device>

Materials that can be used for the semiconductor device are described below.

### [Substrate]

As a substrate where the transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor element, a resistor element, a switching element, a light-emitting element, and a storage element.

### [Insulator]

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as leakage current may arise because of a thinner gate insulator. When a high-k material is used for the insulator functioning as a gate insulator, the voltage at the time of the operation of the transistor can be reduced while the physical thickness is maintained. In addition, the equivalent oxide thickness (EOT) of the insulator functioning as the gate insulator can be reduced. By contrast, when a material with a low relative permittivity is used for an insulator functioning as an interlayer insulating film, the parasitic capacitance generated between wirings can be reduced. Thus, a material is preferably selected in accordance with the function of the insulator. Note that the material with a low relative permittivity is a material with high dielectric strength.

Examples of the material with a high relative permittivity (high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the material with a low relative permittivity include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of an inorganic insulating material with a low relative permittivity include silicon oxide to which fluorine is added, silicon oxide to which carbon is added, and silicon oxide to which carbon and nitrogen are added. Another example is porous silicon oxide. Note that these silicon oxides may contain nitrogen.

Alternatively, a material that can have ferroelectricity may be used for the insulator. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. Here, the atomic ratio of a hafnium atom to the element J1 can be set as appropriate; the atomic ratio of a hafnium atom to the element J1 can be, for example, 1:1 or the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. The atomic ratio of a zirconium atom to the element J2 can be set as appropriate; the atomic ratio of a zirconium atom to the element J2 can be, for example, 1:1 or the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

When a transistor including a metal oxide is surrounded by an insulator having a function of inhibiting passage of impurities and oxygen, the transistor can have stable electrical characteristics. As the insulator having a function of inhibiting passage of oxygen and impurities, a single layer or stacked layers including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used.

Specifically, as the insulator having a function of inhibiting passage of oxygen and impurities, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulator that is in contact with a semiconductor or provided in the vicinity of a semiconductor layer, such as a gate insulator, preferably includes a region containing oxygen released by heating (hereinafter, sometimes referred to as excess oxygen). For example, when an insulator including a region containing excess oxygen is in contact with a semiconductor layer or provided in the vicinity of the semiconductor layer, the number of oxygen vacancies in the semiconductor layer can be reduced. Examples of an insulator in which a region containing excess oxygen is easily formed include silicon oxide, silicon oxynitride, and porous silicon oxide.

Examples of a barrier insulator against oxygen include an oxide containing one or both of aluminum and hafnium, an oxide containing hafnium and silicon (hafnium silicate), magnesium oxide, gallium oxide, gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate).

The contents described in this embodiment can be referred to for a barrier insulator against hydrogen.

A barrier insulator against oxygen and a barrier insulator against hydrogen can each be regarded as a barrier insulator against one or both of oxygen and hydrogen.

The contents described in this embodiment can be referred to for an insulator having a function of capturing or fixing hydrogen.

### [Conductor]

As a conductor, it is preferable to use a metal element selected from aluminum, chromium, copper, silver, gold, platinum, tantalum, nickel, cobalt, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements as its component; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Alternatively, a semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting diffusion of oxygen, or a material maintaining its conductivity even after absorbing oxygen. Examples of the conductive material containing oxygen include indium oxide containing tungsten oxide, indium oxide containing titanium oxide, indium tin oxide, indium tin oxide containing titanium oxide, indium tin oxide to which silicon is added, indium zinc oxide, and indium zinc oxide containing tungsten oxide. In this specification and the like, a conductive film formed using the conductive material containing oxygen may be referred to as an oxide conductive film.

In addition, a conductive material containing tungsten, copper, or aluminum as its main component is preferable because it has high conductivity.

A stack of a plurality of conductive layers formed of the above-described materials may be used. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

In the case where a metal oxide is used for the channel formation region of the transistor, the conductor functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### [Metal Oxide]

A metal oxide sometimes has a lattice defect. Examples of the lattice defect include point defects such as an atomic vacancy and an exotic atom, a line defect such as dislocation, a plane defect such as a crystal grain boundary, and a volume defect such as a void. Examples of a factor in generating a lattice defect include the deviation of the proportion of the number of atoms in constituent elements (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with many lattice defects in a semiconductor layer of a transistor might lead to unstable electrical characteristics of the transistor. Thus, a metal oxide used in a semiconductor layer of a transistor preferably has a small number of lattice defects.

The kind of a lattice defect that is likely to be present in a metal oxide and the number of lattice defects that are present vary depending on the structure of the metal oxide, a method for forming the metal oxide, or the like.

Structures of metal oxides are classified into a single crystal structure and other structures (non-single-crystal structures). Examples of non-single-crystal structures include a CAAC structure, a polycrystalline structure, an nc structure, an amorphous-like (a-like) structure, and an amorphous structure. The a-like structure has a structure between the nc structure and the amorphous structure.

A metal oxide having an a-like structure and a metal oxide having an amorphous structure each include a void or a low-density region. That is, the metal oxide having the a-like structure and the metal oxide having the amorphous structure have low crystallinity as compared with a metal oxide having the nc structure and a metal oxide having the CAAC structure.

Moreover, the metal oxide having the a-like structure has a higher hydrogen concentration in the metal oxide than the metal oxide having the nc structure and the metal oxide having the CAAC structure. Thus, a lattice defect is easily formed in the metal oxide having the a-like structure and the metal oxide having the amorphous structure.

Thus, a metal oxide with high crystallinity is preferably used in a semiconductor layer of a transistor. For example, it is preferable to use the metal oxide having the CAAC structure or the metal oxide having the single crystal structure. The use of such a metal oxide for a transistor enables the transistor to have favorable electrical characteristics. In addition, the transistor can have high reliability.

For the channel formation region of a transistor, a metal oxide that increases the on-state current of the transistor is preferably used. To increase the on-state current of the transistor, the carrier mobility of the metal oxide used for the transistor is preferably increased. To increase the carrier mobility of the metal oxide, the transfer of carriers (electrons in the case of an n-channel transistor) needs to be facilitated or scattering factors that affect the carrier transfer need to be reduced. Note that the carriers flow from the source to the drain through the channel formation region. Thus, the on-state current of the transistor can be increased by providing a channel formation region through which carriers can easily flow in the channel length direction.

Here, it is preferable to use a metal oxide with high crystallinity for a metal oxide including a channel formation region. The crystal further preferably has a crystal structure in which a plurality of layers (for example, a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor and a CAAC-OS.

The c-axis of the above crystal is preferably aligned in the normal direction with respect to the formation surface or film surface of the metal oxide. This enables the plurality of layers to be placed parallel or substantially parallel to the formation surface or film surface of the metal oxide. In other words, the plurality of layers extend in the channel length direction.

The above layered crystal structure including three layers is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal are a YbFe₂O₄ type structure, a Yb₂Fe₃O₇ type structure, their deformed structures, and the like.

Preferably, each of the first layer to the third layer is composed of one metal element or a plurality of metal elements with the same valence and oxygen. The valence of the one or plurality of metal elements included in the first layer is preferably equal to the valence of the one or plurality of metal elements included in the second layer. The first layer and the second layer may include the same metal element. The valence of the one or plurality of metal elements included in the first layer is preferably different from the valence of the one or plurality of metal elements included in the third layer.

The above structure can increase the crystallinity of the metal oxide, which leads to an increase in the carrier mobility of the metal oxide. Thus, the use of the metal oxide for the channel formation region of the transistor increases the on-state current of the transistor, leading to an improvement in the electrical characteristics of the transistor.

Examples of the metal oxide of one embodiment of the present invention include indium oxide, gallium oxide, and zinc oxide. The metal oxide of one embodiment of the present invention preferably contains at least indium (In) or zinc (Zn). The metal oxide preferably contains two or three kinds selected from indium, the element M, and zinc. Note that the element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, still further preferably gallium. When the element M contained in the metal oxide is gallium, the metal oxide of one embodiment of the present invention preferably contains one or more selected from indium, gallium, and zinc. In this specification and the like, a metal element and a metalloid element may be collectively referred to as a “metal element”, and a “metal element” in this specification and the like may refer to a metalloid element.

For example, as the metal oxide of one embodiment of the present invention, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide; also referred to as IGTO), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO or IAGZO) can be used. Alternatively, indium tin oxide containing silicon, gallium tin oxide (Ga—Sn oxide), aluminum tin oxide (Al—Sn oxide), or the like can be used.

By increasing the proportion of the number of indium atoms in the total number of atoms of all the metal elements contained in the metal oxide, the field-effect mobility of the transistor can be increased.

Note that the metal oxide may contain, instead of indium, one or more kinds of metal elements with large period numbers. Alternatively, the metal oxide may contain, in addition to indium, one or more kinds of metal elements with large period numbers. The larger the overlap between orbits of metal elements is, the more likely it is that the metal oxide will have high carrier conductivity. Thus, a transistor containing a metal element with a large period number can have high field-effect mobility in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements included in the metal oxide, the metal oxide has high crystallinity, so that diffusion of impurities in the metal oxide can be inhibited. Consequently, a change in electrical characteristics of the transistor can be inhibited, and the reliability of the transistor can be increased.

By increasing the proportion of the number of atoms of the element M in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor is inhibited, and the reliability of the transistor can be increased.

By increasing the proportion of the number of In atoms in the total number of atoms of all the metal elements included in the metal oxide, high on-state current and excellent frequency characteristics of the transistor can be achieved.

In the description of this embodiment, In—Ga—Zn oxide is sometimes taken as an example of the metal oxide.

For the formation of a metal oxide having the layered crystal structure, atomic layers are preferably deposited one by one. Since an ALD method is employed as the formation method of the metal oxide in one embodiment of the present invention, a metal oxide having the layered crystal structure is easily formed.

### [[Transistor Including Metal Oxide]]

Next, the case where a metal oxide (oxide semiconductor) is used for a transistor is described. Hereinafter, a transistor including silicon in its semiconductor layer is referred to as a Si transistor in some cases.

When the metal oxide (oxide semiconductor) of one embodiment of the present invention is used for a transistor, the transistor with high field-effect mobility can be achieved. In addition, the transistor can have high reliability. Furthermore, a miniaturized or highly integrated transistor can be achieved. For example, a transistor with a channel length greater than or equal to 2 nm and less than or equal to 30 nm can be fabricated.

An oxide semiconductor having a low carrier concentration is preferably used for a channel formation region of a transistor. For example, the carrier concentration in the channel formation region of the oxide semiconductor is lower than or equal to 1×10¹⁸ cm⁻³, preferably lower than or equal to 1×10¹⁷ cm⁻³, further preferably lower than or equal to 1×10¹⁵ cm⁻³, still further preferably lower than or equal to 1×10¹³ cm⁻³, yet further preferably lower than or equal to 1×10¹¹ cm⁻³, yet still further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film can be reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, the impurity concentration in an adjacent film is also preferably reduced. Examples of impurities include hydrogen, carbon, and nitrogen. Note that an impurity in an oxide semiconductor refers to, for example, an element other than the main components of the oxide semiconductor. For example, an element with a concentration lower than 0.1 atomic % can be regarded as an impurity.

The band gap of the oxide semiconductor is preferably larger than the band gap of silicon (typically 1.1 eV), further preferably larger than or equal to 2 eV, still further preferably larger than or equal to 2.5 eV, yet further preferably larger than or equal to 3.0 eV. With the use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a large band gap, and thus can inhibit the short-channel effect. In other words, the OS transistor is a transistor in which the short-channel effect does not appear or hardly appears.

Note that the short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes also referred to as S value), and an increase in leakage current. Here, the S value means the amount of change in gate voltage in the subthreshold region by which the drain current is changed by one order of magnitude at a constant drain voltage.

The characteristic length is widely used as an indicator of resistance to the short-channel effect. The characteristic length is an indicator of curving of potential in a channel formation region. When the characteristic length is shorter, the potential rises more sharply, which means that the resistance to the short-channel effect is high.

The OS transistor is an accumulation-type transistor and the Si transistor is an inversion-type transistor. Accordingly, the OS transistor has a shorter characteristic length between a source region and a channel formation region and a shorter characteristic length between a drain region and the channel formation region than the Si transistor. Thus, the OS transistor has higher resistance to the short-channel effect than the Si transistor. That is, in the case where a transistor with a short channel length is to be manufactured, the OS transistor is more suitable than the Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to larger than or equal to 0.1 eV and smaller than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure where the channel formation region becomes an n⁻-type region and the source region and the drain region become n⁺-type regions.

An OS transistor having the above structure enables favorable electrical characteristics even when the semiconductor device is miniaturized or highly integrated. For example, favorable electrical characteristics can be obtained even when the OS transistor has a channel length or a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Thus, an OS transistor can be used as a transistor with a short channel length more suitably than a Si transistor. Note that the gate length refers to the length of a gate electrode in a direction in which carriers move in a channel formation region during operation of the transistor.

Miniaturization of the OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz in a room temperature environment, for example.

As described above, the OS transistor has effects superior to those of the Si transistor, such as low off-state current and capability of having a short channel length.

### [[Impurity in Metal Oxide]]

Here, the influence of each impurity in the metal oxide (oxide semiconductor) is described.

When silicon or carbon, which is one of Group 14 elements, is contained in the oxide semiconductor, defect states are formed in the oxide semiconductor. Thus, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor that contains nitrogen as a semiconductor is likely to have normally-on characteristics. When nitrogen is contained in the oxide semiconductor, trap states are sometimes formed. This might make the electrical characteristics of the transistor unstable. Therefore, the concentration of nitrogen in the channel formation region in the oxide semiconductor, which is obtained by SIMS, is set lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet further preferably lower than 1×10¹⁸ atoms/cm³, yet still further preferably lower than 1×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the channel formation region of the oxide semiconductor that is obtained by SIMS is set lower than or equal to 1×10¹⁸ atoms/cm³, preferably lower than or equal to 2×10¹⁶ atoms/cm³.

When an oxide semiconductor with sufficiently reduced impurities is used for the channel formation region of the transistor, stable electrical characteristics can be given.

### [Other Semiconductor Materials]

The oxide semiconductor 230 can be rephrased as a semiconductor layer including a channel formation region of the transistor. A semiconductor material that can be used for the semiconductor layer is not limited to the above metal oxides. A semiconductor material that has a band gap (a semiconductor material that is not a zero-gap semiconductor) may be used for the semiconductor layer. For example, a single element semiconductor, a compound semiconductor, or a layered substance (also referred to as an atomic layer substance, a two-dimensional material, or the like) is preferably used as a semiconductor material.

Here, in this specification and the like, the layered substance generally refers to a group of materials having a layered crystal structure. The layered crystal structure is a structure in which layers formed by covalent bonding or ionic bonding are stacked with bonding such as the Van der Waals bonding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having high on-state current can be provided.

Examples of the single element semiconductor that can be used as the semiconductor material include silicon and germanium. Examples of silicon that can be used for the semiconductor layer include single crystal silicon, polycrystalline silicon, microcrystalline silicon, and amorphous silicon. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

Examples of the layered substance include graphene, silicene, boron carbonitride, and chalcogenide. Boron carbonitride serving as the layered substance contains carbon, nitrogen, and boron atoms arranged in a hexagonal lattice structure on a plane. Chalcogenide is a compound containing chalcogen. Chalcogen is a general term for elements belonging to Group 16, which includes oxygen, sulfur, selenium, tellurium, polonium, and livermorium. Examples of chalcogenide include transition metal chalcogenide and chalcogenide of Group 13 elements.

For the semiconductor layer, transition metal chalcogenide functioning as a semiconductor is preferably used, for example. Specific examples of the transition metal chalcogenide that can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer enables a semiconductor device with high on-state current to be provided.

This embodiment can be combined with the other embodiments and Example as appropriate. In this specification, in the case where a plurality of structure examples are shown in one embodiment, the structure examples can be combined as appropriate.

### Embodiment 2

A semiconductor device 900 of one embodiment of the present invention is described in this embodiment. The semiconductor device 900 can function as a memory device.

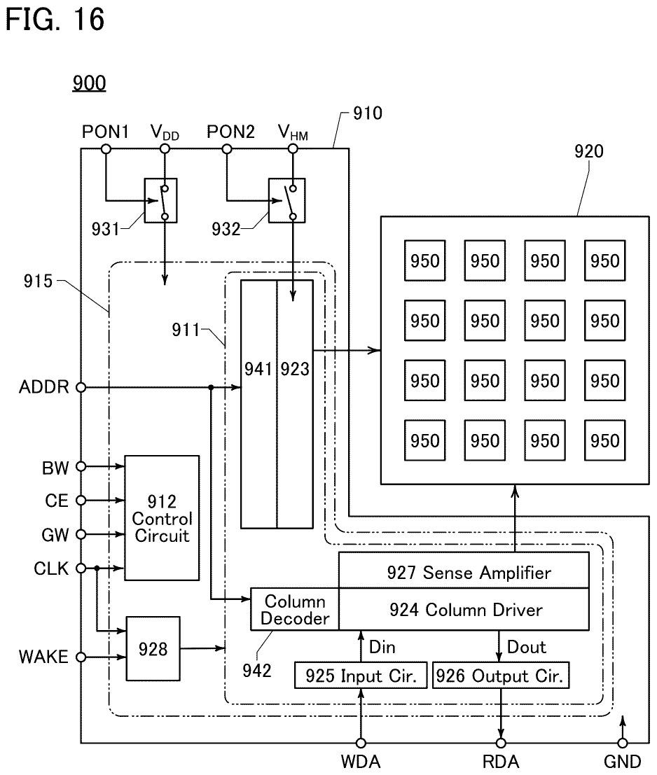

FIG. 16 shows a block diagram showing a structure example of the semiconductor device 900. The semiconductor device 900 shown in FIG. 16 includes a driver circuit 910 and a memory array 920. The memory array 920 includes at least one memory cell 950. FIG. 16 shows an example in which the memory array 920 includes a plurality of memory cells 950 arranged in a matrix.

The transistor described as an example in the above embodiment can be used for the memory cell 950. The use of the above-described transistor allows miniaturization and high integration of the memory device. In addition, the capacity per area of the memory device can be increased.

The driver circuit 910 includes a PSW 931 (power switch), a PSW 932, and a peripheral circuit 915. The peripheral circuit 915 includes a peripheral circuit 911, a control circuit 912, and a voltage generation circuit 928.

In the semiconductor device 900, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 912.

The control circuit 912 is a logic circuit having a function of controlling the overall operation of the semiconductor device 900. For example, the control circuit 912 performs logical operation on the signal CE, the signal GW, and the signal BW to determine an operation mode of the semiconductor device 900 (e.g., write operation or read operation). Alternatively, the control circuit 912 generates a control signal for the peripheral circuit 911 so that the operation mode is executed.

The voltage generation circuit 928 has a function of generating negative voltage. The signal WAKE has a function of controlling the input of the signal CLK to the voltage generation circuit 928. For example, when an H-level signal is supplied as the signal WAKE, the signal CLK is input to the voltage generation circuit 928, and the voltage generation circuit 928 generates negative voltage.

The peripheral circuit 911 is a circuit for performing writing and reading of data to/from the memory cell 950. The peripheral circuit 911 includes a row decoder 941, a column decoder 942, a row driver 923, a column driver 924, an input circuit 925 (Input Cir.), an output circuit 926 (Output Cir.), and a sense amplifier 927.

The row decoder 941 and the column decoder 942 have a function of decoding the signal ADDR. The row decoder 941 is a circuit for specifying a row to be accessed, and the column decoder 942 is a circuit for specifying a column to be accessed. The row driver 923 has a function of selecting the row specified by the row decoder 941. The column driver 924 has a function of writing data to the memory cell 950, a function of reading data from the memory cell 950, a function of retaining the read data, and the like.

The input circuit 925 has a function of retaining the signal WDA. Data retained by the input circuit 925 is output to the column driver 924. Data output from the input circuit 925 is data (Din) to be written to the memory cell 950. Data (Dout) read from the memory cell 950 by the column driver 924 is output to the output circuit 926. The output circuit 926 has a function of retaining Dout. In addition, the output circuit 926 has a function of outputting Dout to the outside of the semiconductor device 900. Data output from the output circuit 926 is the signal RDA.

The PSW 931 has a function of controlling the supply of VDD to the peripheral circuit 915. The PSW 932 has a function of controlling supply of VHM to the row driver 923. Here, in the semiconductor device 900, high power supply voltage is VDD and low power supply voltage is GND (a ground potential). In addition, VHM is high power supply voltage used to set the word line at a high level and is higher than VDD. The on/off state of the PSW 931 is controlled by the signal PON1, and the on/off state of the PSW 932 is controlled by the signal PON2. The number of power domains to which VDD is supplied is one in the peripheral circuit 915 in FIG. 16 but can be more than one. In that case, a power switch may be provided for each power domain.

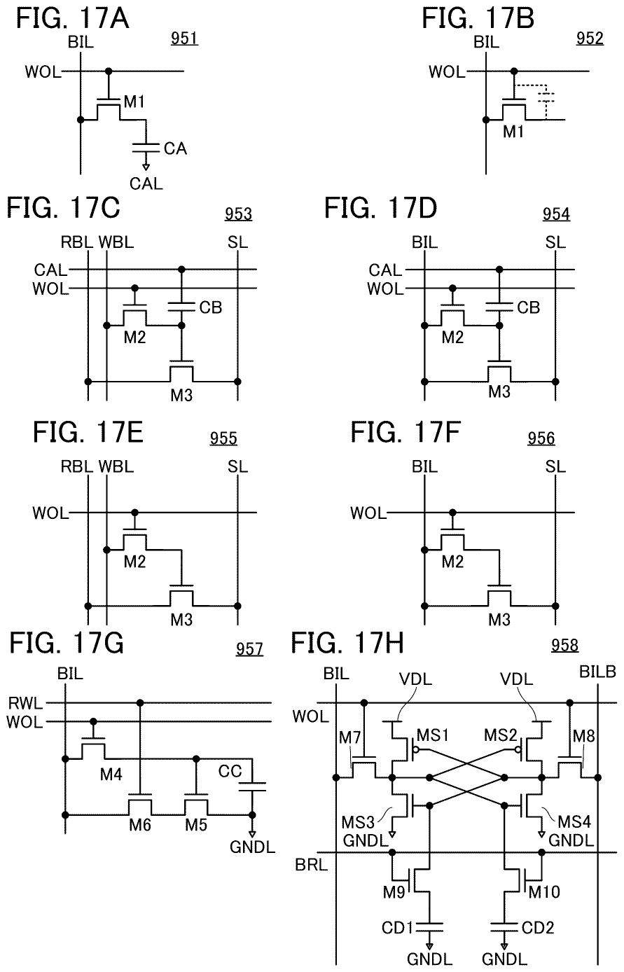

A structure example of another memory cell that can be used for the memory cell 950 is described with reference to FIG. 17A to FIG. 17H.

### [DOSRAM]

FIG. 17A illustrates a circuit configuration example of a memory cell of DRAM. In this specification and the like, a DRAM using an OS transistor is referred to as a DOSRAM (Dynamic Oxide Semiconductor Random Access Memory). A memory cell 951 includes a transistor M1 and a capacitor CA.

Note that the transistor M1 may include a front gate (simply referred to as a gate in some cases) and a back gate. Here, the back gate may be connected to a wiring supplied with a constant potential or a signal, and the front gate and the back gate may be connected to each other.

A first terminal of the transistor M1 is connected to a first terminal of the capacitor CA, a second terminal of the transistor M1 is connected to a wiring BIL, and a gate of the transistor M1 is connected to a wiring WOL. A second terminal of the capacitor CA is connected to the wiring CAL.

The wiring BIL functions as a bit line, and the wiring WOL functions as a word line. The wiring CAL functions as a wiring for applying a predetermined potential to the second terminal of the capacitor CA. At the time of data writing and reading, a low-level potential (also referred to as a reference potential in some cases) is preferably applied to the wiring CAL.

Data writing and data reading are performed as follows: a high-level potential is applied to the wiring WOL to turn on the transistor M1, and thus the wiring BIL is connected to the first terminal of the capacitor CA.

The memory cell that can be used as the memory cell 950 is not limited to the memory cell 951, and the circuit configuration can be changed. For example, a structure of a memory cell 952 illustrated in FIG. 17B can be employed. The memory cell 952 is an example including neither the capacitor CA nor the wiring CAL. The first terminal of the transistor M1 is in an electrically floating state.

In the memory cell 952, a potential written through the transistor M1 is retained in a capacitor (also referred to as parasitic capacitance) between the first terminal and the gate, which is indicated by a dashed line. Such a structure can greatly simplify the structure of the memory cell.

It is preferable to use, as the transistor M1, the OS transistor described in the above embodiment. With use of the OS transistor described in the above embodiment, the area occupied by a memory cell can be reduced. The OS transistor has characteristics of having extremely low off-state current. The use of an OS transistor as the transistor M1 enables extremely low leakage current of the transistor M1. That is, with the use of the transistor M1, written data can be retained for a long time, and thus the frequency of the refresh operation for the memory cell can be decreased. Alternatively, refresh operation for the memory cell can be unnecessary. In addition, the extremely low leakage current allows multi-level data or analog data to be retained in the memory cell 951 and the memory cell 952.

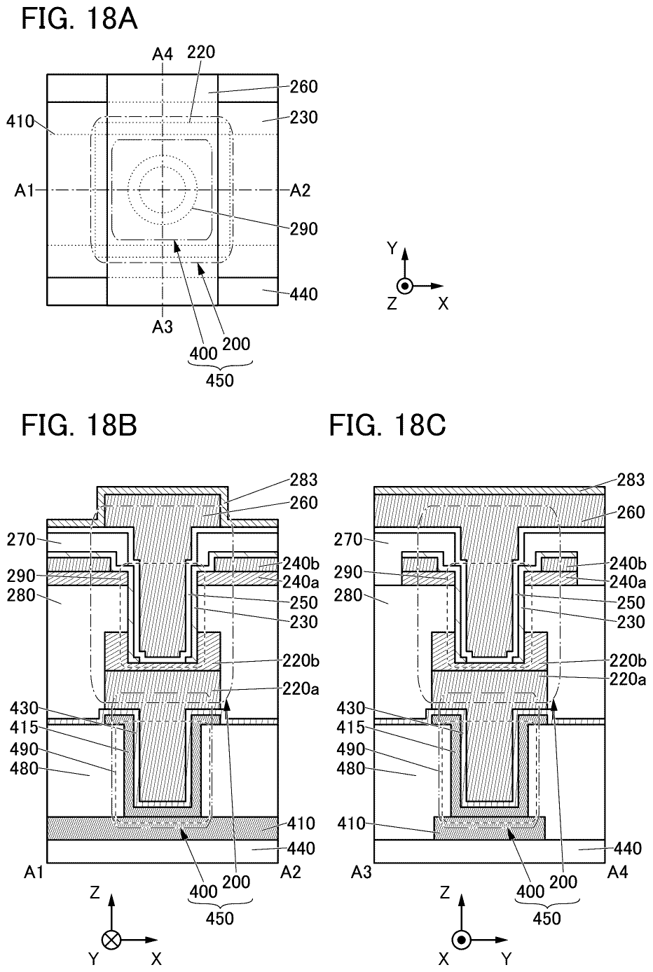

Here, an example of the structure of a DOSRAM is described with reference to FIG. 18. FIG. 18A to FIG. 18C are a plan view and cross-sectional views of the memory device including the transistor 200 and a capacitor 400. FIG. 18A is a plan view of the memory device. FIG. 18B and FIG. 18C are cross-sectional views of the memory device. Here, FIG. 18B is a cross-sectional view of a portion indicated by the dashed-dotted line A1-A2 in FIG. 18A. FIG. 18C is a cross-sectional view of a portion indicated by the dashed-dotted line A3-A4 in FIG. 18A. Note that for clarity of the drawing, some components are not illustrated in the plan view of FIG. 18A.

The memory device illustrated in FIG. 18A to FIG. 18C includes an insulator 440 over a substrate (not illustrated), a conductor 410 over the insulator 440, a memory cell 450 over the conductor 410, an insulator 480 over the conductor 410, the insulator 280, and the insulator 283 over the memory cell 450. The insulator 440, the insulator 480, and the insulator 280 each function as an interlayer film. The conductor 410 functions as a wiring.

The memory cell 450 includes the capacitor 400 over the conductor 410 and the transistor 200 over the capacitor 400. Here, the transistor described in Embodiment 1 may be used as the transistor 200. The description in Embodiment 1 can be referred to for the details of the transistor 200.

The capacitor 400 includes a conductor 415 over the conductor 410, an insulator 430 over the conductor 415, and the conductor 220a over the insulator 430. The conductor 220a functions as one of a pair of electrodes (sometimes referred to as an upper electrode), the conductor 415 functions as the other of the pair of electrodes (sometimes referred to as a lower electrode), and the insulator 430 functions as a dielectric. That is, the capacitor 400 forms a M1M (Metal-Insulator-Metal) capacitor.

As illustrated in FIG. 18B and FIG. 18C, an opening portion 490 reaching the conductor 410 is provided in the insulator 480. At least part of the conductor 415 is placed in the opening portion 490. The conductor 415 includes a region in contact with the top surface of the conductor 410 in the opening portion 490, a region in contact with the side surface of the insulator 480 in the opening portion 490, and a region in contact with at least part of the top surface of the insulator 480. The insulator 430 is placed such that at least part of the insulator 430 is positioned in the opening portion 490. At least part of the conductor 220a is placed to be positioned in the opening portion 490. Note that the conductor 220a is preferably provided to fill the opening portion 490 as illustrated in FIG. 18B and FIG. 18C.

The capacitor 400 has a structure in which the upper electrode and the lower electrode face each other with the dielectric therebetween on the side surface as well as on the bottom surface of the opening portion 490; thus, the capacitance per unit area can be increased. Accordingly, the deeper the opening portion 490 is, the larger the capacitance of the capacitor 400 can be. Increasing the capacitance per unit area of the capacitor 400 in this manner enables a stable reading operation of the memory device. This also allows further miniaturization or high integration of the memory device.

Note that the sidewall of the opening portion 490 is preferably perpendicular to the top surface of the conductor 410. In that case, the opening portion 490 has a cylindrical shape. With the structure, the memory device can be miniaturized or highly integrated.

The conductor 415 and the insulator 430 are provided to be stacked along the sidewall of the opening portion 490 and the top surface of the conductor 410. The conductor 220a is provided over the insulator 430 to fill the opening portion 490. The capacitor 400 having such a structure may be referred to as a trench-type capacitor or a trench capacitor.

As illustrated in FIG. 18A to FIG. 18C, the transistor 200 is provided to overlap with the capacitor 400. The opening portion 290 where part of the structure of the transistor 200 is provided includes a region overlapping with the opening portion 490 where part of the structure of the capacitor 400 is provided. In particular, since the conductor 220a has a function of one of the source electrode and the drain electrode of the transistor 200 and a function of the upper electrode of the capacitor 400, the transistor 200 and the capacitor 400 partly share the structure. With such a structure, the transistor 200 and the capacitor 400 can be provided without a great increase in the occupation area in the plan view. Thus, the area occupied by the memory cell 450 can be reduced, so that the memory cells 450 can be arranged densely and the memory capacity of the memory device can be increased. In other words, the memory device can be highly integrated.

The structure illustrated in FIG. 18A to FIG. 18C functions as, for example, the DOSRAM memory cell 951 illustrated in FIG. 17A. The transistor M1 corresponds to the transistor 200 and the capacitor CA corresponds to the capacitor 400.

Here, the wiring BIL corresponds to the conductor 240 (the conductor 240a and the conductor 240b), the wiring WOL corresponds to the conductor 260, and the wiring CAL corresponds to the conductor 410. As illustrated in FIG. 18A to FIG. 18C, it is preferable that the conductor 260 be provided to extend in the Y direction and the conductor 240 be provided to extend in the X direction. With such a structure, the wiring BIL and the wiring WOL are provided to intersect with each other. Although the wiring CAL (the conductor 410) is provided to extend in the X direction in FIG. 18A, the present invention is not limited thereto. For example, the wiring CAL may be provided to extend in the Y direction or may be provided to have a planar shape.

The conductor 410 is provided over the insulator 440. As the conductor 410, a single layer or stacked layers of any of the conductors in the section [Conductor] in Embodiment 1 can be used. Moreover, a conductive material with high conductivity such as tungsten can be used for the conductor 410, for example. With the use of a conductive material with high conductivity, the conductor 410 can have improved conductivity and can serve well as the wiring CAL.

A single layer or stacked-layer including a conductive material that is less likely to be oxidized, a conductive material having a function of inhibiting diffusion of oxygen, or the like is preferably used for the conductor 410. For example, titanium nitride, indium tin oxide to which silicon is added, or the like may be used. Alternatively, for example, a structure in which titanium nitride is stacked over tungsten may be used. Alternatively, for example, a structure in which tungsten is stacked over a first titanium nitride and a second titanium nitride is stacked over the tungsten may be used. With such a structure, when an oxide insulator is used for the insulator 480, the conductor 410 can be inhibited from being oxidized by the insulator 480.

As the conductor 415, a single layer or stacked layers of any of the conductors described in the section [Conductor] in Embodiment 1 can be used. In addition, a conductive material that is less likely to be oxidized, a conductive material having a function of inhibiting diffusion of oxygen, or the like is preferably used for the conductor 415. For example, titanium nitride, tantalum nitride, or the like can be used. For example, a structure in which tantalum nitride is stacked over titanium nitride may be used. With such a structure, when an oxide insulator is used as the insulator 430, the conductor 415 can be inhibited from being oxidized by the insulator 430. Such a structure can also inhibit oxidation of the conductor 415 by the insulator 480 when an oxide insulator is used as the insulator 480.

The insulator 430 is provided over the conductor 415. The insulator 430 is provided in contact with the top surface and the side surface of the conductor 415. That is, the insulator 430 preferably covers the side end portion of the conductor 415. This can prevent a short circuit between the conductor 415 and the conductor 220a.

Alternatively, the side end portion of the insulator 430 and the side end portion of the conductor 415 may be aligned with each other. This structure enables the insulator 430 and the conductor 415 to be formed using the same mask, so that the fabrication process of the memory device can be simplified.

For the insulator 430, any of materials with a high relative permittivity, that is, high-k materials, described in the section [Insulator] in Embodiment 1 is preferably used. Using such a high-k material for the insulator 430 allows the insulator 430 to be thick enough to inhibit leakage current and the capacitor 400 to have a sufficiently high capacitance.

It is preferable for the insulator 430 to use stacked insulating layers formed of any of the high-k materials, and it is preferable to use a stacked-layer structure of a high relative permittivity (high-k) material and a material having a higher dielectric strength than the high-k material. As the insulator 430, an insulating film in which zirconium oxide, aluminum oxide, and zirconium oxide are stacked in this order can be used, for example. An insulating film in which zirconium oxide, aluminum oxide, zirconium oxide, and aluminum oxide are stacked in this order can be used, for example. Alternatively, an insulating film in which hafnium zirconium oxide, aluminum oxide, hafnium zirconium oxide, and aluminum oxide are stacked in this order can be used, for example. The use of stacked insulators with relatively high dielectric strength, such as aluminum oxide, can increase the dielectric strength and inhibit electrostatic breakdown of the capacitor 400.

A material that can have ferroelectricity may be used for the insulator 430. Examples of the material that can have ferroelectricity include metal oxides such as hafnium oxide, zirconium oxide, and HfZrO_{X} (X is a real number greater than 0). Examples of the material that can have ferroelectricity also include a material in which the element J1 (the element J1 here is one or more selected from zirconium, silicon, aluminum, gadolinium, yttrium, lanthanum, strontium, and the like) is added to hafnium oxide. Here, the atomic ratio of a hafnium atom to the element J1 can be set as appropriate; the atomic ratio of a hafnium atom to the element J1 can be, for example, 1:1 or the neighborhood thereof. Examples of the material that can have ferroelectricity also include a material in which the element J2 (the element J2 here is one or more selected from hafnium, silicon, aluminum, gadolinium, yttrium, lanthanum, strontium, and the like) is added to zirconium oxide. The atomic ratio of a zirconium atom to the element J2 can be set as appropriate; the atomic ratio of a zirconium atom to the element J2 can be, for example, 1:1 or the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can have ferroelectricity also include a metal nitride containing an element M1, an element M2, and nitrogen. Here, the element M1 is one or more selected from aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen has ferroelectricity in some cases even though the metal oxide does not contain the element M2. Examples of the material that can have ferroelectricity also include a material in which an element M3 is added to the above metal nitride. Note that the element M3 is one or more selected from magnesium, calcium, strontium, zinc, cadmium, and the like. Here, the ratio between the number of atoms of the element M1, the number of atoms of the element M2, and the number of atoms of the element M3 can be set as appropriate.

Examples of the material that can have ferroelectricity also include a perovskite-type oxynitride such as SrTaO₂N or BaTaO₂N, GaFeO₃ with a x-alumina-type structure, and the like.

In the above description, metal oxides and metal nitrides are presented as non-limiting examples. For example, a metal oxynitride in which nitrogen is added to any of the above metal oxides, a metal nitride oxide in which oxygen is added to any of the above metal nitrides, or the like may be used.

The material that can have ferroelectricity can be, for example, a mixture or a compound formed of a plurality of materials selected from the above-listed materials. Alternatively, the insulator 430 can have a stacked-layer structure of a plurality of materials selected from the above-listed materials. Note that the crystal structures (properties) of the above-listed materials and the like can be changed depending on the processes as well as the formation conditions; thus, a material that exhibits ferroelectricity is referred to not only as a ferroelectric but also as a material that can have ferroelectricity in this specification and the like.

A metal oxide containing one or both of hafnium and zirconium is preferable because the metal oxide can have ferroelectricity even when being a thin film of several nanometers. Here, the thickness of the insulator 430 can be less than or equal to 100 nm, preferably less than or equal to 50 nm, further preferably less than or equal to 20 nm, still further preferably less than or equal to 10 nm (typically greater than or equal to 2 nm and less than or equal to 9 nm). The thickness is preferably greater than or equal to 8 nm and less than or equal to 12 nm, for example. When a ferroelectric layer that can be thinned is used, the capacitor 400 can be combined with a semiconductor element such as a miniaturized transistor to form a semiconductor device. Note that in this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

A metal oxide containing one or both of hafnium and zirconium is preferable because the metal oxide can have ferroelectricity even with a minute area. For example, a ferroelectric layer can have ferroelectricity even with an area (occupying area) less than or equal to 100 μm², less than or equal to 10 μm², less than or equal to 1 μm², or less than or equal to 0.1 μm² in a plan view. Furthermore, even a ferroelectric layer with an area less than or equal to 10000 nm² or less than or equal to 1000 nm² has ferroelectricity in some cases. With a small-area ferroelectric layer, the area occupied by the capacitor 400 can be reduced.

The ferroelectric is an insulator and has a property of causing internal polarization by application of an electric field from the outside and maintaining the polarization even after the electric field is made zero. Thus, with a capacitor that includes this material as a dielectric (hereinafter, the capacitor may be referred to as a ferroelectric capacitor), a nonvolatile memory element can be formed. A nonvolatile memory element that includes a ferroelectric capacitor is sometimes referred to as an FeRAM (Ferroelectric Random Access Memory), a ferroelectric memory, or the like. For example, a ferroelectric memory includes a transistor and a ferroelectric capacitor, and one of a source and a drain of the transistor is electrically connected to one terminal of the ferroelectric capacitor. Thus, in the case of using a ferroelectric capacitor as the capacitor 400, the memory device described in this embodiment functions as a ferroelectric memory.

It is considered that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulator 430 can exhibit ferroelectricity, the insulator 430 needs to include a crystal. It is particularly preferable that the insulator 430 include a crystal having an orthorhombic crystal structure to exhibit ferroelectricity. Note that a crystal structure of a crystal included in the insulator 430 may be one or more selected from a cubic crystal structure, a tetragonal crystal structure, an orthorhombic crystal structure, a monoclinic crystal structure, and a hexagonal crystal structure. Alternatively, the insulator 430 may have an amorphous structure. In that case, the insulator 430 may have a composite structure including an amorphous structure and a crystal structure.

The conductor 220a is provided in contact with part of the top surface of the insulator 430. The conductor 220a is similar to the one used for the transistor 200. A structure in which the conductor 220c is stacked under the conductor 220a can be employed.

The insulator 480, which functions as an interlayer film, preferably has a low relative permittivity. When a material with a low relative permittivity is used for an interlayer film, the parasitic capacitance generated between wirings can be reduced. As the insulator 480, a single layer or stacked layers of insulators containing any of the materials with a low relative permittivity described in the section [Insulator] in Embodiment 1 can be used. Silicon oxide and silicon oxynitride are preferable because they are thermally stable. Here, the insulator 480 contains at least silicon and oxygen.

Although FIG. 18B and FIG. 18C show a single-layer of the insulator 480, the present invention is not limited thereto. The insulator 480 may have a stacked-layer structure. In the case of employing a stacked-layer structure, an insulator having a barrier property against hydrogen, which is described in the section [Insulator] in Embodiment 1, is preferably used for one or more layers of the insulator 480. In that case, diffusion of hydrogen into the insulator 430 from below through the insulator 480 and the conductor 415 can be inhibited. Silicon nitride and silicon nitride oxide can be suitably used for the insulator 480 because silicon nitride and silicon nitride oxide release fewer impurities (e.g., water and hydrogen) and are less likely to transmit oxygen and hydrogen.

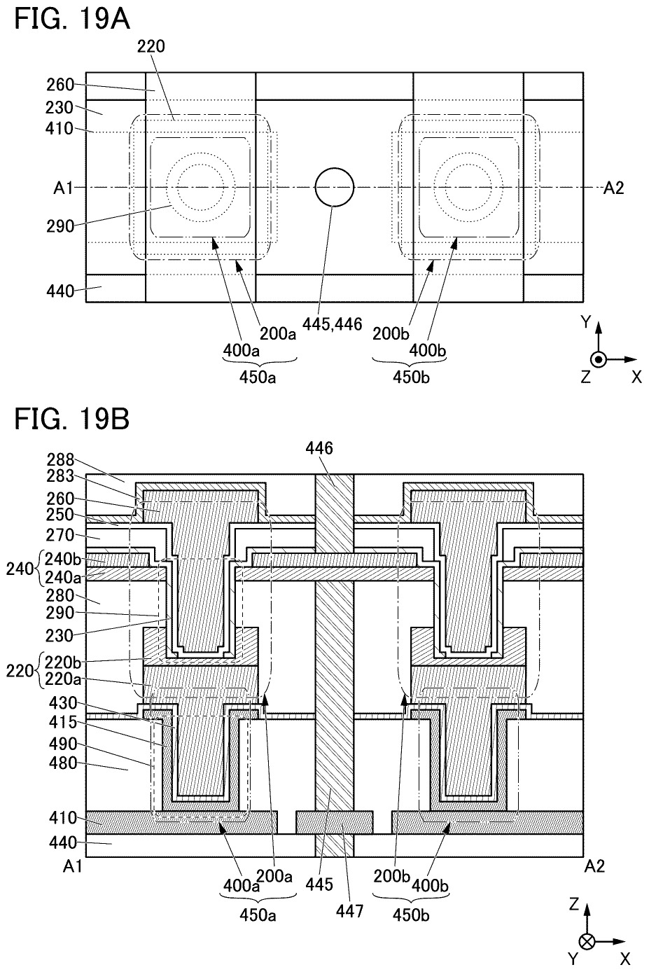

An example of a memory device in which two memory cells 450 (hereinafter referred to as a memory cell 450a and a memory cell 450b) are connected to a common wiring is described with reference to FIG. 19A and FIG. 19B. FIG. 19A is a plan view of the memory device. FIG. 19B is a cross-sectional view of a portion indicated by the dashed-dotted line A1-A2 in FIG. 19A. Note that some components are omitted in the plan view in FIG. 19A for clarity of the drawing.

Here, the memory cell 450a and the memory cell 450b illustrated in FIG. 19A and FIG. 19B each have a structure similar to that of the memory cell 450. The memory cell 450a includes a capacitor 400a and a transistor 200a, and the memory cell 450b includes a capacitor 400b and a transistor 200b. Thus, in the memory device illustrated in FIG. 19A and FIG. 19B, components having the same functions as the components of the memory device illustrated in FIG. 18 are denoted by the same reference numerals.

As illustrated in FIG. 19A and FIG. 19B, the conductor 260 functioning as the wiring WOL is provided in each of the memory cell 450a and the memory cell 450b. The conductor 240 functioning as part of the wiring BIL is provided to be shared by the memory cell 450a and the memory cell 450b. That is, the conductor 240 is in contact with the oxide semiconductor 230 of the memory cell 450a and the oxide semiconductor 230 of the memory cell 450b.

Here, the memory device illustrated in FIG. 19A and FIG. 19B includes a conductor 445 and a conductor 446 functioning as plugs (which can also be referred to as connection electrodes) electrically connected to the memory cell 450a and the memory cell 450b. The conductor 445 is placed in an opening formed in the insulator 480, the insulator 430, and the insulator 280 and is in contact with the bottom surface of the conductor 240a and the top surface of the conductor 447 formed in the same layer as the conductor 410. The conductor 446 is placed in an opening formed in an insulator 288, the insulator 283, the insulator 250, the insulator 270, and the oxide semiconductor 230 and is in contact with the top surface of the conductor 240b. A conductor similar to the conductor 446 may be provided under the conductor 447. In addition, a conductive material or the like that can be used for the conductor 240 can be used for the conductor 445 and the conductor 446.

The insulator 288 is provided over the insulator 283. The insulator 288 functions as an interlayer film and thus preferably has a low relative permittivity. When a material with a low relative permittivity is used for an interlayer film, the parasitic capacitance generated between wirings can be reduced. As the insulator 288, a single layer or stacked layers of insulators containing any of the materials with a low relative permittivity described in the section [Insulator] described in Embodiment 1 can be used.

Here, the conductor 445 and the conductor 446 function as plugs or wirings for electrically connecting the memory cell 450a and the memory cell 450b to a circuit element such as a switch, a transistor, a capacitor, an inductor, a resistor, or a diode, a wiring, an electrode, or a terminal. For example, the memory cell 450a and the memory cell 450b can be electrically connected to a sense amplifier provided below the memory device or another memory device provided above the memory device. In that case, the conductor 445 and the conductor 446 function as part of the wiring BIL. When the memory device or the like is provided above or below the memory device illustrated in FIG. 19 in this manner, the memory capacity per unit area can be increased.

The memory cell 450a and the memory cell 450b have a line-symmetric structure with a perpendicular bisector of the dashed-dotted line A1-A2 as the symmetric axis. Thus, the transistor 200a and the transistor 200b are also placed symmetrically with the conductor 445 and the conductor 446 therebetween. Here, the conductor 240 has a function of the other of a source electrode and a drain electrode of the transistor 200a and a function of the other of a source electrode and a drain electrode of the transistor 200b. The transistor 200a and the transistor 200b share the conductor 445 and the conductor 446 functioning as plugs. Accordingly, when the two transistors and the plug are connected as described above, a memory device that can be miniaturized or highly integrated can be provided.

Note that the conductor 410 functioning as the wiring CAL may be provided in each of the memory cell 450a and the memory cell 450b or may be provided to be shared by the memory cell 450a and the memory cell 450b. However, as illustrated in FIG. 19B, the conductor 410 is provided to be apart from the conductor 447 so that the conductor 410 and the conductor 447 are not short-circuited.

### [NOSRAM]

FIG. 17C illustrates a circuit configuration example of a gain-cell memory cell including two transistors and one capacitor. A memory cell 953 includes a transistor M2, a transistor M3, and a capacitor CB. In this specification and the like, a memory device including a gain memory cell using an OS transistor as the transistor M2 is referred to as a NOSRAM (Nonvolatile Oxide Semiconductor RAM).

A first terminal of the transistor M2 is connected to a first terminal of the capacitor CB, a second terminal of the transistor M2 is connected to a wiring WBL, and a gate of the transistor M2 is connected to the wiring WOL. A second terminal of the capacitor CB is connected to the wiring CAL. A first terminal of the transistor M3 is connected to a wiring RBL, a second terminal of the transistor M3 is connected to a wiring SL, and a gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. At the time of data writing, data retention, and data reading, a low-level potential (referred to as a reference potential in some cases) is preferably applied to the wiring CAL.

Data writing is performed by applying a high-level potential to the wiring WOL to turn on the transistor M2, thereby connecting the wiring WBL to the first terminal of the capacitor CB. Specifically, when the transistor M2 is on, a potential corresponding to data to be stored is applied to the wiring WBL, and the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. The current flowing between a source and a drain of the transistor M3 and the potential of the first terminal of the transistor M3 are determined by the potential of the gate of the transistor M3 and the potential of the second terminal of the transistor M3; thus, by reading the potential of the wiring RBL connected to the first terminal of the transistor M3, the potential retained at the first terminal of the capacitor CB (or the gate of the transistor M3) can be read. In other words, data written into this memory cell can be read from the potential retained at the first terminal of the capacitor CB (or the gate of the transistor M3).

Alternatively, for example, the wiring WBL and the wiring RBL may be collectively connected to be one as the wiring BIL. FIG. 17D illustrates a circuit configuration example of the memory cell. In a memory cell 954, one wiring BIL corresponds to the wiring WBL and the wiring RBL in the memory cell 953, and the second terminal of the transistor M2 and the first terminal of the transistor M3 are connected to the wiring BIL. In other words, the memory cell 954 has a structure in which one wiring BIL operates as a write bit line and a read bit line.

A memory cell 955 illustrated in FIG. 17E is an example in which the capacitor CB and the wiring CAL in the memory cell 953 are omitted. A memory cell 956 illustrated in FIG. 17F is an example in which the capacitor CB and the wiring CAL in the memory cell 954 are omitted. With such a structure, the integration degree of the memory cells can be increased.

Note that it is preferable to use the OS transistor described in the above embodiment as at least the transistor M2. It is particularly preferable to use the OS transistor described in the above embodiment as the transistor M2 and the transistor M3. With use of the OS transistor described in the above embodiment, the area occupied by a memory cell can be reduced.

Since an OS transistor has a characteristic of extremely low off-state current, written data can be retained for a long time with the transistor M2, and thus the frequency of refresh operation for the memory cell can be decreased. Alternatively, refresh operation for the memory cell can be unnecessary. In addition, the extremely low leakage current allows multi-level data or analog data to be retained in the memory cell 953, the memory cell 954, the memory cell 955, and the memory cell 956.

The memory cell 953, the memory cell 954, the memory cell 955, and the memory cell 956 each using an OS transistor as the transistor M2 are embodiments of a NOSRAM.

Note that a Si transistor may be used as the transistor M3. A Si transistor can have high field-effect mobility and can be a p-channel transistor, so that circuit design flexibility can be increased.

In the case where an OS transistor is used as the transistor M3, the memory cell can be composed of a single-polarity circuit.

FIG. 17G illustrates a gain-cell memory cell 957 including three transistors and one capacitor. The memory cell 957 includes a transistor M4 to a transistor M6 and a capacitor CC.

A first terminal of the transistor M4 is connected to a first terminal of the capacitor CC, and a second terminal of the transistor M4 is connected to the wiring BIL, and a gate of the transistor M4 is connected to the wiring WOL. A second terminal of the capacitor CC is electrically connected to a first terminal of the transistor M5 and a wiring GNDL. A second terminal of the transistor M5 is connected to a first terminal of a transistor M6, and a gate of the transistor M5 is connected to the first terminal of the capacitor CC. A second terminal of the transistor M6 is connected to the wiring BIL, and a gate of the transistor M6 is connected to a wiring RWL.

The wiring BIL functions as a bit line, the wiring WOL functions as a write word line, and the wiring RWL functions as a read word line. The wiring GNDL is a wiring for applying a low-level potential.

Data writing is performed by applying a high-level potential to the wiring WOL to turn on the transistor M4, thereby connecting the wiring BIL to the first terminal of the capacitor CC. Specifically, when the transistor M4 is on, a potential corresponding to data to be stored is applied to the wiring BIL, and the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed by precharging the wiring BIL with a predetermined potential, and then making the wiring BIL in an electrically floating state and applying a high-level potential to the wiring RWL. Since the wiring RWL has the high-level potential, the transistor M6 is turned on, so that the wiring BIL is electrically connected to the second terminal of the transistor M5. At this time, the potential of the wiring BIL is applied to the second terminal of the transistor M5; the potential of the second terminal of the transistor M5 and the potential of the wiring BIL change depending on the potential retained at the first terminal of the capacitor CC (or the gate of the transistor M5). Here, by reading the potential of the wiring BIL, the potential retained at the first terminal of the capacitor CC (or the gate of the transistor M5) can be read. In other words, data written into the memory cell can be read from the potential retained at the first terminal of the capacitor CC (or the gate of the transistor M5).

Note that it is preferable to use the OS transistor described in the above embodiment at least as the transistor M4. With use of the OS transistor described in the above embodiment, the area occupied by a memory cell can be reduced.

Note that Si transistors may be used as the transistors M5 and M6. As described above, a Si transistor has higher field-effect mobility than an OS transistor in some cases depending on the crystal state of silicon used in a semiconductor layer, for example.

When OS transistors are used as the transistors M5 and M6, the memory cell can be composed of a single-polarity circuit.

### [OS-SRAM]

FIG. 17H illustrates an example of an SRAM (Static Random Access Memory) using an OS transistor. In this specification and the like, an SRAM using an OS transistor is referred to as an OS-SRAM (Oxide Semiconductor-SRAM). Note that a memory cell 958 illustrated in FIG. 17H is a memory cell of an SRAM capable of backup.

The memory cell 958 includes a transistor M7 to a transistor M10, a transistor MS1 to a transistor MS4, a capacitor CD1, and a capacitor CD2. The transistor MS1 and the transistor MS2 are p-channel transistors, and the transistor MS3 and the transistor MS4 are n-channel transistors.

A first terminal of the transistor M7 is connected to the wiring BIL, and a second terminal of the transistor M7 is connected to a first terminal of the transistor MS1, a first terminal of the transistor MS3, a gate of the transistor MS2, a gate of the transistor MS4, and a first terminal of the transistor M10. Agate of the transistor M7 is connected to the wiring WOL. A first terminal of the transistor M8 is connected to a wiring BILB, and a second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is electrically connected to a wiring VDL. A second terminal of the transistor MS2 is electrically connected to the wiring VDL. A second terminal of the transistor MS3 is electrically connected to the wiring GNDL. A second terminal of the transistor MS4 is electrically connected to the wiring GNDL.

A second terminal of the transistor M9 is connected to a first terminal of the capacitor CD1, and a gate of the transistor M9 is connected to the wiring BRL. The second terminal of the transistor M10 is connected to a first terminal of the capacitor CD2, and the gate of the transistor M10 is connected to the wiring BRL.

A second terminal of the capacitor CD1 is connected to the wiring GNDL, and a second terminal of the capacitor CD2 is connected to the wiring GNDL.

The wiring BIL and the wiring BILB function as bit lines, the wiring WOL functions as a word line, and the wiring BRL controls the conduction state and the non-conduction state of the transistors M9 and M10.

The wiring VDL is a wiring supplying a high-level potential, and the wiring GNDL is a wiring supplying a low-level potential.

Data writing is performed by applying a high-level potential to the wiring WOL and applying a high-level potential to the wiring BRL. Specifically, when the transistor M10 is on, a potential corresponding to data to be stored is applied to the wiring BIL, and the potential is written to the second terminal side of the transistor M10.

In the memory cell 958, an inverter loop is constructed by the transistor MS1 to the transistor MS2; thus, an inverted signal of a data signal corresponding to the potential is input to the second terminal side of the transistor M8. Since the transistor M8 is on, an inverted signal of the potential applied to the wiring BIL, that is, the signal input to the wiring BIL is output to the wiring BILB. Since the transistor M9 and the transistor M10 are in an on state, the potential of the second terminal of the transistor M7 is retained at the first terminal of the capacitor CD2, and the potential of the second terminal of the transistor M8 is retained at the first terminal of the capacitor CD1. After that, a low-level potential is applied to the wiring WOL and the wiring BRL to turn off the transistor M7 to transistor M10, whereby the potential of the first terminal of the capacitor CD1 and the potential of the first terminal of the capacitor CD2 are retained.

Data reading is performed by precharging the wiring BIL and the wiring BILB with a predetermined potential, and then applying a high-level potential to the wiring WOL and the wiring BRL, whereby the potential of the first terminal of the capacitor CD1 is refreshed by the inverter loop in the memory cell 958 and output to the wiring BILB. Moreover, the potential of the first terminal of the capacitor CD2 is refreshed by the inverter loop in the memory cell 958 and is output to the wiring BIL. Since the potentials of the wiring BIL and the wiring BILB are changed from the precharged potentials to the potentials of the first terminal of the capacitor CD2 and the first terminal of the capacitor CD1, the potential retained in the memory cell can be read on the basis of the potentials of the wiring BIL and the wiring BILB.

Note that OS transistors are preferably used as the transistor M7 to the transistor M10. Accordingly, written data can be retained for a long time by the transistor M7 to the transistor M10; thus, the frequency of refresh operations for the memory cell can be decreased. Alternatively, refresh operation for the memory cell can be unnecessary. The use of the OS transistor described in the above embodiment as the transistor M7 to the transistor M10 enables a reduction in the area occupied by the memory cell.

As the transistor MS1 to the transistor MS4, Si transistors may be used.

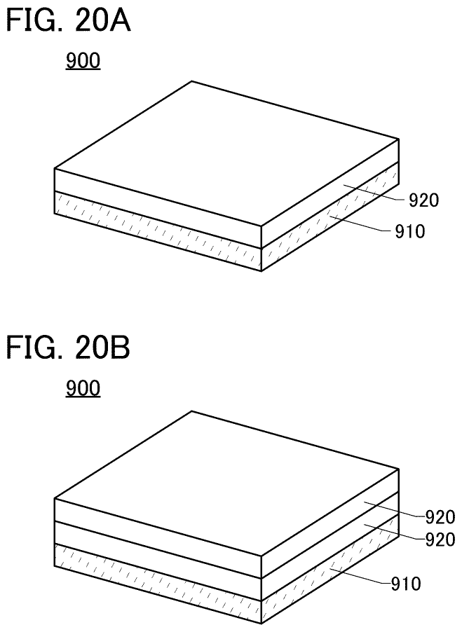

The driver circuit 910 and the memory array 920 that are included in the semiconductor device 900 may be provided on the same plane. As illustrated in FIG. 20A, the driver circuit 910 and the memory array 920 may be provided to overlap with each other. When the driver circuit 910 and the memory array 920 are provided to overlap with each other, the signal transmission distance can be shortened. Alternatively, a plurality of memory arrays 920 may be provided over the driver circuit 910 as illustrated in FIG. 20B.

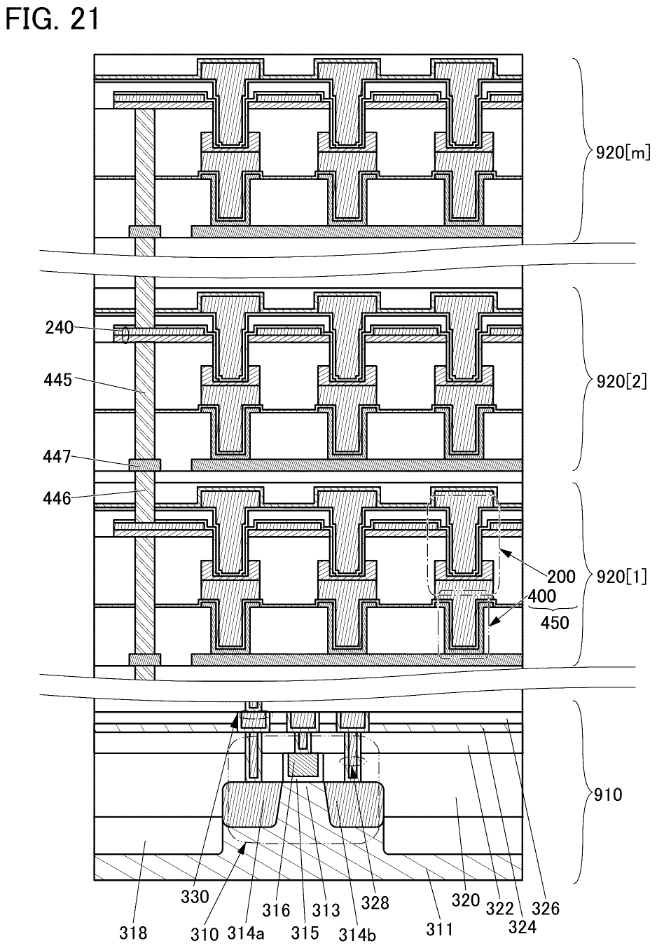

Here, an example of a structure in which a plurality of memory arrays are stacked over the driver circuit 910 is described with reference to FIG. 21. The memory device illustrated in FIG. 21 has a structure in which m layers (m is an integer greater than or equal to 2) of the memory arrays 920 each including the memory cells 450 are stacked. Here, FIG. 21 illustrates a memory array 920[1] as the layer provided in the first layer (the lowermost layer), a memory array 920[2] as the layer provided in the second layer, and a memory array 920[m] as the layer provided in the m-th layer (the uppermost layer). In other words, the memory device of one embodiment of the present invention may include a plurality of layers including the memory cells 450 and have a structure in which the plurality of layers are stacked. In each of the memory arrays 920, the conductor 446, the conductor 445, and the conductor 447 are provided as in FIG. 19.

As illustrated in FIG. 21, the conductor 446, the conductor 445, and the conductor 447 function as wirings that connect one memory array 920 provided in the upper layer and another memory array 920 provided in the lower layer. For example, the conductor 240 in the memory array 920[2] is electrically connected to the conductor 240 in the memory array 920[1] through the conductor 445, the conductor 447, and the conductor 446. As illustrated in FIG. 21, the conductor 446, the conductor 445, and the conductor 447 can be provided outside the memory array 920. Alternatively, the conductor 446, the conductor 445, and the conductor 447 can be provided in the memory array 920.

The driver circuit 910 is provided under the memory array 920. With a structure in which the driver circuit is provided under the memory device, the area of the memory device can be increased and the memory capacity of the memory device can be increased.

FIG. 21 illustrates a transistor 310 included in the driver circuit 910 as an example. The transistor 310 is provided on a substrate 311 and includes a conductor 316 functioning as a gate, an insulator 315 functioning as a gate insulator, a semiconductor region 313 including part of the substrate 311, and a low-resistance region 314a and a low-resistance region 314b functioning as a source region and a drain region. An element isolation layer 318 is preferably provided between adjacent transistors 310. The transistor 310 can be either a p-channel transistor or an n-channel transistor. As the substrate 311, a single crystal silicon substrate can be used, for example.

Here, in the transistor 310 illustrated in FIG. 21, the semiconductor region 313 (part of the substrate 311) in which a channel is formed has a protruding shape. The conductor 316 is provided to cover the side surface and the top surface of the semiconductor region 313 with the insulator 315 therebetween. Note that the conductor 316 may be formed using a material for adjusting the work function. The transistor 310 is also referred to as a FIN-type transistor because it utilizes a protruding portion of the semiconductor substrate. Note that an insulator functioning as a mask for forming the protruding portion may be provided in contact with the upper portion of the protruding portion. Although the case where the protruding portion is formed by processing part of the semiconductor substrate is described here, a semiconductor film having a protruding shape may be formed by processing an SOI (Silicon on Insulator) substrate.

Note that the transistor 310 illustrated in FIG. 21 is an example and the structure is not limited thereto; an appropriate transistor can be used in accordance with a circuit configuration or a driving method.

A wiring layer provided with an interlayer film, a wiring, a plug, and the like may be provided between the memory array 920 and the driver circuit 910. A plurality of wiring layers can be provided in accordance with the design. Furthermore, in this specification and the like, a wiring and a plug electrically connected to the wiring may be a single component. That is, part of a conductor functions as a wiring in some cases and part of the conductor functions as a plug in other cases.

For example, an insulator 320, an insulator 322, an insulator 324, and an insulator 326 are stacked in this order over the transistor 310 as interlayer films. A conductor 328 and the like are embedded in the insulator 320 and the insulator 322. A conductor 330 and the like are embedded in the insulator 324 and the insulator 326. Note that the conductor 328 and the conductor 330 function as a contact plug or a wiring.

The insulator functioning as an interlayer film may function as a planarization film that covers an uneven shape thereunder. For example, the top surface of the insulator 322 may be planarized by CMP treatment to increase the level of planarity.

Next, an example of an arithmetic processing device that can include the semiconductor device such as the above-described memory device is described.

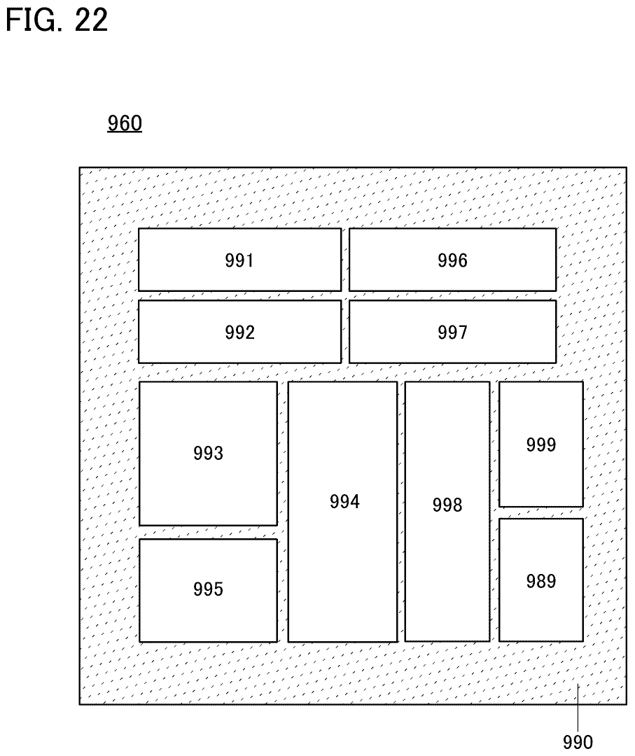

FIG. 22 is a block diagram of an arithmetic device 960. The arithmetic device 960 illustrated in FIG. 22 can be used for a CPU, for example. The arithmetic device 960 can also be used for a processor including a larger number of (several tens to several hundreds of) processor cores capable of parallel processing than a CPU, such as a GPU (Graphics Processing Unit), a TPU (Tensor Processing Unit), or an NPU (Neural Processing Unit).

The arithmetic device 960 illustrated in FIG. 22 includes, over a substrate 990, an ALU 991 (Arithmetic logic unit, arithmetic circuit), an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may also include a rewritable ROM and a ROM interface. The cache 999 and the cache interface 989 may be provided in a separate chip.

The cache 999 is connected through the cache interface 989 to a main memory provided in another chip. The cache interface 989 has a function of supplying part of data retained in the main memory to the cache 999. The cache interface 989 has a function of outputting part of data retained in the cache 999 to the ALU 991, the register 996, or the like via the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in this case, the driver circuit 910 is preferably included in part of the cache interface 989.

It is also possible that the cache 999 is not provided and only the memory array 920 is used as a cache.

The arithmetic device 960 illustrated in FIG. 22 is only an example with a simplified structure, and the actual arithmetic device 960 has a variety of structures depending on the application. For example, what is called a multicore structure is preferably employed in which a plurality of cores each including the arithmetic device 960 illustrated in FIG. 22 operate in parallel. The larger number of cores can enhance the arithmetic performance. The number of cores is preferably larger; for example, the number is preferably 2, further preferably 4, still further preferably 8, yet further preferably 12, yet still further preferably 16 or larger. For application requiring extremely high arithmetic performance, e.g., a server, it is preferable to employ the multicore structure including 16 or more, preferably 32 or more, further preferably 64 or more cores. The number of bits that the arithmetic device 960 can process in an internal arithmetic circuit or in a data bus can be 8, 16, 32, or 64, for example.

An instruction that is input to the arithmetic device 960 through the bus interface 998 is input to the instruction decoder 993 and decoded therein, and then, input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. While the arithmetic device 960 is executing a program, the interrupt controller 994 judges an interrupt request from an external input/output device, a peripheral circuit, or the like on the basis of its priority or a mask state, and processes the request. The register controller 997 generates the address of the register 996, and reads or writes data from or to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above various circuits.

In the arithmetic device 960 illustrated in FIG. 22, the register controller 997 selects a retention operation in the register 996 in accordance with an instruction from the ALU 991. That is, the register controller 997 selects whether data is stored by a flip-flop or by a capacitor in the memory cell included in the register 996. When data retention by the flip-flop is selected, power supply voltage is supplied to the memory cell in the register 996. When data retention by the capacitor is selected, the data is rewritten into the capacitor, and supply of power supply voltage to the memory cell in the register 996 can be stopped.

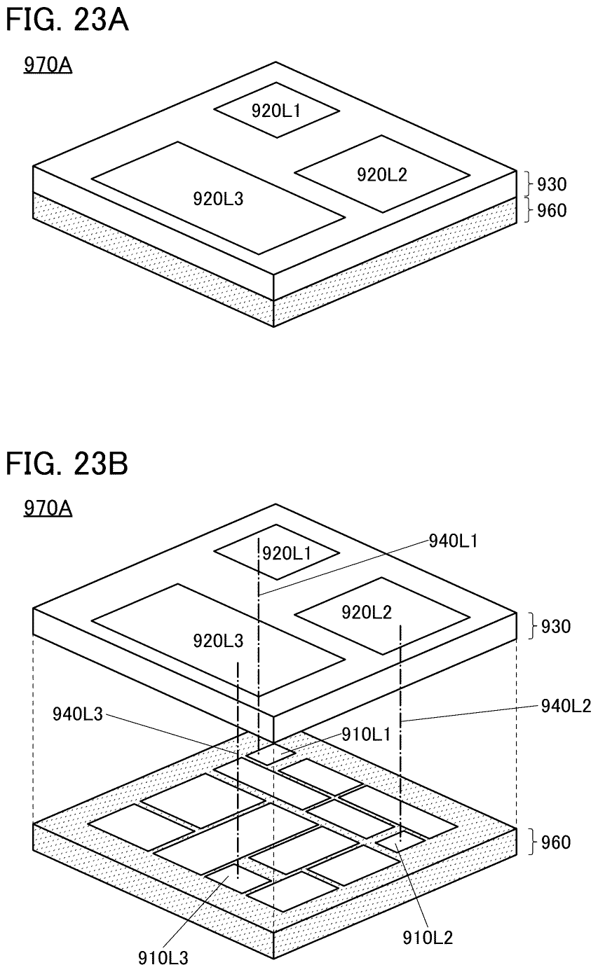

The memory array 920 and the arithmetic device 960 can be provided to overlap with each other. FIG. 23A and FIG. 23B are perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 and each of the memory arrays include overlap regions. For easy understanding of the structure of the semiconductor device 970A, the arithmetic device 960 and the layer 930 are separately illustrated in FIG. 23B.

Providing the layer 930 including the memory arrays and the arithmetic device 960 to overlap with each other can shorten the connection distance therebetween. Accordingly, the communication speed therebetween can be increased. Moreover, since the connection distance is short, power consumption can be reduced.

As a method for stacking the layer 930 including the memory arrays and the arithmetic device 960, either of the following methods may be employed: a method in which the layer 930 including the memory arrays is stacked directly on the arithmetic device 960 (also referred to as monolithic stacking) and a method in which the arithmetic device 960 and the layer 930 are formed over different substrates, the two substrates are bonded to each other, and the arithmetic device 960 and the layer 930 are electrically connected to each other using a through via or a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory arrays 920L1, 920L2, and 920L3 provided in the layer 930 are each used as a cache. In that case, for example, the memory array 920L1 can be used as an L1 cache (also referred to as a level 1 cache), the memory array 920L2 can be used as an L2 cache (also referred to as a level 2 cache), and the memory array 920L3 can be used as an L3 cache (also referred to as a level 3 cache). Among the three memory arrays, the memory array 920L3 has the highest storage capacity and the lowest access frequency. The memory array 920L 1 has the lowest capacity and the highest access frequency.

Note that in the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 23B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Although the case where three memory arrays function as caches is described here, the number of memory arrays may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuit 910L2 and the driver circuit 910L3 may function as part of the cache interface 989 or be connected thereto.

Whether the memory array 920 functions as the cache or the main memory is determined by the control circuit 912 included in each of the driver circuits 910. The control circuit 912 can make some of the plurality of memory cells 950 included in the semiconductor device 900 function as RAM in accordance with a signal supplied from the arithmetic device 960.

In the semiconductor device 900, some of the plurality of memory cells 950 can function as the caches and the other memory cells 950 can function as the main memory. That is, the semiconductor device 900 can have both the function of the cache and the function of the main memory. The semiconductor device 900 of one embodiment of the present invention can function as a universal memory, for example.

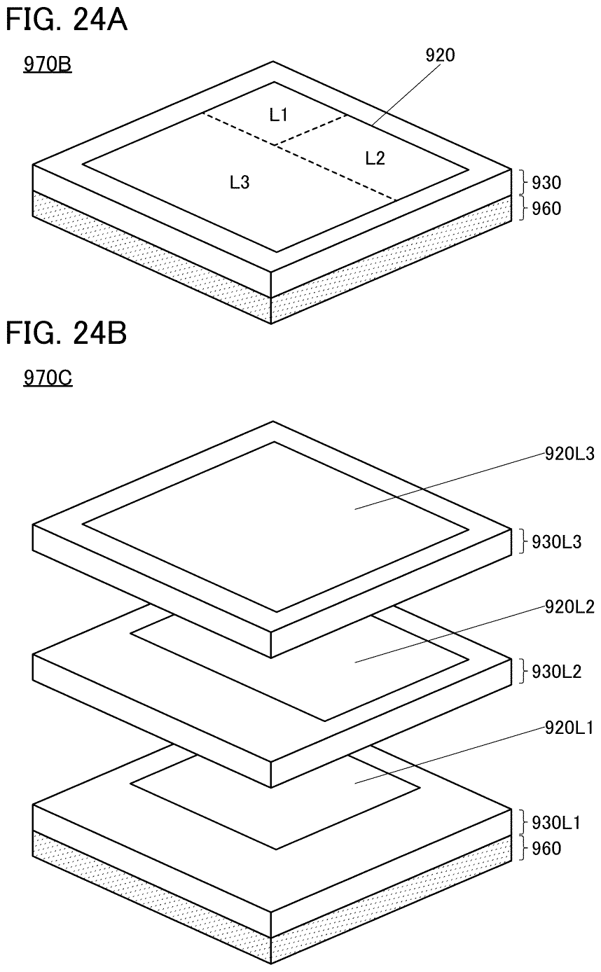

The layer 930 including one memory array 920 may be provided to overlap with the arithmetic device 960. FIG. 24A illustrates a perspective view of a semiconductor device 970B.

In the semiconductor device 970B, one memory array 920 can be divided into a plurality of areas having different functions. FIG. 24A illustrates an example in which a region L1, a region L2, and a region L3 are used as the L1 cache, the L2 cache, and the L3 cache, respectively.

In the semiconductor device 970B, the capacity of each of the region L1 to the region L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 24B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the farthest memory array 920L3 can be used as a low-level cache or a main memory. Such a structure can increase the capacity of each memory array, thereby improving processing capability.

Note that this embodiment can be combined with any of the other embodiments and Example in this specification as appropriate.

### Embodiment 3

In this embodiment, application examples of the memory device of one embodiment of the present invention is described.

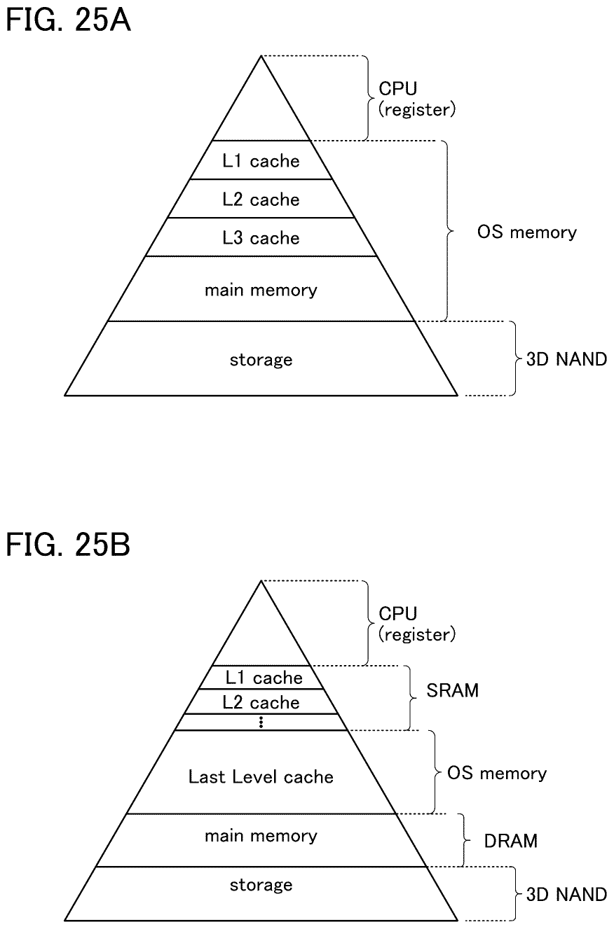

In general, a variety of memory devices are used in semiconductor devices such as computers in accordance with the intended use. FIG. 25A shows the hierarchy of various memory devices used in semiconductor devices. The memory devices at the upper levels require higher operating speed, whereas the memory devices at the lower levels require higher memory capacity and higher memory density. FIG. 25A shows, for example, a memory included as a register in an arithmetic processing device such as a CPU, an L1 cache, an L2 cache, an L3 cache, a main memory, and a storage in this order from the uppermost layer. Although the caches up to the L3 cache are included in this example, a lower-level cache may further be included.

A memory included as a register in an arithmetic processing device such as a CPU is used for temporary storage of arithmetic operation results, for example, and thus is very frequently accessed by the arithmetic processing device. Accordingly, high operating speed is required rather than memory capacity. The register also has a function of retaining setting information of the arithmetic processing device, for example.

The cache has a function of duplicating and retaining part of data retained in the main memory. Duplicating frequently used data and retaining the duplicated data in the cache facilitate rapid data access. The cache requires a lower memory capacity than the main memory but a higher operating speed than the main memory. Data that is rewritten in the cache is duplicated, and the duplicated data is supplied to the main memory.

The main memory has a function of retaining a program, data, and the like that are read from the storage.

The storage has a function of retaining data that needs to be stored for a long time and a variety of programs used in the arithmetic processing device, for example. Therefore, the storage needs to have a high memory capacity and a high memory density rather than operating speed. For example, a high-capacity nonvolatile memory device such as a 3D NAND can be used.

The memory device using an oxide semiconductor (the OS memory) of one embodiment of the present invention operates at high speed and can retain data for a long time. Thus, as shown in FIG. 25A, the memory device of one embodiment of the present invention can be suitably used for devices at both the level including the cache and the level including the main memory. The memory device of one embodiment of the present invention can also be used at the level including the storage.

FIG. 25B shows an example of the case where an SRAM is used as some of the caches and the OS memory of one embodiment of the present invention is used as the other cache.

Among the caches, the lowest-level cache can be referred to as an LLC (Last Level Cache). The LLC does not require a higher operating speed than a higher-level cache, but desirably has a high memory capacity. The OS memory of one embodiment of the present invention operates at high speed and can retain data for a long time, and thus can be suitably used as the LLC. Note that the OS memory of one embodiment of the present invention can also be used as an FLC (Final Level Cache).

For example, as shown in FIG. 25B, an SRAM can be used as the higher-level caches (the L1 cache, the L2 cache, and the like), and the OS memory of one embodiment of the present invention can be used as the LLC. Moreover, not only the OS memory but also a DRAM can be used as the main memory as shown in FIG. 25B.

Note that this embodiment can be combined with other embodiments and Example in this specification as appropriate.

### Embodiment 4

This embodiment will describe an electronic component, an electronic device, a large computer, space equipment, and a data center (also referred to as a DC) in which the semiconductor device described in the above embodiment can be used. An electronic device, a large computer, space equipment, and a data center in which the semiconductor device of one embodiment of the present invention is used are effective in improving performance, e.g., reducing power consumption.

### [Electronic Device]

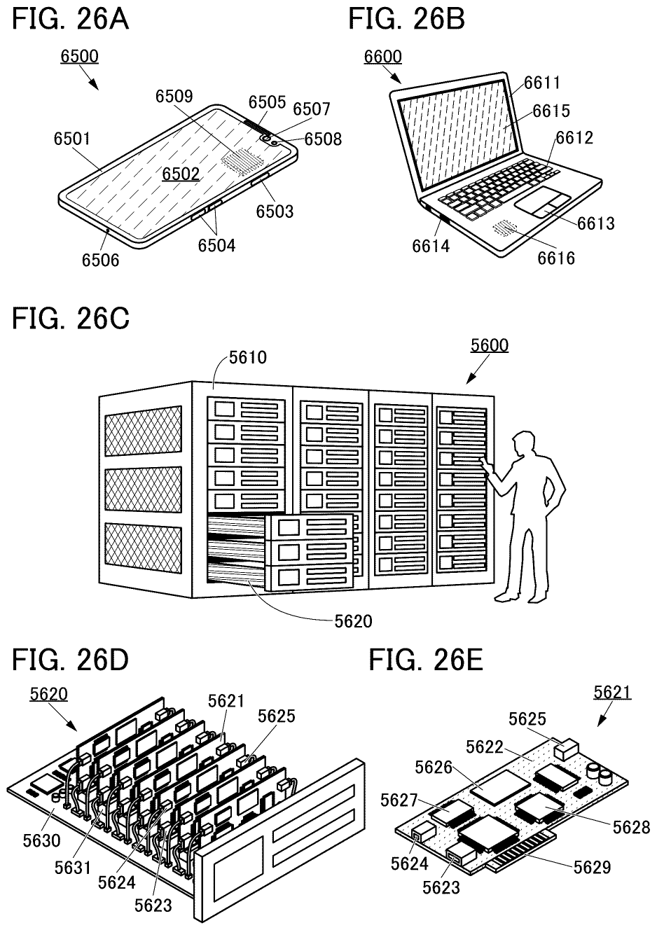

Next, FIG. 26A is a perspective view of an electronic device 6500. The electronic device 6500 illustrated in FIG. 26A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. One or more selected from a CPU, a GPU, and a memory device are provided as the control device 6509, for example. The semiconductor device of one embodiment of the present invention can be used for the display portion 6502, the control device 6509, and the like.

An electronic device 6600 illustrated in FIG. 26B is an information terminal that can be used as a laptop personal computer. The electronic device 6600 includes a housing 6611, a keyboard 6612, a pointing device 6613, an external connection port 6614, a display portion 6615, a control device 6616, and the like. One or more selected from a CPU, a GPU, and a memory device are provided as the control device 6616, for example. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

FIG. 26C is a perspective view of a large computer 5600. In the large computer 5600 illustrated in FIG. 26C, a plurality of rack mount computers 5620 are stored in a rack 5610. Note that the large computer 5600 may be referred to as a supercomputer.

The computer 5620 can have a structure in a perspective view of FIG. 26D, for example. In FIG. 26D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 26E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 26E also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply, signal input, or the like to the PC card 5621. For another example, they can each serve as an interface for outputting a signal calculated by the PC card 5621. Examples of the standard for each of the connection terminal 5623, the connection terminal 5624, and the connection terminal 5625 include USB, SATA (Serial ATA), and SCSI (Small Computer System Interface). In the case where video signals are output from the connection terminal 5623, the connection terminal 5624, and the connection terminal 5625, an example of the standard therefor is HDM1 (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used as space equipment such as equipment that processes and stores information.

The semiconductor device of one embodiment of the present invention can include an OS transistor. A change in electrical characteristics of the OS transistor due to radiation irradiation is small. That is, the OS transistor is highly resistant to radiation and thus can be suitably used in an environment where radiation can enter. For example, the OS transistor can be suitably used in outer space.

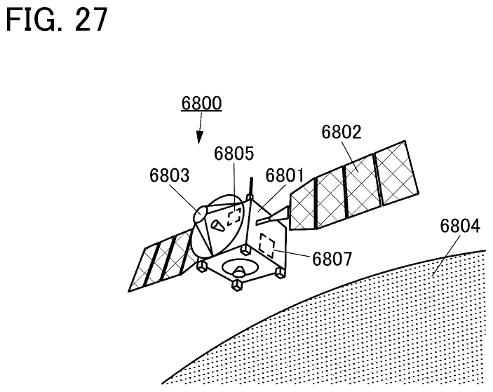

FIG. 27 illustrates an artificial satellite 6800 as an example of space equipment. The artificial satellite 6800 includes a body 6801, a solar panel 6802, an antenna 6803, a secondary battery 6805, and a control device 6807. FIG. 27 illustrates a planet 6804 in outer space, for example. Note that outer space refers to, for example, space at an altitude greater than or equal to 100 km, and outer space in this specification also includes thermosphere, mesosphere, and stratosphere in some cases.

Although not illustrated in FIG. 27, a battery management system (also referred to as BMS) or a battery control circuit may be provided in the secondary battery 6805. The battery management system or the battery control circuit preferably includes an OS transistor, in which case power consumption is low and high reliability is achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for an operation of the artificial satellite 6800 is generated. However, for example, in the situation where the solar panel is not irradiated with sunlight or the amount of sunlight with which the solar panel is irradiated is small, the amount of generated electric power is small. Accordingly, electric power required for an operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed using one or more selected from a CPU, a GPU, and a memory device, for example. Note that the semiconductor device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. For example, the semiconductor device of one embodiment of the present invention can be suitably used for space equipment such as a spacecraft, a space capsule, or a space probe.

As described above, the OS transistor has advantageous effects over the Si transistor, such as a wide memory bandwidth and high radiation resistance.

### [Data Center]

The semiconductor device of one embodiment of the present invention can be suitably used for a storage system in a data center or the like, for example. Long-term data management, such as guarantee of data immutability, is required for the data center. In the case where data is managed for a long term, it is necessary to increase the scale of the data center for installation of storages and servers for storing an enormous amount of data, stable electric power for data retention, cooling equipment for data retention, or the like.

With the use of the semiconductor device of one embodiment of the present invention for the storage system used in the data center, electric power required for data retention can be reduced and a semiconductor device retaining data can be downsized. Thus, downsizing of the storage system, downsizing of a power source for data retention, downscaling of the cooling equipment, and the like can be achieved. This can reduce the space of the data center.

Since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention enables a data center that operates stably even in a high-temperature environment. Thus, the reliability of the data center can be increased.

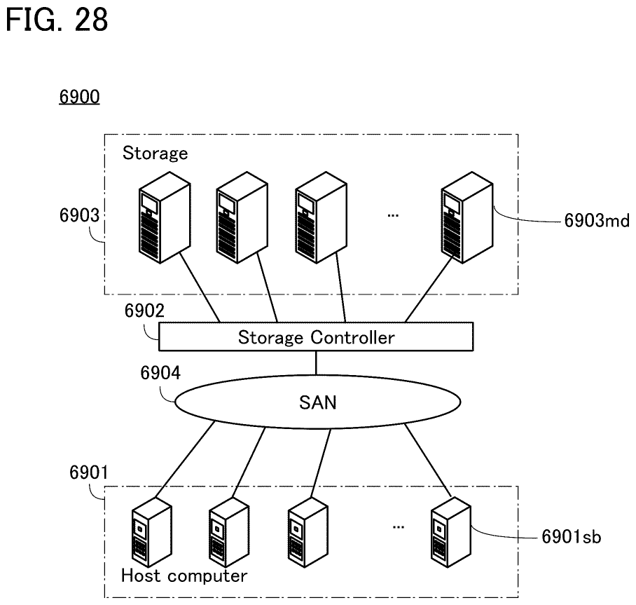

FIG. 28 illustrates a storage system that can be used in a data center. A storage system 6900 illustrated in FIG. 28 includes a plurality of servers 6901sb as a host 6901 (indicated as “Host Computer” in the diagram). The storage system 6900 includes a plurality of memory devices 6903md as a storage 6903 (indicated as “Storage” in the diagram). In the illustrated mode, the host 6901 and the storage 6903 are connected to each other through a storage area network 6904 (indicated as “SAN” in the diagram) and a storage control circuit 6902 (indicated as “Storage Controller” in the diagram).

The host 6901 corresponds to a computer that accesses data stored in the storage 6903. The host 6901 may be connected to another host 6901 through a network.

The data access speed, i.e., the time taken for storing and outputting data, of the storage 6903 is shortened by using a flash memory, but is still considerably longer than the data access speed of a DRAM that can be used as a cache memory in a storage. In the storage system, in order to solve the problem of low access speed of the storage 6903, a cache memory is normally provided in the storage to shorten the time required for data storage and output.

The above-described cache memory is used in the storage control circuit 6902 and the storage 6903. Data transmitted between the host 6901 and the storage 6903 is stored in the cache memory in the storage control circuit 6902 and the storage 6903 and then output to the host 6901 or the storage 6903.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the semiconductor device of one embodiment of the present invention for one or more selected from an electronic component, an electronic device, a large computer, space equipment, and a data center will produce an effect of reducing power consumption. While the demand for energy is expected to increase with higher performance or higher integration of semiconductor devices, the emission amount of greenhouse effect gases typified by carbon dioxide (CO₂) can be reduced with the use of the semiconductor device of one embodiment of the present invention. Furthermore, the semiconductor device of one embodiment of the present invention has low power consumption and thus is effective as a global warming countermeasure.

The configuration, structure, method, or the like described in this embodiment can be used in combination with the configuration, structure, method, or the like described in the other embodiments, Example, and the like as appropriate.

### Embodiment 5

This embodiment will describe structure examples of a display device that can use the transistor of one embodiment of the present invention.

Since the transistor of one embodiment of the present invention can be extremely minute, a display device using the transistor of one embodiment of the present invention can have an extremely high resolution. For example, a display device of one embodiment of the present invention can be used for display portions of information terminals (wearable devices) such as watch-type and bracelet-type information terminals and display portions of devices capable of being worn on a head, such as VR devices like head-mounted displays (HMDs) and glasses-type AR devices.

### [Display Module]

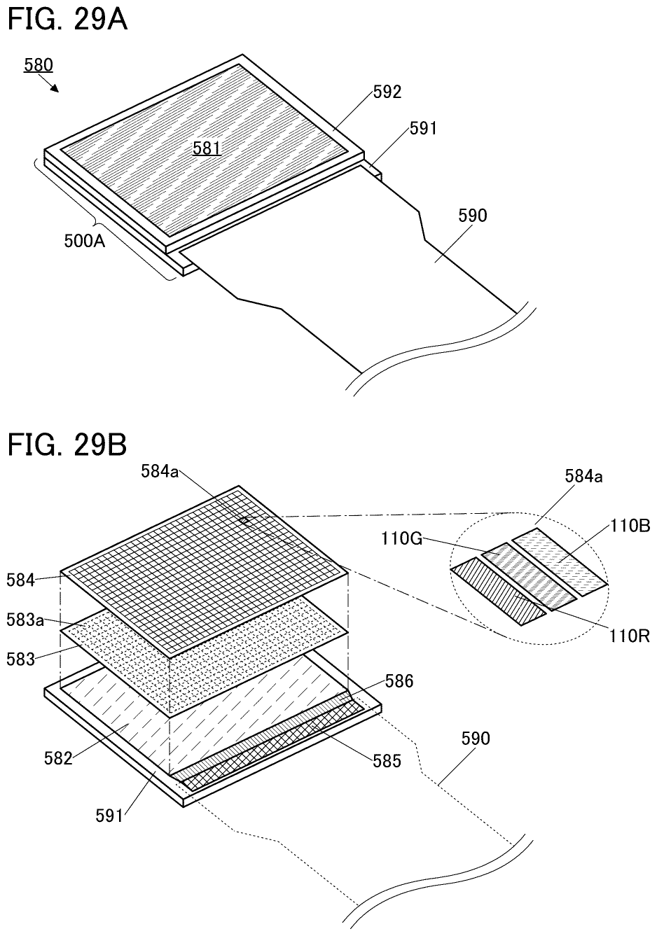

FIG. 29A is a perspective view of a display module 580. The display module 580 includes a display device 500A and an FPC 590. Note that a display panel included in the display module 580 is not limited to the display device 500A and may be a display device 500C described later.

The display module 580 includes a substrate 591 and a substrate 592. The display module 580 includes a display portion 581. The display portion 581 is a region where an image is displayed.

FIG. 29B is a perspective view schematically illustrating a structure on the substrate 591 side. Over the substrate 591, a circuit portion 582, a pixel circuit portion 583 over the circuit portion 582, and a pixel portion 584 over the pixel circuit portion 583 are stacked. A terminal portion 585 to be connected to the FPC 590 is provided over the substrate 591 in a portion that does not overlap with the pixel portion 584. The terminal portion 585 and the circuit portion 582 are electrically connected to each other through a wiring portion 586 formed of a plurality of wirings.

The pixel portion 584 includes a plurality of pixels 584a arranged periodically. An enlarged view of one pixel 584a is illustrated on the right side in FIG. 29B. The pixel 584a includes a light-emitting element 110R that emits red light, a light-emitting element 110G that emits green light, and a light-emitting element 110B that emits blue light.

The pixel circuit portion 583 includes a plurality of pixel circuits 583a arranged periodically. One pixel circuit 583a is a circuit for controlling light emission of three light-emitting devices included in one pixel 584a. One pixel circuit 583a may be provided with three circuits each controlling light emission of one light-emitting device. For example, the pixel circuit 583a can include at least one selection transistor, one current control transistor (driving transistor), and a capacitor for one light-emitting device. In that case, a gate signal is input to a gate of the selection transistor, and a source signal is input to a source of the selection transistor. Thus, an active-matrix display panel is achieved.

The circuit portion 582 includes a circuit for driving the pixel circuits 583a in the pixel circuit portion 583. For example, the circuit portion 582 preferably includes one or both of a gate line driver circuit and a source line driver circuit. The circuit portion 582 may also include at least one of an arithmetic circuit, a memory circuit, a power supply circuit, and the like. In addition, a transistor provided in the circuit portion 582 may constitute part of the pixel circuit 583a. That is, the pixel circuit 583a may be constituted by a transistor included in the pixel circuit portion 583 and a transistor included in the circuit portion 582.

The FPC 590 functions as a wiring for supplying a video signal, a power supply potential, and the like to the circuit portion 582 from the outside. An IC may be mounted on the FPC 590.

The display module 580 can have a structure in which one or both of the pixel circuit portion 583 and the circuit portion 582 are provided to be stacked below the pixel portion 584; thus, the aperture ratio (effective display area ratio) of the display portion 581 can be significantly high. For example, the aperture ratio of the display portion 581 can be greater than or equal to 40% and less than 100%, preferably greater than or equal to 50% and less than or equal to 95%, further preferably greater than or equal to 60% and less than or equal to 95%. Furthermore, the pixels 584a can be arranged extremely densely and thus the display portion 581 can have an extremely high resolution. For example, the pixels 584a are preferably arranged in the display portion 581 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 580 has an extremely high resolution, and thus can be suitably used for a VR device such as a head-mounted display or a glasses-type AR device. For example, even with a structure in which the display portion of the display module 580 is seen through a lens, pixels of the extremely-high-resolution display portion 581 included in the display module 580 are prevented from being recognized when the display portion is magnified by the lens, so that display providing a high sense of immersion can be performed. Without being limited thereto, the display module 580 can be suitably used for electronic devices including a relatively small display portion. For example, the display module 580 can be suitably used for a display portion of a wearable electronic device such as a wristwatch.

### [Display Device 500A]

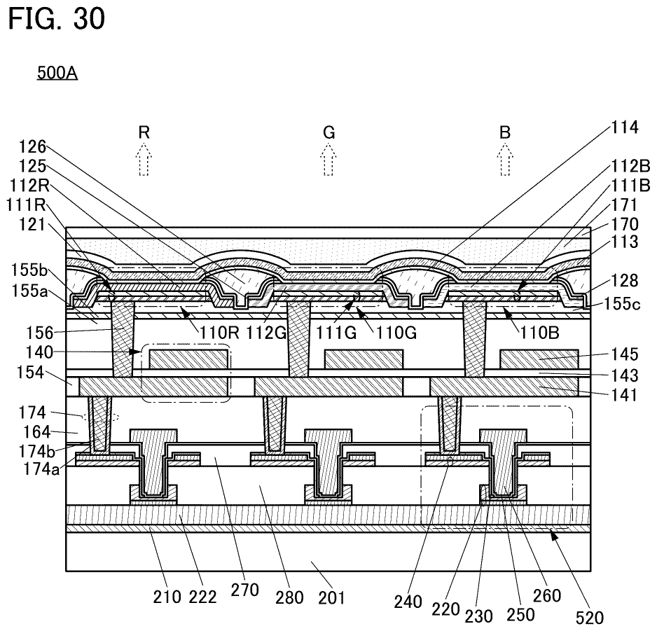

The display device 500A illustrated in FIG. 30 includes a substrate 201, the light-emitting element 110R, the light-emitting element 110G, the light-emitting element 110B, a capacitor 140, and a transistor 520.

The substrate 201 corresponds to the substrate 591 in FIG. 29A.

The transistor 520 is a vertical-channel transistor using an oxide semiconductor in a semiconductor layer where a channel is formed. The transistor 520 includes the oxide semiconductor 230, the insulator 250, the conductor 260, the conductor 240, the conductor 220, and the like.

As the transistor 520, a variety of transistors exemplified in Embodiment 1 can be used. For example, as illustrated in FIG. 30, the transistor 200 illustrated in FIG. 1A to FIG. 1D can be used as the transistor 520.

The insulator 210 is provided over the substrate 201. The insulator 210 functions as a barrier layer that prevents diffusion of impurities such as water and hydrogen from the substrate 201 into the transistor 520 and release of oxygen from the oxide semiconductor 230 to the insulator 210 side. As the insulator 210, for example, a film in which hydrogen or oxygen is less likely to diffuse than in a silicon oxide film, such as an aluminum oxide film, a hafnium oxide film, or a silicon nitride film, can be used.

The insulator 222 is provided over the insulator 210. The insulator 222 functions as an insulating film that captures or fixes hydrogen contained in the insulator 280, the oxide semiconductor 230, and the like. As the insulator 222, a hafnium silicate film or the like can be used, for example.

The insulator 280 is provided over the insulator 222 and the conductor 220, and the conductor 240 is provided over the insulator 280. An opening is provided in the insulator 280, and the oxide semiconductor 230, the insulator 250, and the conductor 260 are provided in the opening. The insulator 270 is provided to cover the conductor 240 and the oxide semiconductor 230. An insulating layer 164 is provided to cover the conductor 260.

The insulating layer 164 functions as an interlayer insulating layer. A barrier layer that prevents diffusion of impurities such as water and hydrogen from the insulating layer 164 or the like into the transistor 520 may be provided between the insulating layer 164 and an insulating layer 154. As the barrier layer, an insulating film similar to the insulator 210 can be used.

A plug 174 electrically connected to one of the conductors 240 is provided to be embedded in the insulating layer 164. Here, the plug 174 preferably includes a conductive layer 174a that covers the side surface of the opening in the insulating layer 164 and part of the top surface of the conductor 240, and a conductive layer 174b in contact with the top surface of the conductive layer 174a. In that case, for the conductive layer 174a, a conductive material that does not easily allow diffusion of hydrogen and oxygen is preferably used.

The capacitor 140 is provided over the insulating layer 164. The capacitor 140 includes a conductive layer 141, a conductive layer 145, and an insulating layer 143 positioned therebetween. The conductive layer 141 functions as one electrode of the capacitor 140, the conductive layer 145 functions as the other electrode of the capacitor 140, and the insulating layer 143 functions as a dielectric of the capacitor 140.

The conductive layer 141 is provided over the insulating layer 164 and is embedded in the insulating layer 154. The conductive layer 141 is electrically connected to the conductor 240 in the transistor 520 through the plug 174. The insulating layer 143 is provided to cover the conductive layer 141. The conductive layer 145 is provided in a region overlapping with the conductive layer 141 with the insulating layer 143 therebetween.

An insulating layer 155a is provided to cover the capacitor 140, an insulating layer 155b is provided over the insulating layer 155a, and an insulating layer 155c is provided over the insulating layer 155b.

An inorganic insulating film can be suitably used as each of the insulating layer 155a, the insulating layer 155b, and the insulating layer 155c. For example, it is preferable that a silicon oxide film be used as each of the insulating layer 155a and the insulating layer 155c and that a silicon nitride film be used as the insulating layer 155b. This enables the insulating layer 155b to function as an etching protective film. Although this embodiment describes an example in which the insulating layer 155c is partly etched and a depressed portion is formed, the depressed portion is not necessarily provided in the insulating layer 155c.

The light-emitting element 110R, the light-emitting element 110G, and the light-emitting element 110B are provided over the insulating layer 155c.

The light-emitting element 110R includes a pixel electrode 111R, an organic layer 112R, a common layer 114, and a common electrode 113. The light-emitting element 110G includes a pixel electrode 111G, an organic layer 112G, the common layer 114, and the common electrode 113. The light-emitting element 110B includes a pixel electrode 111B, an organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R contains at least a light-emitting organic compound that emits red light. The organic layer 112G included in the light-emitting element 110G contains at least a light-emitting organic compound that emits green light. The organic layer 112B included in the light-emitting element 110B contains at least a light-emitting organic compound that emits blue light. Each of the organic layer 112R, the organic layer 112G, and the organic layer 112B can also be referred to as an EL layer and includes at least a layer containing a light-emitting organic compound (a light-emitting layer).

Since the light-emitting devices of different colors are separately formed in the display device 500A, a difference in chromaticity between light emission at low luminance and light emission at high luminance is small. Furthermore, since the organic layers 112R, 112G, and 112B are apart from each other, crosstalk generated between adjacent subpixels can be inhibited even when the display panel has a high resolution. It is thus possible to achieve a display panel that has a high resolution and high display quality.

In a region between adjacent light-emitting elements, an insulating layer 125, a resin layer 126, and a layer 128 are provided.

The pixel electrode 111R, the pixel electrode 111G, and the pixel electrode 111B of the light-emitting elements are each electrically connected to the conductor 240 in the transistor 520 through a plug 156 that is embedded in the insulating layer 155a, the insulating layer 155b, and the insulating layer 155c, the conductive layer 141 that is embedded in the insulating layer 154, and the plug 174. The top surface of the insulating layer 155c and the top surface of the plug 156 are level with or substantially level with each other. A variety of conductive materials can be used for the plugs.

A protective layer 121 is provided over the light-emitting elements 110R, 110G, and 110B. A substrate 170 is attached onto the protective layer 121 with an adhesive layer 171.

An insulating layer covering the end portion of the top surface of the pixel electrode 111 is not provided between two adjacent pixel electrodes 111. Thus, the distance between adjacent light-emitting elements can be extremely short. Accordingly, the display device can have a high resolution or a high definition.

### [Display Device 500C]

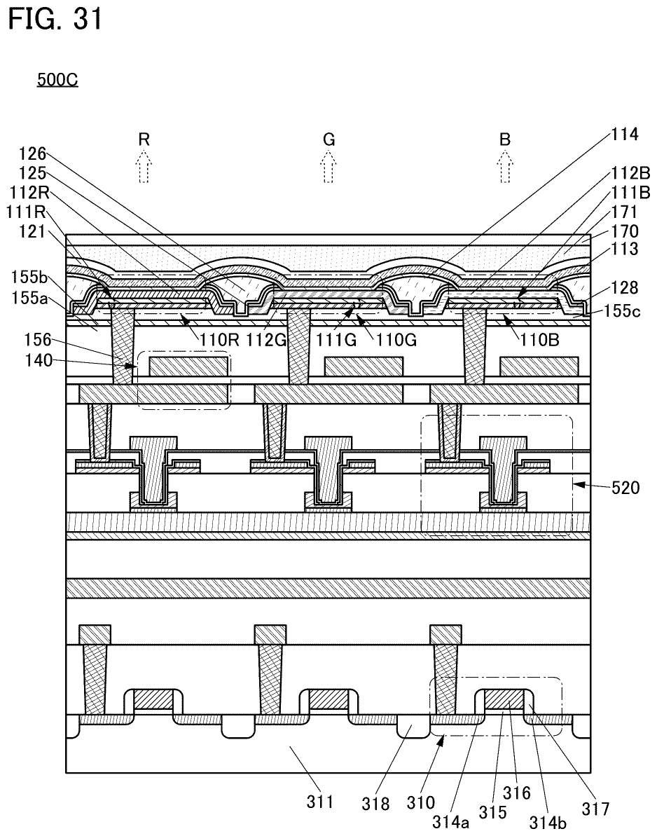

The display device 500C illustrated in FIG. 31 has a structure in which a transistor 310 whose channel is formed in a semiconductor substrate and the transistor 520 that is a vertical-channel transistor are stacked.

As in FIG. 21, the transistor 310 is a transistor including a channel formation region in the substrate 311. As the substrate 311, a semiconductor substrate such as a single crystal silicon substrate can be used, for example. The transistor 310 includes part of the substrate 311, a conductor 316, a low-resistance region 314a, a low-resistance region 314b, an insulator 315, and an insulator 317. The conductor 316 functions as agate electrode. The insulator 315 is positioned between the substrate 311 and the conductor 316 and functions as a gate insulating layer. The low-resistance region 314a and the low-resistance region 314b are each a region where the substrate 311 is doped with an impurity. The low-resistance region 314a functions as one of a source and a drain and the low-resistance region 314b functions as the other of the source and the drain. The insulator 317 is provided to cover the side surface of the conductor 316.

An element isolation layer 318 is provided between two adjacent transistors 310 to be embedded in the substrate 311.

At least part of this embodiment can be implemented in combination with the other embodiments and Example described in this specification as appropriate.

### Embodiment 6

This embodiment will describe structure examples of a display device that can be used as a display device fabricated using the transistor of one embodiment of the present invention. The display device exemplified below can be used for the pixel portion 584 in Embodiment 5, for example.

One embodiment of the present invention is a display device including a light-emitting element (also referred to as a light-emitting device). The display device includes two or more pixels of different emission colors. The pixels include light-emitting elements. The light-emitting elements each include a pair of electrodes and an EL layer therebetween. The light-emitting elements are preferably organic EL elements (organic electroluminescent elements). Two or more light-emitting elements of different emission colors include EL layers including different light-emitting materials. For example, when three kinds of light-emitting elements that emit red (R), green (G), and blue (B) light are included, a full-color display device can be achieved.

In the case of fabricating a display device including a plurality of light-emitting elements of different emission colors, at least layers containing light-emitting materials (light-emitting layers) each need to be formed in an island shape. In the case of separately forming part or the whole of an EL layer, a method for forming an island-shaped organic film by an evaporation method using a shadow mask such as a metal mask is known. However, this method causes a deviation from the designed shape and position of the island-shaped organic film due to various influences such as the accuracy of the metal mask, the positional deviation between the metal mask and a substrate, a warp of the metal mask, and expansion of the outline of a formed film due to vapor scattering, for example; accordingly, it is difficult to achieve a high resolution and a high aperture ratio of the display device. In addition, the outline of the layer might blur during evaporation, so that the thickness of an end portion might be reduced. That is, the thickness of an island-shaped light-emitting layer might vary from place to place. In addition, in the case of fabricating a display device with a large size, a high definition, or a high resolution, the manufacturing yield might be reduced because of low dimensional accuracy of the metal mask and deformation due to heat or the like. Thus, measures have been taken for a pseudo increase in resolution (also referred to as pixel density) by employing unique pixel arrangement such as PenTile arrangement.

In this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

In one embodiment of the present invention, fine patterning of EL layers is performed by photolithography without using a shadow mask such as an FMM (Fine Metal Mask). Accordingly, it is possible to achieve a display device with a high resolution and a high aperture ratio, which has been difficult to achieve so far. Moreover, since the EL layers can be formed separately, it is possible to achieve a display device that performs extremely clear display with high contrast and high display quality. Note that fine patterning of the EL layers may be performed using both a metal mask and photolithography, for example.

In addition, part or the whole of the EL layer can be physically divided. This can inhibit leakage current flowing between adjacent light-emitting elements through a layer shared by the light-emitting elements (also referred to as a common layer). This can prevent unintended light emission due to crosstalk, so that a display device with extremely high contrast can be obtained. Specifically, a display device having high current efficiency at low luminance can be obtained.

In one embodiment of the present invention, the display device can also be obtained by combining a light-emitting element that emits white light with a color filter. In that case, light-emitting elements having the same structure can be used as light-emitting elements provided in pixels (subpixels) that emit light of different colors, which allows all the layers to be common layers. In addition, part or the whole of each EL layer may be divided by photolithography. Thus, leakage current through the common layer is inhibited; accordingly, a display device with high contrast can be achieved. In particular, when an element has a tandem structure in which a plurality of light-emitting layers are stacked with a highly conductive intermediate layer therebetween, leakage current through the intermediate layer can be effectively prevented, so that a display device with high luminance, a high resolution, and high contrast can be achieved.

In the case where the EL layer is processed by a photolithography method, part of the light-emitting layer is sometimes exposed to cause deterioration. Thus, an insulating layer covering at least the side surface of the island-shaped light-emitting layer is preferably provided. The insulating layer may cover part of the top surface of the island-shaped EL layer. For the insulating layer, a material having a barrier property against water and oxygen is preferably used. For example, an inorganic insulating film that is less likely to diffuse water or oxygen can be used. This can inhibit deterioration of the EL layer and can achieve a highly reliable display device.

Moreover, between two adjacent light-emitting elements, there is a region (a depressed portion) where none of the EL layers of the light-emitting elements is provided. In the case where a common electrode or a common electrode and a common layer are formed to cover the depressed portion, a phenomenon where the common electrode is divided by a step at an end portion of the EL layer (such a phenomenon is also referred to as disconnection) might occur, which might cause insulation of the common electrode over the EL layer. In view of this, a structure is preferably employed in which a local gap positioned between two adjacent light-emitting elements is filled with a resin layer functioning as a planarization film (also referred to as LFP: Local Filling Planarization). The resin layer has a function of a planarization film. This structure can inhibit disconnection of the common layer or the common electrode and can achieve a highly reliable display device.

More specific structure examples of the display device of one embodiment of the present invention will be described below with reference to drawings.

### Structure Example 1

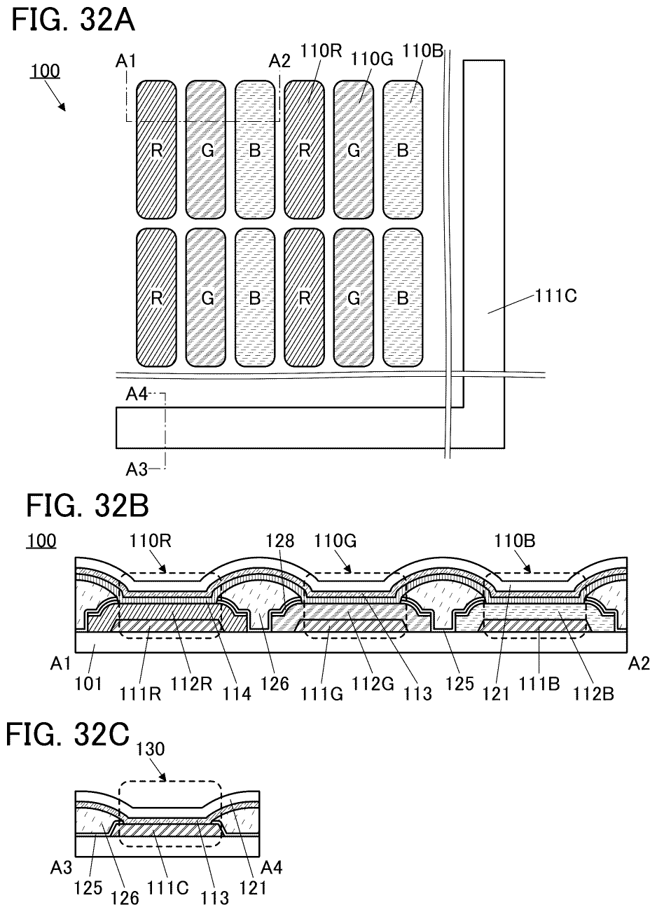

FIG. 32A is a schematic top view of a display device 100 of one embodiment of the present invention. The display device 100 includes, over a substrate 101, a plurality of the light-emitting elements 110R exhibiting red, a plurality of the light-emitting elements 110G exhibiting green, and a plurality of the light-emitting elements 110B exhibiting blue. In FIG. 32A, light-emitting regions of the light-emitting elements are denoted by R, G, and B to easily differentiate the light-emitting elements.

The light-emitting elements 110R, the light-emitting elements 110G, and the light-emitting elements 110B are arranged in a matrix. FIG. 32A illustrates what is called stripe arrangement, in which the light-emitting elements of the same color are arranged in one direction. Note that an arrangement method of the light-emitting elements is not limited thereto; an arrangement method such as S-stripe arrangement, delta arrangement, Bayer arrangement, or zigzag arrangement may be employed, or PenTile arrangement, diamond arrangement, or the like can also be used.

As each of the light-emitting elements 110R, the light-emitting elements 110G, and the light-emitting elements 110B, an OLED (Organic Light Emitting Diode) or a QLED (Quantum-dot Light Emitting Diode) is preferably used, for example. Examples of a light-emitting substance contained in the EL element include a substance that emits fluorescent light (a fluorescent material), a substance that emits phosphorescent light (a phosphorescent material), and a substance that exhibits thermally activated delayed fluorescence (a thermally activated delayed fluorescent (TADF) material). As the light-emitting substance contained in the EL element, not only an organic compound but also an inorganic compound (a quantum dot material or the like) can be used.

FIG. 32A also illustrates a connection electrode 111C electrically connected to the common electrode 113. The connection electrode 111C is supplied with a potential (e.g., an anode potential or a cathode potential) that is to be supplied to the common electrode 113. The connection electrode 111C is provided outside a display region where the light-emitting elements 110R and the like are arranged.

The connection electrode 111C can be provided along the outer periphery of the display region. For example, the connection electrode 111C may be provided along one side of the outer periphery of the display region, or the connection electrode 111C may be provided along two or more sides of the outer periphery of the display region. That is, in the case where the display region has a rectangular top surface shape, the top surface shape of the connection electrode 111C can be a band shape (a rectangle), an L shape, a U shape (a square bracket shape), a quadrangular shape, or the like.

FIG. 32B and FIG. 32C are schematic cross-sectional views corresponding to the dashed-dotted line A1-A2 and the dashed-dotted line A3-A4 in FIG. 32A. FIG. 32B is a schematic cross-sectional view of the light-emitting element 110R, the light-emitting element 110G, and the light-emitting element 110B, and FIG. 32C is a schematic cross-sectional view of a connection portion 130 where the connection electrode 111C and the common electrode 113 are connected to each other.

The light-emitting element 110R includes the pixel electrode 111R, the organic layer 112R, the common layer 114, and the common electrode 113. The light-emitting element 110G includes the pixel electrode 111G, the organic layer 112G, the common layer 114, and the common electrode 113. The light-emitting element 110B includes the pixel electrode 111B, the organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R contains at least a light-emitting organic compound that emits red light. The organic layer 112G included in the light-emitting element 110G contains at least a light-emitting organic compound that emits green light. The organic layer 112B included in the light-emitting element 110B contains at least a light-emitting organic compound that emits blue light. Each of the organic layer 112R, the organic layer 112G, and the organic layer 112B can also be referred to as an EL layer and includes at least a layer containing a light-emitting organic compound (a light-emitting layer).

Hereinafter, the term “light-emitting element 110” is sometimes used to describe matters common to the light-emitting element 110R, the light-emitting element 110G, and the light-emitting element 110B. Similarly, in the description of matters common to components that are distinguished from each other using alphabets, such as the organic layer 112R, the organic layer 112G, and the organic layer 112B, reference numerals without alphabets are sometimes used.

The organic layer 112 and the common layer 114 can each independently include one or more of an electron-injection layer, an electron-transport layer, a hole-injection layer, and a hole-transport layer. For example, it is possible to employ a structure in which the organic layer 112 has a stacked-layer structure of a hole-injection layer, a hole-transport layer, a light-emitting layer, and an electron-transport layer from the pixel electrode 111 side and the common layer 114 includes an electron-injection layer.

The pixel electrode 111R, the pixel electrode 111G, and the pixel electrode 111B are provided for the respective light-emitting elements. The common electrode 113 and the common layer 114 are each provided as one continuous layer shared by the light-emitting elements. A conductive film having a light-transmitting property with respect to visible light is used for either the pixel electrodes or the common electrode 113, and a conductive film having a reflective property is used for the other. When the pixel electrodes have a light-transmitting property and the common electrode 113 has a reflective property, a bottom-emission display device can be obtained. By contrast, when the pixel electrodes have a reflective property and the common electrode 113 has a light-transmitting property, a top-emission display device can be obtained. Note that when both the pixel electrodes and the common electrode 113 have a light-transmitting property, a dual-emission display device can be obtained.

The protective layer 121 is provided over the common electrode 113 to cover the light-emitting elements 110. The protective layer 121 has a function of preventing diffusion of impurities such as water into the light-emitting elements from the above.

The end portion of the pixel electrode 111 preferably has a tapered shape. In the case where the end portion of the pixel electrode 111 has a tapered shape, the organic layer 112 provided along the end portion of the pixel electrode 111 can also have a tapered shape. When the end portion of the pixel electrode 111 has a tapered shape, coverage with the organic layer 112 provided beyond the end portion of the pixel electrode 111 can be increased. The side surface of the pixel electrode 111 preferably has a tapered shape, in which case a foreign matter (also referred to as dust or particles, for example) in the fabrication process is easily removed by processing such as cleaning.

The organic layer 112 is processed into an island shape by a photolithography method. Thus, an angle formed between the top surface and the side surface of the end portion of the organic layer 112 is approximately 90°. By contrast, an organic film formed using an FMM or the like has a thickness that tends to gradually decrease with decreasing distance to the end portion, and has a top surface forming a slope in an area extending greater than or equal to 1 μm and less than or equal to 10 μm to the end portion, for example; thus, such an organic film has a shape whose top surface and side surface are difficult to distinguish from each other.

The insulating layer 125, the resin layer 126, and the layer 128 are included between two adjacent light-emitting elements.

Between two adjacent light-emitting elements, the side surfaces of the organic layers 112 are provided to face each other with the resin layer 126 therebetween. The resin layer 126 is positioned between the two adjacent light-emitting elements and is provided to bury the end portions of the organic layers 112 and a region between the two organic layers 112. The resin layer 126 has a top surface with a smooth protruding shape, and the common layer 114 and the common electrode 113 are provided to cover the top surface of the resin layer 126.

The resin layer 126 functions as a planarization film that fills a step positioned between two adjacent light-emitting elements. Providing the resin layer 126 can prevent a phenomenon in which the common electrode 113 is divided by a step at the end portion of the organic layer 112 (also referred to as disconnection) from occurring and the common electrode over the organic layer 112 from being insulated. The resin layer 126 can also be referred to as an LFP (Local Filling Planarization) layer.

An insulating layer containing an organic material can be suitably used as the resin layer 126. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 126. A photoresist may be used as the photosensitive resin. As the photosensitive resin, a material of positive type or a material of negative type can be used.

The resin layer 126 may include a material absorbing visible light. For example, the resin layer 126 itself may be made of a material absorbing visible light, or the resin layer 126 may include a pigment absorbing visible light. For example, for the resin layer 126, it is possible to use a resin that can be used as a color filter transmitting red, blue, or green light and absorbing other light, a resin that contains carbon black as a pigment and functions as a black matrix, or the like.

The insulating layer 125 is provided in contact with the side surface of the organic layer 112. In addition, the insulating layer 125 is provided to cover an upper end portion of the organic layer 112. Furthermore, part of the insulating layer 125 is provided in contact with the top surface of the substrate 101.

The insulating layer 125 is positioned between the resin layer 126 and the organic layer 112 and functions as a protective film for preventing the resin layer 126 from being in contact with the organic layer 112. When the organic layer 112 and the resin layer 126 are in contact with each other, the organic layer 112 might be dissolved by an organic solvent or the like used at the time of forming the resin layer 126. Thus, providing the insulating layer 125 between the organic layer 112 and the resin layer 126 can protect the side surface of the organic layer 112.

An insulating layer including an inorganic material can be used as the insulating layer 125. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD method is used for the insulating layer 125, it is possible to form the insulating layer 125 that has a small number of pinholes and has an excellent function of protecting the EL layer.

In this specification and the like, oxynitride refers to a material having a composition in which the oxygen content is higher than the nitrogen content, and nitride oxide refers to a material having a composition in which the nitrogen content is higher than the oxygen content. For example, silicon oxynitride refers to a material having a composition in which the oxygen content is higher than the nitrogen content, and silicon nitride oxide refers to a material having a composition in which the nitrogen content is higher than the oxygen content.

The insulating layer 125 can be formed by a sputtering method, a CVD method, a PLD method, an ALD method, or the like. The insulating layer 125 is preferably formed by an ALD method that provides good coverage.

In addition, a structure may be employed in which a reflective film (e.g., a metal film containing one or more selected from silver, palladium, copper, titanium, aluminum, and the like) is provided between the insulating layer 125 and the resin layer 126 so that light emitted from the light-emitting layer is reflected by the reflective film. This can improve light extraction efficiency.

The layer 128 is a remaining part of a protective layer (also referred to as a mask layer or a sacrificial layer) for protecting the organic layer 112 during etching of the organic layer 112. For the layer 128, any of the materials that can be used for the insulating layer 125 can be used. It is particularly preferable to use the same material for the layer 128 and the insulating layer 125, in which case an apparatus or the like for processing can be used in common.

In particular, since a metal oxide film such as an aluminum oxide film or a hafnium oxide film or an inorganic insulating film such as a silicon oxide film that is formed by an ALD method has a small number of pinholes, such a film has an excellent function of protecting the EL layer and can be suitably used for the insulating layer 125 and the layer 128.

The protective layer 121 can have, for example, a single-layer structure or a stacked-layer structure including at least an inorganic insulating film. Examples of the inorganic insulating film include oxide films and nitride films such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as indium gallium oxide, indium zinc oxide, indium tin oxide, or indium gallium zinc oxide may be used for the protective layer 121.

For the protective layer 121, a stacked-layer film of an inorganic insulating film and an organic insulating film can be used. For example, a structure in which an organic insulating film is sandwiched between a pair of inorganic insulating films is preferable. Furthermore, the organic insulating film preferably functions as a planarization film. In that case, the top surface of the organic insulating film can be flat, whereby the coverage thereof with the inorganic insulating film can be improved to achieve higher barrier properties. The top surface of the protective layer 121 is flat, which is preferable because the influence of an uneven shape due to a component below the protective layer 121 can be reduced in the case where a component (e.g., a color filter, an electrode of a touch sensor, or a lens array) is provided above the protective layer 121.

FIG. 32C illustrates the connection portion 130 in which the connection electrode 111C and the common electrode 113 are electrically connected to each other. In the connection portion 130, an opening portion is provided in the insulating layer 125 and the resin layer 126 over the connection electrode 111C. The connection electrode 111C and the common electrode 113 are electrically connected to each other in the opening portion.

Although FIG. 32C illustrates the connection portion 130 in which the connection electrode 111C and the common electrode 113 are electrically connected to each other, the common electrode 113 may be provided over the connection electrode 111C with the common layer 114 therebetween. Particularly in the case where a carrier-injection layer is used as the common layer 114, for example, a material used for the common layer 114 has sufficiently low electrical resistivity and the common layer 114 can be formed to be thin; thus, problems do not arise in many cases even when the common layer 114 is positioned in the connection portion 130. Accordingly, the common electrode 113 and the common layer 114 can be formed with the use of the same shielding mask, so that manufacturing cost can be reduced.

### Structure Example 2

A display device having a structure partly different from that in Structure example 1 described above will be described below. Note that the above description is referred to for portions common to those in Structure example 1, and the description is omitted in some cases.

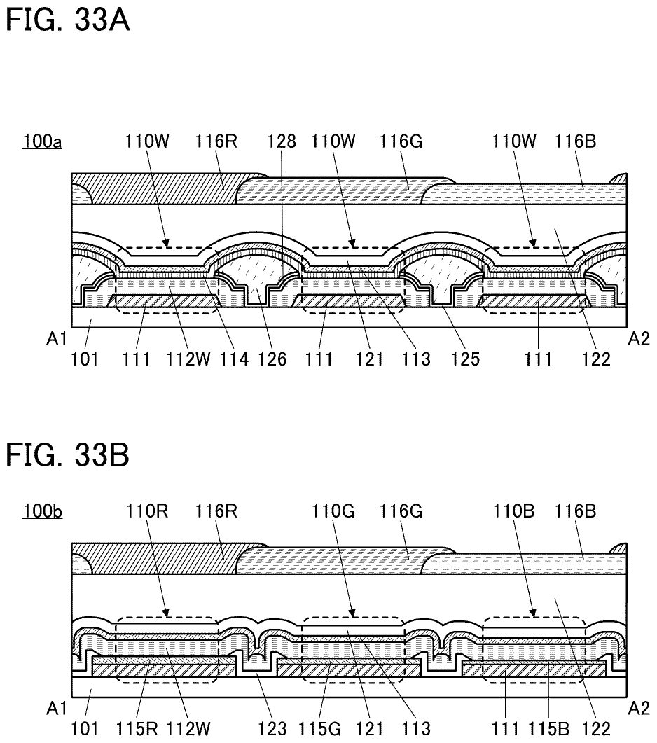

FIG. 33A is a schematic cross-sectional view of a display device 100a. The display device 100a is different from the above-described display device 100 mainly in the structure of the light-emitting element and including a coloring layer.

The display device 100a includes a light-emitting element 110W that emits white light. The light-emitting element 110W includes the pixel electrode 111, an organic layer 112W, the common layer 114, and the common electrode 113. The organic layer 112W emits white light. For example, the organic layer 112W can include two or more kinds of light-emitting materials whose emission colors are complementary colors. For example, the organic layer 112W can include a light-emitting organic compound that emits red light, a light-emitting organic compound that emits green light, and a light-emitting organic compound that emits blue light. Alternatively, the organic layer 112W may include a light-emitting organic compound that emits blue light and a light-emitting organic compound that emits yellow light.

The organic layer 112W is divided between two adjacent light-emitting elements 110W. Thus, leakage current flowing between the adjacent light-emitting elements 110W through the organic layer 112W can be inhibited and crosstalk due to the leakage current can be inhibited. Accordingly, the display device can have high contrast and high color reproducibility.

An insulating layer 122 functioning as a planarization film is provided over the protective layer 121, and a coloring layer 116R, a coloring layer 116G, and a coloring layer 116B are provided over the insulating layer 122.

An organic resin film or an inorganic insulating film with a flat top surface can be used as the insulating layer 122. The insulating layer 122 serves as a formation surface of the coloring layer 116R, the coloring layer 116G, and the coloring layer 116B; thus, with a flat top surface of the insulating layer 122, the thicknesses of the coloring layer 116R and the like can be uniform and color purity can be increased. Note that when the thicknesses of the coloring layer 116R and the like are not uniform, the amount of light absorption varies from place to place in the coloring layer 116R, which might decrease the color purity.

### Structure Example 3

FIG. 33B is a schematic cross-sectional view of a display device 100b.

The light-emitting element 110R includes the pixel electrode 111, a conductive layer 115R, the organic layer 112W, and the common electrode 113. The light-emitting element 110G includes the pixel electrode 111, a conductive layer 115G, the organic layer 112W, and the common electrode 113. The light-emitting element 110B includes the pixel electrode 111, a conductive layer 115B, the organic layer 112W, and the common electrode 113. The conductive layer 115R, the conductive layer 115G, and the conductive layer 115B each have a light-transmitting property and function as an optical adjustment layer.

A film that reflects visible light is used for the pixel electrode 111 and a film having properties of reflecting and transmitting visible light is used for the common electrode 113, so that a micro resonator (microcavity) structure can be achieved. At this time, by adjusting the thicknesses of the conductive layer 115R, the conductive layer 115G, and the conductive layer 115B to obtain optimal optical path lengths, light obtained from the light-emitting element 110R, the light-emitting element 110G, and the light-emitting element 110B can be intensified light with different wavelengths even in the case where the organic layer 112 exhibiting white light emission is used.

Furthermore, the coloring layer 116R, the coloring layer 116G, and the coloring layer 116B are provided on the optical paths of the light-emitting element 110R, the light-emitting element 110G, and the light-emitting element 110B, respectively, whereby light with high color purity can be obtained.

An insulating layer 123 that covers the end portions of the pixel electrode 111 and the conductive layer 115 is provided. The end portion of the insulating layer 123 preferably has a tapered shape. When the insulating layer 123 is provided, coverage with the organic layer 112W, the common electrode 113, the protective layer 121, and the like formed over the insulating layer 123 can be increased.

The organic layer 112W and the common electrode 113 are each provided as one continuous film shared by the light-emitting elements. Such a structure is preferable because the fabrication process of the display device can be greatly simplified.

Here, the end portion of the pixel electrode 111 preferably has a substantially vertical shape. Accordingly, a steep portion can be formed on the surface of the insulating layer 123, and thus a thin portion can be formed in part of the organic layer 112W that covers the steep portion or part of the organic layer 112W can be divided. Consequently, leakage current generated between adjacent light-emitting elements through the organic layer 112W can be inhibited without processing the organic layer 112W by a photolithography method or the like.

The above is the description of the structure examples of the display devices.

At least part of this embodiment can be implemented in combination with the other embodiments and Example described in this specification as appropriate.

### Embodiment 7

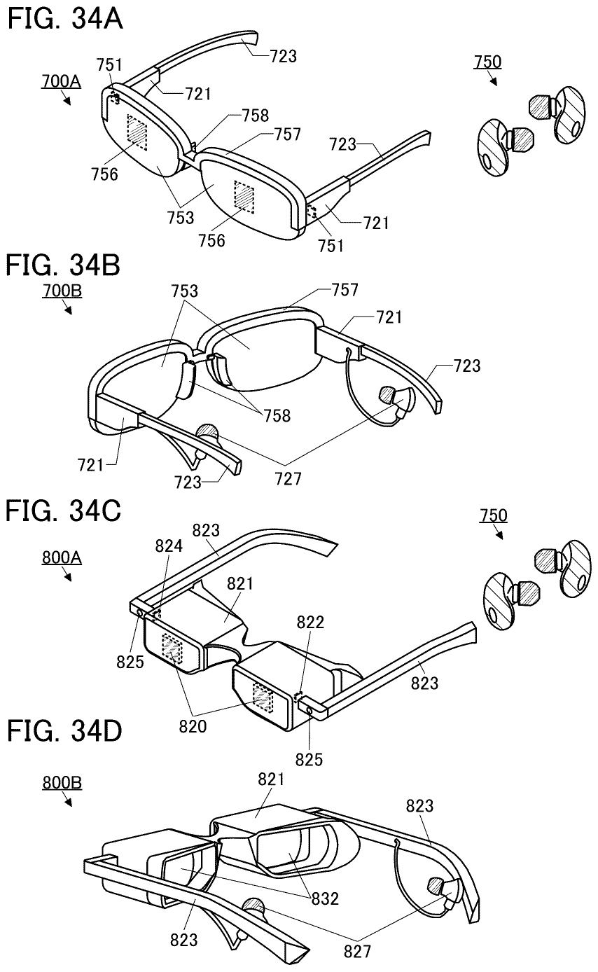

In this embodiment, electronic devices of one embodiment of the present invention will be described with reference to FIG. 34 to FIG. 36.

Electronic devices in this embodiment each include a display panel (display device) employing the transistor of one embodiment of the present invention in a display portion. The display device of one embodiment of the present invention can easily achieve higher resolution and higher definition and can achieve high display quality. Thus, the display device of one embodiment of the present invention can be used for display portions of a variety of electronic devices.

Examples of the electronic devices include a digital camera, a digital video camera, a digital photo frame, a mobile phone, a portable game machine, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display panel of one embodiment of the present invention can have higher resolution and thus can be suitably used for an electronic device having a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The definition of the display panel of one embodiment of the present invention is preferably as high as HD (pixel count: 1280×720), FHD (pixel count: 1920×1080), WQHD (pixel count: 2560×1440), WQXGA (pixel count: 2560×1600), 4K (pixel count: 3840×2160), or 8K (pixel count: 7680×4320). In particular, a definition of 4K, 8K, or higher is preferable. In addition, the pixel density (resolution) of the display panel of one embodiment of the present invention is preferably higher than or equal to 100 ppi, further preferably higher than or equal to 300 ppi, still further preferably higher than or equal to 500 ppi, yet further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. With the use of such a display panel having one or both of high definition and high resolution, realistic sensation, sense of depth, and the like can be further increased. There is no particular limitation on the screen ratio (aspect ratio) of the display panel of one embodiment of the present invention. For example, the display panel is compatible with a variety of screen ratios such as 1:1 (a square), 4:3, 16:9, and 16:10.

The electronic device in this embodiment may include a sensor (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, electric power, radiation, a flow rate, humidity, a gradient, oscillation, odor, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of wearable devices that can be worn on a head will be described with reference to FIG. 34A to FIG. 34D. These wearable devices have one or both of a function of displaying AR contents and a function of displaying VR contents. Note that the wearable devices may have a function of displaying SR or MR contents, in addition to AR and VR contents. The electronic device having a function of displaying contents of at least one of AR, VR, SR, MR, and the like enables the user to reach a higher level of immersion.

An electronic device 700A illustrated in FIG. 34A and an electronic device 700B illustrated in FIG. 34B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display panel of one embodiment of the present invention can be used as the display panels 751. Thus, the electronic device can perform display with extremely high resolution.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion can include a wireless communication device, and a video signal and the like can be supplied by the wireless communication device. Note that instead of the wireless communication device or in addition to the wireless communication device, a connector to which a cable for supplying a video signal and a power supply potential can be connected may be provided.

In addition, each of the electronic device 700A and the electronic device 700B is provided with a battery so that charging can be performed wirelessly and/or by wire.

A touch sensor module may be provided in the housing 721. The touch sensor module has a function of detecting touch on the outer surface of the housing 721. A tap operation, a slide operation, or the like by the user can be detected with the touch sensor module, whereby a variety of processing can be executed. For example, processing such as a pause or a restart of a moving image can be executed by a tap operation, and processing such as fast forward or fast rewind can be executed by a slide operation. When the touch sensor module is provided in each of the two housings 721, the range of the operation can be increased.

Various touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic device 800A illustrated in FIG. 34C and an electronic device 800B illustrated in FIG. 34D each include a pair of display portions 820, a housing 821, a communication portion 822, a pair of wearing portions 823, a control portion 824, a pair of image capturing portions 825, and a pair of lenses 832.

The display panel of one embodiment of the present invention can be used for the display portions 820. Thus, the electronic device can perform display with extremely high resolution. This enables a user to feel a high sense of immersion.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be worn on the user's head with the wearing portions 823. FIG. 34C and the like illustrate examples in which the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided to cover a plurality of fields of view, such as a telescope field of view and a wide field of view.

Although an example in which the image capturing portion 825 is provided is illustrated here, a range sensor (hereinafter, also referred to as a sensing portion) capable of measuring a distance to an object just needs to be provided. That is, the image capturing portion 825 is one embodiment of the sensing portion. For the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy a video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 34A has a function of transmitting information to the earphones 750 with the wireless communication function. For another example, the electronic device 800A illustrated in FIG. 34C has a function of transmitting information to the earphones 750 with the wireless communication function.

The electronic device may include earphone portions. The electronic device 700B illustrated in FIG. 34B includes earphone portions 727. For example, a structure in which the earphone portions 727 and the control portion are connected to each other by wire can be employed. Part of a wiring that connects the earphone portions 727 and the control portion may be positioned inside the housing 721 or the wearing portion 723.

Similarly, the electronic device 800B illustrated in FIG. 34D includes earphone portions 827. For example, a structure in which the earphone portions 827 and the control portion 824 are connected to each other by wire can be employed. Part of a wiring that connects the earphone portions 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

Note that the electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are suitable as the electronic device of one embodiment of the present invention.

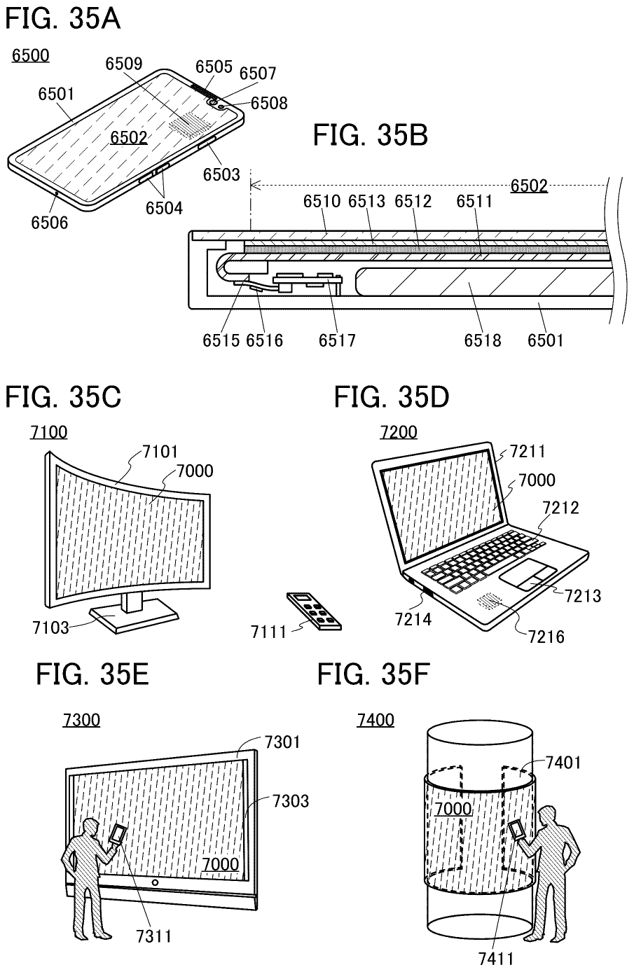

The electronic device 6500 illustrated in FIG. 35A is a portable information terminal that can be used as a smartphone.

The electronic device 6500 includes the housing 6501, the display portion 6502, the power button 6503, the buttons 6504, the speaker 6505, the microphone 6506, the camera 6507, the light source 6508, the control device 6509, and the like. The display portion 6502 has a touch panel function. Note that as the control device 6509, for example, one or more selected from a CPU, a GPU, and a memory device are included. The semiconductor device of one embodiment of the present invention can be used for the display portion 6502, the control device 6509, and the like. The semiconductor device of one embodiment of the present invention is preferably used for the control device 6509, in which case power consumption can be reduced.

The display panel of one embodiment of the present invention can be used for the display portion 6502.

FIG. 35B is a schematic cross-sectional view including the end portion of the housing 6501 on the microphone 6506 side.

A protection member 6510 having a light-transmitting property is provided on the display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A display device of one embodiment of the present invention can be used for the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back such that a connection portion with the FPC 6515 is provided on the back side of a pixel portion, whereby an electronic device with a narrow bezel can be achieved.

FIG. 35C illustrates an example of a television device. In a television device 7100, a display portion 7000 is incorporated in a housing 7101. Here, the housing 7101 is supported by a stand 7103.

Operation of the television device 7100 illustrated in FIG. 35C can be performed with an operation switch provided in the housing 7101 and a separate remote controller 7111.

Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 35D illustrates an example of a laptop personal computer. A laptop personal computer 7200 includes a housing 7211, a keyboard 7212, a pointing device 7213, an external connection port 7214, a control device 7216, and the like. In the housing 7211, the display portion 7000 is incorporated. As the control device 7216, for example, one or more selected from a CPU, a GPU, and a memory device are included. The semiconductor device of one embodiment of the present invention can be used for the display portion 7000, the control device 7216, and the like. The semiconductor device of one embodiment of the present invention is preferably used for the control device 7216, in which case power consumption can be reduced.

FIG. 35E and FIG. 35F illustrate examples of digital signage.

Digital signage 7300 illustrated in FIG. 35E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 35F illustrates digital signage 7400 attached to a cylindrical pillar 7401. The digital signage 7400 includes the display portion 7000 provided along a curved surface of the pillar 7401.

The larger display portion 7000 can provide a larger amount of information at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 35E and FIG. 35F, it is preferable that the digital signage 7300 or the digital signage 7400 be capable of working with an information terminal 7311 or an information terminal 7411, such as a smartphone a user has, through wireless communication. For example, information of an advertisement displayed on the display portion 7000 can be displayed on a screen of the information terminal 7311 or the information terminal 7411. By operating the information terminal 7311 or the information terminal 7411, display on the display portion 7000 can be switched.

It is also possible to make the digital signage 7300 or the digital signage 7400 execute a game with the use of the screen of the information terminal 7311 or the information terminal 7411 as an operation means (a controller). Thus, an unspecified number of users can join in and enjoy the game concurrently.

The display panel of one embodiment of the present invention can be used for the display portion 7000 in each of FIG. 35C to FIG. 35F.

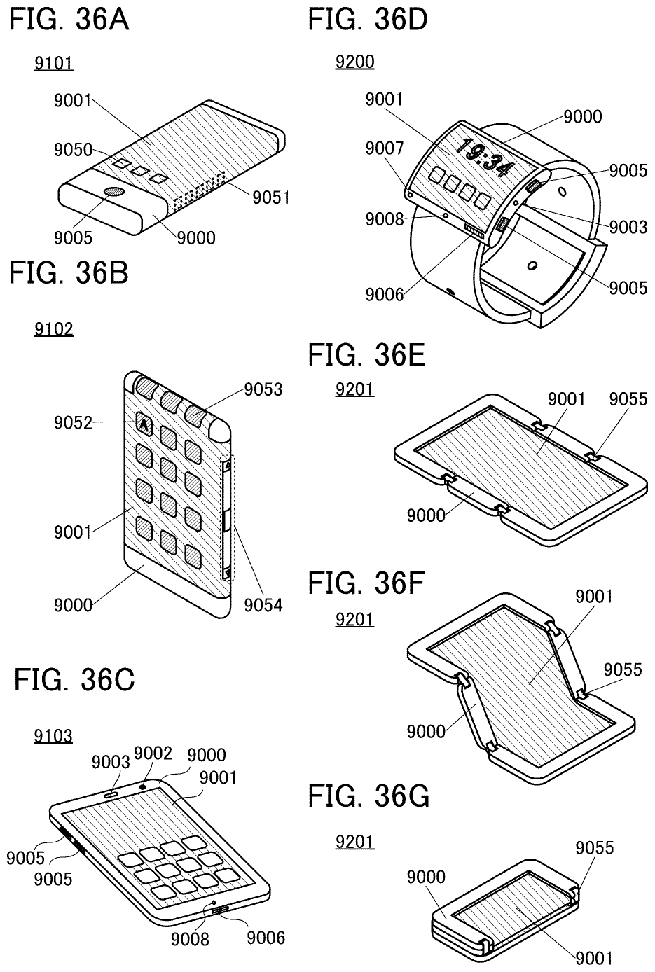

Electronic devices illustrated in FIG. 36A to FIG. 36G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, electric power, radiation, a flow rate, humidity, a gradient, oscillation, odor, or infrared rays), a microphone 9008, and the like.

The electronic devices illustrated in FIG. 36A to FIG. 36G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading and processing a program or data stored in a recording medium. Note that the functions of the electronic devices are not limited thereto, and the electronic devices can have a variety of functions. The electronic devices may each include a plurality of display portions. In addition, the electronic devices may each be provided with a camera or the like and have a function of taking a still image or a moving image and storing the taken image in a recording medium (an external recording medium or a recording medium incorporated in the camera), a function of displaying the taken image on the display portion, or the like.

The details of the electronic devices illustrated in FIG. 36A to FIG. 36G are described below.

FIG. 36A is a perspective view illustrating a portable information terminal 9101. The portable information terminal 9101 can be used as a smartphone, for example. Note that the portable information terminal 9101 may be provided with the speaker 9003, the connection terminal 9006, the sensor 9007, or the like. The portable information terminal 9101 can display text and image information on its plurality of surfaces. FIG. 36A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 36B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 36C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface.

FIG. 36D is a perspective view illustrating a watch-type portable information terminal 9200. The portable information terminal 9200 can be used as a Smartwatch (registered trademark), for example. The display surface of the display portion 9001 is curved, and display can be performed on the curved display surface. Furthermore, mutual communication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 36E to FIG. 36G are perspective views illustrating a foldable portable information terminal 9201. FIG. 36E is a perspective view of an opened state of the portable information terminal 9201, FIG. 36G is a perspective view of a folded state thereof, and FIG. 36F is a perspective view of a state in the middle of change from one of FIG. 36E and FIG. 36G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

At least part of this embodiment can be implemented in combination with the other embodiments and Example described in this specification as appropriate.

### Example

In this example, the results of device simulation for evaluating the electrical characteristics of the semiconductor device of one embodiment of the present invention are described.

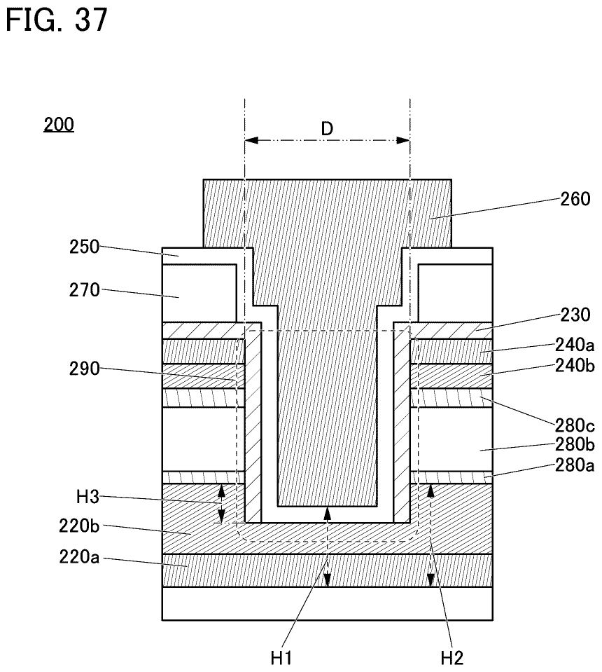

FIG. 37 illustrates a model used for the device simulation in this example. Like the transistor 200 illustrated in FIG. 1A to FIG. 1D and FIG. 2A, the transistor 200 of the model illustrated in FIG. 37 includes the conductor 220a, the conductor 220b, the insulator 280a, the insulator 280b, the insulator 280c, the conductor 240b, the conductor 240a, the oxide semiconductor 230, the insulator 250, the insulator 270, and the conductor 260. The opening portion 290 is formed in the conductor 240a, the conductor 240b, and the insulator 280a to the insulator 280c, and the oxide semiconductor 230, the insulator 250, and the conductor 260 are formed in the opening portion 290. Note that in the model in this example, unlike in the transistor 200 illustrated in FIG. 1A to FIG. 1D and FIG. 2A, the side surface of the conductor 240a and the side surface of the conductor 240b are aligned with each other. The conductor 240a is formed over the conductor 240b. A protruding portion in the lower portion of the oxide semiconductor 230 is omitted.

Materials assumed to be used for the components of the transistor 200 are described. The conductor 220a is a tungsten film and the conductor 220b is an ITSO film. The insulator 280a and the insulator 280c are silicon nitride films and the insulator 280b is a silicon oxide film. The conductor 240b is a tungsten film and the conductor 240a is an ITSO film. The oxide semiconductor 230 is an In—Ga—Zn oxide film with In:Ga:Zn=1:1:1.2 [atomic ratio](also referred to as IGZO(111) in some cases). The insulator 250 is a stacked-layer film in which an aluminum oxide film, a silicon oxide film, a hafnium oxide film, and a silicon nitride film are formed in this order. The insulator 270 is a silicon oxide film. The conductor 260 is a titanium nitride film.

Table 1 shows the list of parameters used in the device simulation in this example.

TABLE 1

| | | Film | Work | Relative |
|---|---|---|---|---|
| | Material | thickness/nm | function/eV | permittivity |
| 260 | Titanium nitride | | 4.7 | |
| 270 | Silicon oxide | 27 | | 4.1 |
| 250 | Silicon nitride | 1 | | 7.4 |
| | Hafnium oxide | 2 | | 19.6 |
| | Silicon oxide | 2 | | 4.1 |
| | Aluminum oxide | 1 | | 8.5 |
| 230 | IGZO(111) | 7 | | 15.0 |
| 240a | ITSO | 10 | 4.4 | |
| 240b | Tungsten | 15 | 5.0 | |
| 280c | Silicon nitride | 10 | | 7.4 |
| 280b | Silicon oxide | 20 | | 4.1 |
| 280a | Silicon nitride | 5 | | 7.4 |
| 220b | ITSO | 16 | 4.4 | |
| 220a | Tungsten | 20 | 5.0 | |

Here, a depth H3 of the depressed portion of the conductor 220b illustrated in FIG. 37 is 11 nm. The height H1 is 31 nm and the height H2 is 36 nm. Thus, the height H1 is lower than the height H2 also in the model for this simulation. The diameter of the opening portion 290 is 60 nm.

In the oxide semiconductor 230, the electron affinity is 4.7 eV, the band gap is 3.12 V, the electron mobility is 6 cm²/Vs, the hole mobility is 0.01 cm²/Vs, the density of states in the conduction band is 5.0×10¹⁸/cm³, the density of states in the valence band is 5.0×10¹⁸/cm³, the donor concentration in the channel is 1.0×10¹⁰/cm³, the donor concentrations in the source and the drain are each 1.0×10²⁰/cm³, and the fixed charge at the interface between the insulator 280 and the oxide semiconductor 230 is −1.1×10¹³/cm².

In this example, the device simulation was performed using TCAD Sentaurus of Synopsys Inc. and the drain current-gate voltage characteristics (Id-Vg characteristics) of the transistor were calculated. Specifically, the Id-Vg characteristics of the transistor including the conductor 220a and the conductor 220b as the source electrode and the conductor 240a and the conductor 240b as the drain electrode were calculated. In the calculation of the Id-Vg characteristics, Vg is swept from −4.0 V to +4.0 V, the drain voltage Vd is 1.2 V, and the source voltage Vs is 0 V.

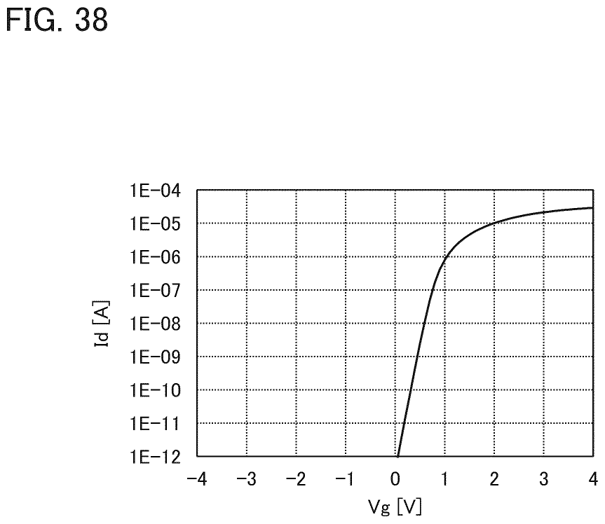

FIG. 38 shows the Id-Vg characteristics (drain voltage Vd=1.2 V) of the transistor illustrated in FIG. 37. As shown in FIG. 38, favorable normally-off electrical characteristics are obtained in the device simulation in this example. In particular, a favorable S value of 128 mV/dec is obtained. In the model in this example, the height H1 is lower than the height H2, and the conductor 260 functioning as a gate is formed to be embedded in the depressed portion of the conductor 220b. Accordingly, it is considered that the electric field of the conductor 260 is sufficiently applied to the oxide semiconductor 230 also in the vicinity of the top surface of the conductor 220b, whereby favorable electrical characteristics are obtained.

As described above, when the height H1 is lower than the height H2, a vertical transistor with favorable electrical characteristics can be provided.

### REFERENCE NUMERALS

100a: display device, 100b: display device, 100: display device, 101: substrate, 1101B: light-emitting element, 110G: light-emitting element, 110R: light-emitting element, 110W: light-emitting element, 110: light-emitting element, 111B: pixel electrode, 111C: connection electrode, 111G: pixel electrode, 111R: pixel electrode, 111: pixel electrode, 112B: organic layer, 112G: organic layer, 112R: organic layer, 112W: organic layer, 112: organic layer, 113: common electrode, 114: common layer, 115B: conductive layer, 115G: conductive layer, 115R: conductive layer, 115: conductive layer, 116B: coloring layer, 116G: coloring layer, 116R: coloring layer, 121: protective layer, 122: insulating layer, 123: insulating layer, 125: insulating layer, 126: resin layer, 128: layer, 130: connection portion, 140: capacitor, 141: conductive layer, 143: insulating layer, 145: conductive layer, 154: insulating layer, 155a: insulating layer, 155b: insulating layer, 155c: insulating layer, 156: plug, 164: insulating layer, 170: substrate, 171: adhesive layer, 174a: conductive layer, 174b: conductive layer, 174: plug, 200_1: transistor, 200_2: transistor, 200_3: transistor, 200_4: transistor, 200a: transistor, 200b: transistor, 200: transistor, 201: substrate, 210: insulator, 220_1: conductor, 220_2: conductor, 220_3: conductor, 220_4: conductor, 220a: conductor, 220a_1: conductor, 220a_2: conductor, 220a_4: conductor, 220b: conductor, 220b_1: conductor, 220b_2: conductor, 220b_4: conductor, 220c: conductor, 220: conductor, 222: insulator, 230_1: oxide semiconductor, 230_2: oxide semiconductor, 230_3: oxide semiconductor, 230_4: oxide semiconductor, 230a: oxide semiconductor, 230b: oxide semiconductor, 230c: oxide semiconductor, 230: oxide semiconductor, 240_1: conductor, 240_2: conductor, 240_3: conductor, 240_4: conductor, 240a: conductor, 240A: conductive film, 240a_1: conductor, 240a_2: conductor, 240a_4: conductor, 240b: conductor, 240B: conductive film, 240b_1: conductor, 240b_2: conductor, 240b_4: conductor, 240: conductor, 250a: insulator, 250b: insulator, 250c: insulator, 250: insulator, 260a: conductor, 260A: conductive film, 260b: conductor, 260c: conductor, 260: conductor, 270A: insulating film, 270: insulator, 280a: insulator, 280b: insulator, 280c: insulator, 280: insulator, 283: insulator, 285: insulator, 287A: coating film, 287: sacrificial layer, 288: insulator, 290: opening portion, 310: transistor, 311: substrate, 313: semiconductor region, 314a: low-resistance region, 314b: low-resistance region, 315: insulator, 316: conductor, 317: insulator, 318: element isolation layer, 320: insulator, 322: insulator, 324: insulator, 326: insulator, 328: conductor, 330: conductor, 370a: oxide semiconductor layer, 370b: oxide semiconductor layer, 370c: oxide semiconductor layer, 370d: oxide semiconductor layer, 372a: region, 372b: region, 372c: region, 400a: capacitor, 400b: capacitor, 400: capacitor, 410: conductor, 415: conductor, 430: insulator, 440: insulator, 445: conductor, 446: conductor, 447: conductor, 450a: memory cell, 450b: memory cell, 450: memory cell, 480: insulator, 490: opening portion, 500A: display device, 500C: display device, 520: transistor, 580: display module, 581: display portion, 582: circuit portion, 583a: pixel circuit, 583: pixel circuit portion, 584a: pixel, 584: the pixel portion, 585: terminal portion, 586: wiring portion, 590: FPC, 591: substrate, 592: substrate, 700A: electronic device, 700B: electronic device, 721: housing, 723: wearing portion, 727: earphone portion, 750: earphone, 751: display panel, 753: optical member, 756: display region, 757: frame, 758: nose pad, 800A: electronic device, 800B: electronic device, 820: display portion, 821: housing, 822: communicator, 823: wearing portion, 824: control portion, 825: image capturing portion, 827: earphone portion, 832: lens, 900: semiconductor device, 910: driver circuit, 911: peripheral circuit, 912: control circuit, 915: peripheral circuit, 920[1]: memory array, 920[2]: memory array, 920[m]: memory array, 920: memory array, 923: row driver, 924: column driver, 925: input circuit, 926: output circuit, 927: sense amplifier, 928: voltage generation circuit, 930: layer, 931: PSW, 932: PSW, 941: row decoder, 942: column decoder, 950: memory cell, 951: memory cell, 952: memory cell, 953: memory cell, 954: memory cell, 955: memory cell, 956: memory cell, 957: memory cell, 958: memory cell, 960: arithmetic device, 970A: semiconductor device, 970B: semiconductor device, 970C: semiconductor device, 989: cache interface, 990: substrate, 991: ALU, 992: ALU controller, 993: instruction decoder, 994: interrupt controller, 995: timing controller, 996: register, 997: register controller, 998: bus interface, 999: cache, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic device, 6501: housing, 6502: display portion, 6503: power button, 6504: button, 6505: speaker, 6506: microphone, 6507: camera, 6508: light source, 6509: control device, 6510: protection member, 6511: display panel, 6512: optical member, 6513: touch sensor panel, 6515: FPC, 6516: IC, 6517: printed circuit board, 6518: battery, 6600: electronic device, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 6900: storage system, 6901sb: server, 6901: host, 6902: storage control circuit, 6903md: memory device, 6903: storage, 7000: display portion, 7100: television device, 7101: housing, 7103: stand, 7111: remote controller, 7200: laptop personal computer, 7211: housing, 7212: keyboard, 7213: pointing device, 7214: external connection port, 7216: control device, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A semiconductor device comprising a transistor and a first insulator,
wherein the transistor comprises a first conductor, a second conductor, an oxide semiconductor, a second insulator and a third conductor,
wherein the second conductor is over the first conductor and the first insulator,
wherein an opening portion reaching the first conductor is in the first insulator and the second conductor,
wherein the first conductor has a depressed portion,
wherein the opening portion and the depressed portion of the first conductor overlap each other,
wherein a part of the oxide semiconductor, a part of the second insulator and a part of the third conductor are provided in the depressed portion of the first conductor,
wherein the oxide semiconductor is in contact with the first conductor and the second conductor,
wherein the second insulator is over the oxide semiconductor and is in contact with at least a part of a top surface of the first conductor, and
wherein the third conductor is over the second insulator.

2. The semiconductor device according to claim 1, wherein at least a part of a bottom surface of the oxide semiconductor is removed in the depressed portion.

3. The semiconductor device according to claim 2, wherein a bottom surface of the third conductor is at a lower level than a top surface of the first conductor in a region not overlapping with the opening portion.

4. The semiconductor device according to claim 1,
wherein the second conductor comprises a first layer and a second layer over the first layer,
wherein the first layer comprises a metal oxide, and
wherein the second layer has a higher conductivity than the first layer.

5. The semiconductor device according to claim 4, wherein the first layer comprises indium.

6. The semiconductor device according to claim 5, wherein the first layer further comprises tin and silicon.

7. The semiconductor device according to claim 4, wherein the second layer comprises tungsten.

8. The semiconductor device according to claim 4, wherein a side surface of the first layer on the opening portion side is positioned closer to the opening portion than a side surface of the second layer on the opening portion side is.

9. The semiconductor device according to claim 8, wherein the oxide semiconductor is in contact with the side surface of the first layer on the opening portion side and a part of a top surface of the first layer.

10. The semiconductor device according to claim 9, wherein a third insulator is between the second layer and the third conductor.

11. The semiconductor device according to claim 1,
wherein the first conductor comprises a third layer and a fourth layer over the third layer,
wherein the third layer has a higher conductivity than the fourth layer, and
wherein the fourth layer comprises a metal oxide.

12. The semiconductor device according to claim 11, wherein the third layer comprises tungsten.

13. The semiconductor device according to claim 12, wherein the fourth layer comprises indium.

14. The semiconductor device according to claim 13, wherein the fourth layer comprises tin and silicon.

15. The semiconductor device according to claim 11, wherein the opening portion reaches the third layer.

16. A semiconductor device comprising a transistor and a first insulator,
wherein the transistor comprises:
a first conductor over a base insulator;
a second conductor over the first conductor and the first insulator;
an oxide semiconductor in contact with the first conductor and the second conductor;
a second insulator over the oxide semiconductor; and
a third conductor over the second insulator,
wherein an opening portion reaching the base insulator is provided in the first conductor, the first insulator and the second conductor,
wherein a part of the oxide semiconductor, a part of the second insulator and a part of the third conductor are provided in the opening portion,
wherein the oxide semiconductor is in contact with the first conductor and the second conductor, and
wherein the second insulator is in contact with at least a part of a top surface of the base insulator.
